(19) United States
(12) Patent Application Publication
(10) Pub. No.: US 2025/0309113 A1
(43) Pub. Date: Oct. 2, 2025

(54) POWER MODULE IMPLEMENTING TRUE AND PARTIAL SOURCE KELVIN INTERCONNECTIONS FOR ENHANCING SWITCHING PERFORMANCE AND PROCESS OF IMPLEMENTING THE SAME

(71) Applicant: WOLFSPEED, INC., Durham, NC (US)

(72) Inventors: Roderick Gomez, Fayetteville, AR (US); Jukkrit Noppakunkajorn, Durham, NC (US); Brice McPherson, Springdale, AR (US); Shashwat Singh, Fayetteville, AR (US); Roberto Marcelo Schupbach, Fayetteville, AR (US); Brandon Scaggs, Farmington, AR (US)

(21) Appl. No.: 18/618,823

(22) Filed: Mar. 27, 2024

(51) Int. Cl. H01L 23/528

(52) U.S. Cl. CPC H01L 23/5286

(57) ABSTRACT

A power module includes a power substrate, at least one first power device arranged on the power substrate, at least one second power device arranged on the power substrate, at least one true Kelvin interconnection, and at least one pseudo-Kelvin interconnection.

### BACKGROUND OF THE DISCLOSURE

Wide Band Gap (WBG) power semiconductors, such as Silicon Carbide (SiC), offer numerous performance benefits, including high voltage blocking, low on-resistance, high current, fast switching, low switching losses, high junction temperatures, and high thermal conductivity. These characteristics result in a notable increase in potential power density, which is power processed per area or volume. Achieving this potential, however, requires addressing significant challenges at the package and system level.

Accordingly, a power module and/or a process of implementing a power module is needed to address the challenges at the package and system level.

### SUMMARY OF THE DISCLOSURE

In one aspect, a power module includes a power substrate. The power module in addition includes at least one first power device arranged on the power substrate. The module moreover includes at least one second power device arranged on the power substrate. The module also includes at least one true Kelvin interconnection. The module further includes at least one pseudo-Kelvin interconnection.

In one aspect, a power module includes at least one first power device. The power module in addition includes at least one second power device. The module moreover includes at least one true Kelvin interconnection. The module also includes at least one pseudo-Kelvin interconnection. The module further includes where the at least one pseudo-Kelvin interconnection is connected to the at least one true Kelvin interconnection.

In one aspect, a power module includes at least one first power device. The power module in addition includes at least one second power device. The module moreover includes at least one true Kelvin interconnection. The module also includes at least one pseudo-Kelvin interconnection. The module further includes where the at least one first power device is connected to the at least one true Kelvin interconnection. The module in addition includes where the at least one second power device is connected to the at least one pseudo-Kelvin interconnection.

In one aspect, a process includes providing a power substrate. The process in addition includes arranging at least one first power device on the power substrate. The process moreover includes arranging at least one second power device on the power substrate. The process also includes providing at least one true Kelvin interconnection. The process further includes providing at least one pseudo-Kelvin interconnection.

In one aspect, a process includes providing at least one first power device. The process in addition includes providing at least one second power device. The process moreover includes providing at least one true Kelvin interconnection. The process also includes providing at least one pseudo-Kelvin interconnection. The process further includes connecting the at least one pseudo-Kelvin interconnection to the at least one true Kelvin interconnection.

In one aspect, a process includes providing at least one first power device. The process in addition includes providing at least one second power device. The process moreover includes providing at least one true Kelvin interconnection. The process also includes providing at least one pseudo-Kelvin interconnection. The process further includes connecting the at least one first power device to the at least one true Kelvin interconnection. The process in addition includes connecting the at least one second power device to the at least one pseudo-Kelvin interconnection.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a schematic of a power module according to aspects of the disclosure.

FIG. 2 illustrates a schematic of a power module according to aspects of the disclosure.

FIG. 3A is a perspective view of an exemplary power device according to aspects of the disclosure, FIG. 3B is a top view of the exemplary power device of FIG. 3A, and FIG. 3C is a bottom view of the exemplary power device of FIG. 3A.

FIG. 4 is a top view of another exemplary power device according to aspects of the disclosure.

FIG. 5 is a top view of an exemplary power device arrangement of a power module according to aspects of the disclosure.

FIG. 6 is a top view of another exemplary power device arrangement of a power module according to aspects of the disclosure.

FIG. 7 illustrates a perspective view of aspects of a power module according to aspects of the disclosure.

FIG. 8 illustrates a top view of the power module according to FIG. 7.

FIG. 9 illustrates another top view of the power module according to FIG. 7.

FIG. 10 illustrates a perspective view of a power module according to aspects of the disclosure.

FIG. 11 illustrates a top view of the power module according to FIG. 10.

FIG. 12 illustrates another top view of the power module according to FIG. 10.

FIG. 13 illustrates another top view of the power module according to FIG. 10.

FIG. 14 illustrates another top view of the power module according to FIG. 10.

FIG. 15 illustrates another top view of the power module according to FIG. 10.

FIG. 16 illustrates a perspective view of a power module according to aspects of the disclosure.

FIG. 17 illustrates a top view of the power module according to FIG. 16.

FIG. 18 illustrates another top view of the power module according to FIG. 16.

FIG. 19 illustrates another top view of the power module according to FIG. 16.

FIG. 20 illustrates another top view of the power module according to FIG. 16.

FIG. 21 illustrates a perspective view of a power module according to aspects of the disclosure.

FIG. 22 illustrates a perspective view of the power module according to FIG. 21.

FIG. 23 illustrates another top view of the power module according to FIG. 21.

FIG. 24 illustrates another top view of the power module according to FIG. 21.

FIG. 25 illustrates a perspective view of a power module according to aspects of the disclosure.

FIG. 26 illustrates a top view of the power module according to FIG. 25.

FIG. 27 illustrates another top view of the power module according to FIG. 25.

FIG. 28 illustrates another top view of the power module according to FIG. 25.

FIG. 29 illustrates another top view of the power module according to FIG. 25.

FIG. 30 illustrates another top view of the power module according to FIG. 25.

FIG. 31 illustrates another top view of the power module according to FIG. 25.

FIG. 32 illustrates top views of power modules according to FIG. 25.

FIG. 33 illustrates a perspective view of a power module according to aspects of the disclosure.

FIG. 34 illustrates a top view of the power module according to FIG. 33.

FIG. 35 illustrates a perspective view of a power module according to aspects of the disclosure.

FIG. 36 illustrates a top view of the power module according to FIG. 35.

FIG. 37 illustrates another top view of the power module according to FIG. 35.

FIG. 38 illustrates another top view of the power module according to FIG. 35.

FIG. 39 illustrates another top view of the power module according to FIG. 35.

FIG. 40 illustrates another top view of the power module according to FIG. 35.

FIG. 41 illustrates another top view of the power module according to FIG. 35.

FIG. 42 illustrates another top view of the power module according to FIG. 35.

FIG. 43 illustrates a perspective view of a power module according to aspects of the disclosure.

FIG. 44 illustrates a top view of the power module according to FIG. 43.

FIG. 45 illustrates a perspective view of a power module according to aspects of the disclosure.

FIG. 46 illustrates a top view of the power module according to FIG. 45.

FIG. 47 illustrates another top view of the power module according to FIG. 45.

FIG. 48 illustrates another top view of the power module according to FIG. 45.

FIG. 49 illustrates a perspective view of a power module according to aspects of the disclosure.

FIG. 50 illustrates a top view of the power module according to FIG. 49.

FIG. 51 illustrates a perspective view of a power module according to aspects of the disclosure.

FIG. 52 illustrates a top view of the power module according to FIG. 51.

### DETAILED DESCRIPTION

The disclosure will now be described with reference to the drawing figures, in which like reference numerals refer to like parts throughout.

The disclosed device and process may be utilized for achieving fast, clean, and efficient switching of paralleled power electronic devices in packages and/or layouts, which do not readily allow true source kelvin interconnection for each individual device without needing additional elements such as signal substrates, complex signal routing, and/or the like.

Here, a true source kelvin may be delivered to one or more (but not all) of the devices, with the remaining signal loops sharing a partial path with a power loop. This shared path may travel a minimal distance with minimal influence from the power path due to a low common mode inductance. Effectively, the first device may start the turn-on and turn-off events faster and without interference, with the other devices following suit. This may improve efficiency, better stabilize oscillations, act to prevent gate voltages from drifting outside of their Safe Operating Area (SOA), and/or the like. The disclosed device and process may help to mitigate and lessen the compromises when a true kelvin for each individual device is not possible or not practical.

In general, fast switching devices, such as Silicon Carbide (SIC) MOSFETs, may benefit from true source kelvin connections, such as no shared path through the power loop, for the most optimal switching performance. However, certain package structures may not be well suited for dedicated kelvin bonds for every device in parallel. This can be due to a terminal location, layout restrictions, device area, interconnection methods, cost targets, and/or the like and combinations thereof.

In these cases, partial or pseudo kelvin connections may be formed where some of the signal loop is shared with the power loop. The more physical and electrical separation between the two paths, the less the effects of the common mode inductance may have on the ability to switch effectively. Effects can further be minimized in some aspects of the disclosed device and process by running signal currents in one direction and running the power in an orthogonal direction to further reduce interactions from a magnetic field.

Here, one or more devices, most often the edge device of a paralleled strand, may be bonded with a true kelvin bond. The neighboring devices may be bonded such that the remaining paths the signals follow share some but limited path with the power interconnections, taking advantage of the minimal shared path distance achieved through the true kelvin bonded device.

In this disclosure, implementations on various generic package layouts and exemplary industry standard packages are illustrated to outline the effectiveness and flexibility of the disclosed device and process for packages where switching performance would otherwise be compromised.

In aspects, the disclosed device and process may include: a mixed kelvin method for providing a true kelvin connection to at least one device in a switch position; a method for providing a low inductance pseudo kelvin connection to remaining devices in a switch position; a true source kelvin interconnection to gate and source pads on the devices through wire bonds, ribbon, laminate overlay, direct attach, and/or the like; a partial or pseudo kelvin interconnection to source pads on the devices through wire bonds, ribbon, laminate overlay, direct attach, and/or the like; structures and layout implementations for linear arrangements of devices; structures and layout implementations for arrayed arrangements of devices; structures and layout implementations for single switch, half-bridge, common source, common drain, three phase, and/or the like topologies; gate interconnection using individual wire bonds; gate interconnection using daisy chained wire bonds; mixed kelvin enablement through shared power path through a source clip attach; mixed kelvin enablement through jumper wire bonds; mixed kelvin enablement through daisy chained wire bonds; scalability through compatibility with many device sizes and pad layouts; scalability through adding or removing devices in the paralleled strand; modularity though fully and partially populated switch positions; flexibility to be applied to most power electronic module layouts which parallel devices; embodiments on single switch position packages; and/or embodiments on half-bridge packages.

Wide Band Gap (WBG) power semiconductors, such as Silicon Carbide (SiC), offer numerous performance benefits, including high voltage blocking, low on-resistance, high current, fast switching, low switching losses, high junction temperatures, and high thermal conductivity. These characteristics result in a notable increase in potential power density, which is power processed per area or volume. Achieving this potential, however, requires addressing significant challenges at the package and system level.

Achieving this potential, however, requires addressing significant challenges at the package and system level. Higher voltages, currents, and switching speeds manifest into significantly higher physical stresses applied onto smaller and more constrained areas. To fully take advantage of what WBG technology offers, these challenges must be addressed, including: capability to form common circuit topologies both within (internal layout) and without (interconnection) the package; waste heat removal including conduction and switching losses from the devices; effective electrical isolation between high voltage potentials; low power loop inductance for minimal high voltage overshoot during high speed switching; low signal loop inductance for minimal gate voltage overshoot and oscillations; internal layout optimized for paralleling of devices for dynamic and steady state current sharing; low power loop resistance for high current carrying without overheating; external terminal arrangement suited for paralleling modules and effective arrangement into circuit topologies; and/or balanced arrangement of devices for even current sharing with minimal thermal overlap.

The internal layout, or physical arrangement of package components, may have a prominent influence on each of these factors. It becomes increasingly more difficult to realize an optimal layout as the number of devices inside of the package increases. Paralleling is a common technique to increase the current capability of a package. With more devices in parallel, the tradeoffs between heat spreading, power loop inductance, signal loop inductance, and package size become progressively more difficult to balance.

In power electronic systems, many topologies, or electrical arrangements of the power devices, may be used. These may include but are not limited to the following: single switch; half-bridge; full-bridge; three-phase bridge/six pack; buck; boost; buck-boost; Cuk; common source, common drain, and/or the like.

While some packages may house and interconnect the full topology itself, others may be intended as building blocks from which many topologies can be formed. Often, packages housing a single switch position of one or more power devices per switch position may be used. Another common arrangement is a bridge leg, or half-bridge, of two switch positions of one or more devices per switch position connected in series. Multiple bridge legs can form topologies such as half-bridge or three-phase, or may also be paralleled themselves for higher currents.

In addition to layout, topology, and performance, to appeal to a broad range of markets and applications, cost is often a driving factor in effective solutions. A few techniques to optimize the Bill of Materials (BOM) and production costs include: Limit use of individual components by serving multiple functions with the same component; optimize functionality and performance out of each component through design; limit the requirement of secondary or finishing operations; use conventional or well-established manufacturing methods known for high yield; utilize batch or continuous processing when possible, using panels, strips, arrays, magazines, etc.; optimize package size and form based on manufacturing methods of the sub-components (such as sizing the parts that may be fabricated on a strip or a panel to maximize utilization of that raw material); and/or the like.

Power packages may contain power semiconductor devices, including MOSFETs, IGBTs, diodes, and/or the like, arranged into a variety of circuit topologies. A power module is typically a package that contains multiple devices in parallel and arranged into multiple switch positions. It serves many functions, including: electrical interconnection; electrical isolation; heat transfer; mechanical structure; protection of the devices from environmental contamination and moisture; external electrical and thermal connection interfaces; compliance with safety standards such as voltage creepage and clearance distances; and/or the like.

Aspects of the disclosed power module or Semiconductor package they use, but may be not limited to, some combination of the following components, each providing multiple functions:
Power Device(s)—Controllable switches MOSFET, IGBT, and the like and Diodes;
Substrate, Power—Layered metal and ceramic for high current electrical; interconnection, high voltage isolation, high thermal conductivity, coefficient of thermal expansion (CTE) matching, and external thermal interface;
Substrate, Signal—Layered Printed Circuit Board (PCB), layered metal and ceramic, thick film, and the like for high frequency electrical interconnection and high voltage isolation;
Terminal, Power—Conductive contact, terminal, or connector for high current external connection and internal interconnection;
Terminal, Signal—Conductive contact, terminal, or connector for low current, often high frequency external connection and internal interconnection;
Lead Frame—Conductive strip for external connection and internal interconnection; Contacts may be joined together on a single sheet, often with multiple products per sheet, and may be processed as an array and then formed and singulated;
Base Plate—Metal, ceramic, composite material, and the like for mechanical structure, thermal conductivity, coefficient of thermal expansion (CTE) matching, and external thermal interface;
Device Attach—Solder, adhesive, or sintered metal, and the like for mechanical structure, electrical interconnection, and thermal conductivity;
Terminal Attach—Solder, adhesive, sintered metal, laser weld, ultrasonic weld, and the like for mechanical structure, electrical interconnection, and thermal conductivity;
Substrate Attach—Solder, adhesive, or sintered metal, and the like for mechanical structure and thermal conductivity;
Wire Bonds, Power—Ultrasonically or thermosonically bonded large diameter wire for high current electrical interconnection;
Wire Bonds, Signal—Ultrasonically or thermosonically bonded small diameter wire for low current electrical interconnection;
Case/Housing—Molded plastic case and lid, providing mechanical structure, high voltage isolation, and acting as a well for the encapsulation material;
Mold Compound—Transfer or compression molded epoxy molding compound (EMC) for mechanical structure, high voltage isolation, coefficient of thermal expansion (CTE) matching, and low humidity absorption;
Encapsulation—Soft, flexible silicone or similar encapsulation material for high voltage isolation, and low humidity absorption;
Sensor—Passive or active element that can be used to monitor characteristics, including temperature, current, strain, test points, and the like; and/or
Signal Circuitry—Resistors, capacitors, surface mount components, sensors, and the like for stabilization of the dynamic switching performance of the devices or for other internal circuit requirements, such as active miller clamping, etc.

Aspects of the disclosed power module may include implementations of power packages that may vary significantly based on the specific applications for and intended usage of the products. Common goals of a power package may include: high power density (power/area or power/volume); high current; high voltage; high temperature operation; low thermal resistance; low stray inductance; fast and clean switching; high efficiency through low on-resistance; high efficiency through high speed switching; thoughtful external terminal layout for effective interconnection; compliance with creepage and clearance standards; moisture sensitivity level (MSL) compliance; low cost; and/or the like.

Aspects of the disclosed device and process may include electrical loops. In implementations of the disclosed power device, there may be multiple electrical circuits necessary for operation. These may be described in the following categories: Power—High voltage, high current path through the switch(es) that may deliver power to the load through the drain (or collector) and source (or emitter) of the semiconductor device(s); Signal, Gate—Low voltage, low current path through the gate (or base) and the source (or emitter) of the semiconductor device(s). The gate-source (or base-emitter) signal path actuates the devices to turn-on or turn-off; Signal, Sense—Path through an active or passive sensing element, such as a temperature sensor, that signal current travels to measure some internal performance metric; and/or the like.

These paths are illustrated in the figures for an example MOSFET. Note that the terminal names and specific loops may be different depending on the device type. Also note that for arrangements of multiple devices in parallel and into topologies, the terminal names and specific loops may also be different.

In a power module, these electrical paths may be part of the full distance current travels through the system in a closed loop. The specific route traveled depends on device type and topology. For any electrical loop, there may be power loss due to resistive losses, and energy stored in the magnetic field (inductance) and electric field (capacitance). Resistive losses may manifest as undesirable self-heating of the conductors. Stored energy can inhibit switching events, slowing turn-on and turn-off and increasing switching losses. They may also result in dynamic oscillations, further increasing loss, increasing voltage stresses, and the chance of unstable or unpredictable switching.

Aspects of the disclosure may include minimizing the parasitic effects of the electrical paths to realize a high performance and reliable power module. Aspects of the disclosure may be configured to achieve: low resistance—lower losses in the conductors and lower conductor temperatures; low inductance—reduced voltage spikes during switching, reduced oscillations, faster, more efficient switching; low capacitance—reduced currents coupled to the surrounding system, reduced electromagnetic interference (EMI), reduced oscillations, faster, more efficient switching; and/or the like.

Aspects of the disclosed device and process may provide low parasitic interconnections for both the power and signal loops in the same package, which may often be difficult to achieve with a single layer power substrate and/or lead frame. This is the result of contrasting needs and manufacturing methods for power paths and signal paths. This is further complicated in the fact that the power and signal loops may interfere with each other as they share a terminal on the device.

Aspects of the disclosed device and process may implement a source kelvin. In particular, the drain-source (or collector-emitter) and gate-source (or gate-emitter) loops may share the same connection at the source (or emitter) of the device. If the power path couples into the signal paths, extra dynamics may be introduced through either positive or negative feedback. Typically, negative feedback introduces extra losses as the power path coupling fights the control signal (i.e. the power path coupling tries to turn the device off when the control signal is trying to turn the device on). Positive feedback typically causes instability as the power path coupling amplifies the control signal until the devices may be destroyed. Ultimately, the coupling of power and signal paths result in a reduction in switching quality, slower switching speeds, increased losses, and possible destruction.

Accordingly, one approach to improve switching quality may be to ensure independent loops. Here, the power source connection may have a separate path from the signal source (referred to as a source Kelvin) such that one does not overlap or interfere with the other. The closer the separate connections are made to the device, the better the switching performance may be.

In general, single switch positions may be assembled in either three or four terminal packages. Three terminal packages may be simpler in construction and may be well suited for applications where switching losses may be low. However, they lack a kelvin connection of any means. For optimal switching, a four terminal package may be employed, in which the power loops and signal loops may be independent of each other (i.e. a kelvin connection) to enable low switching loss with fast, well controlled dynamics.

Packages with multiple switch positions may generally have power terminals respective to their given layout and two signal terminals per switch position. Depending on the package structure, these signal terminals may or may not have true kelvin implementation.

If the loops are completely independent, this may be referred as a ‘true kelvin’ connection. If there is some amount of overlap, this may be referred as a ‘pseudo kelvin’ in which as much overlap as possible is minimized.

While a true kelvin may be desired for each individual device in a switch position, often limitations in a product outline, such as paralleling more devices in industry standard footprints, and manufacturing methods may create the need for compromises in structure and performance.

Power routing may require carrying high currents (in the tens to hundreds of amps as well as hundreds to thousands of amps) through thick conductive layers at a large cross sectional area. This may be necessary to reduce electrical resistances and the associated rise in temperature due to resistive losses. As these losses scale with the square of the current, increasingly higher currents demand increasingly lower resistance and increasingly more cross sectional area of the conductors.

Aspects of the disclosed device may utilize conventional fabrication methods, such as etching, metal stamping, metal forming, and/or the like and may have minimum requirements for cuts, bending angles, and/or the like. These minimum requirements may increase with metal thickness. For example, thicker metal may require wider slots and larger bending angles. Accordingly, for thicker metal structures intended for high currents, it can be challenging to achieve complex, high resolution shapes.

Aspects of the disclosed device may utilize signal routing. In this regard, signal routing, on the other hand, is typically low in current. As such, less metal is required. However, the signal network often has many more electrical connections and loops in comparison to power. These include gate and source kelvin connections, sensors, protection, circuitry, and/or the like. These electrical connections may travel long distances within the module. To reduce inductance, the traces may often be either laid out as differential pairs in a single layer or as differential planes in multiple layers.

Due to the thick metal fabrication methods for power, and the desire for high density routing for signal, it may be difficult to have a single element, for example in the substrate or lead frame, to achieve both. This is further complicated by the desire to have a true source kelvin.

In many cases, efficiency and switching stability may be the driving design decision. Here, accommodations for completely independent power and signal loops for every device in a switch position may allow for optimal performance. However, these accommodations may be generally at the sacrifice of cost. For example, additional signal substrates, larger power substrates, additional functional elements, and/or power density, such as signal traces on power substrates, signal beams on lead frames, and/or the like.

In other cases, the signal loop may be compromised. Here, most of, if not all, or the source kelvin connection may be shared with the power loop as a pseudo kelvin. This can achieve a lower product cost and smaller footprint at the sacrifice of slower switching, higher switching losses, and higher switching instabilities.

Aspects of the disclosed device and process may implement mixed kelvin.

In particular, the disclosed device and process may address this tradeoff with a mixed kelvin approach in which at least one device in a switch position has an optimal true kelvin connection, with the remaining devices having a low impedance pseudo kelvin connection through the true kelvin device through some shared source to source interconnection.

In this aspect, the first device may have a true kelvin connection in which there is no overlap of the power and signal interconnections. Subsequent devices in the array may share the true kelvin connection of the first device and some element of the power loop to their own source contacts. Accordingly, these devices have mixed kelvin loops which may be composites of both true and partial kelvin paths.

While four devices may be implemented, the number of paralleled devices could be as few as two up to any arbitrary number following a similar interconnection. Also note that the gate terminals on each device could be connected to the same terminal on the package.

Another method may be to deliver a true kelvin connection to as many devices as is practical or possible, with the remaining devices employing the mixed kelvin method. In aspects, four devices may be paralleled with the devices on the edges having true kelvin connections and the inner devices having mixed kelvin connections.

While four devices may be implemented, for this distributed kelvin approach the number of paralleled devices could be as few as three up to any arbitrary number following a similar interconnection. At least two devices would have true kelvin with the remaining arbitrary number having mixed kelvin. Also note that the gate and true kelvin terminals on each device would be connected to the same terminal on the package.

In aspects, the disclosed device and process may implement numerous layouts. For example, an exemplary device may be a MOSFET with three terminal pads: gate, source, and drain. On the topside, there may be a gate pad, gate runner(s), and source pads. Gate runners may be used to better distribute the gate across the device area and may run along the perimeter of the device as well as one more multiple runners across the inner region. The topside have an insulating layer, often polyimide, that may protect surfaces and may provide electrical isolation. The entire backside of the device may be the drain. Note that this is a simplified description of the device with respect to a package layout. There may be many other functional elements and layers in a power device that may not be relevant to the disclosure and accordingly not represented or called out.

In aspects, the topside polyimide (or similar insulating material) may be patterned to facilitate a given interconnection method (wire bonds, solder, sinter, and/or the like). As an example, if power wire bonding or ribbon bonding is used, the source pads may be best left open as much as possible to allow for optimal bonding area. In other cases, the power contacts may be directly attached as a clip to the topside source pads and wire bonds connect to the signal pads. Here, the polyimide may be used to keep solder or similar attach material for the power clip from spreading onto the wire bonding pads. Note that the source pads may be still connected, just masked off on top through the polyimide layer. The underlying device may be the same, with the key difference being the pattern of the polyimide.

For the purposes of this disclosure, the polyimide pattern for clip attach may be used for simplicity. For the disclosed device and process, any device pad arrangement, device size, aspect ratio, and/or the like may be compatible.

In power modules, devices may be typically paralleled to increase the amount of output current. Generally, there may be a number of methods of paralleling devices in a power electronic package. For example:
Linear arrangement, linear power flow, where: power flows from one side of the strand to the other; often used when many devices (≥4) are paralleled; and/or often used in existing industry standard footprints.

Linear arrangement, parallel power flow, where: devices in a strand in one direction; power flows evenly across the strand; often used when many devices (≥4) may be paralleled; and/or often used in low inductance, high performance packages.

Arrayed, where: devices may be arranged on a grid in two directions; power can flow in either or both directions; often used with smaller device counts (≤6) that may be paralleled; and/or often used in small footprint, high performance packages

These arrangements may be presented for four devices. The number of devices can be considered arbitrary with linear arrangements being more than two devices, and arrayed arrangements being at least four devices. Also note that arrays can be of arbitrary size, such as 2×2 (four devices), 2×3 (six devices), etc.

Exemplary layouts for the three paralleling methods are disclosed herein. Note that the depictions display intent and function and may not be necessarily representative of an actual product design.

For each of the layouts, a ‘standard’ power module stack-up including substrates, electrical terminals for the power and signal connections, and the power and signal interconnections may be utilized. Other elements, such as attach layers, housings, base plates, etc. are not shown for simplicity, but may be necessary in a full system.

Some elements, such as the power and signal terminals, may be implemented in the layouts as standalone elements. However, they may also be part of a lead frame structure, an overmolded metal contact, part of the power substrate, part of a secondary substrate, and/or the like.

In aspects, the mixed kelvin approach may be compatible with different and more advanced packaging technologies, attaches, and/or materials that may or may not be represented in the example layouts.

In aspects, the disclosed device and process may implement a linear arrangement, linear power flow.

For example, a mixed kelvin layout for a linear arrangement with linear power flow. Here, each device may have a dedicated gate wire bond over to a trace on the power substrate. In aspects a rightmost and/or leftmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, daisy chained stitch bond, and/or the like. These jumpers may shorten the distance the signal current must flow in the loop while minimizing the shared path with the power loop.

In aspects, the power and signal loops may be laid out linearly, with the power flowing in and out from the same side, while the signals flow in and out on one side. The power terminals may be on one side, on opposite sides, or on both sides. The signal terminals may be on the opposite side of the power terminals, as pictured, the same side, or on both sides.

In aspects, the signal current may flow through the gate terminal, through the trace on the substrate, through the dedicated gate bonds, through the gate network on the devices, through the source pads of the devices to the wire bond jumpers, through to the trace on the substrate, and finally out of the source kelvin terminal. One device may have a true kelvin with no overlap of the power loop, while the remaining devices have some overlap but minimal interaction with the drain-source current. Notably through in this aspect of the power module 100, efficient switching can occur without needing to add a second trace on the substrate (or lead frame, signal substrate, etc.) which can take up room, add complexity, and add cost.

For further optimization, the gate pads on the devices can be stitch bonded together such that they all share the same linkage through a single daisy chained wire, removing the need for the dedicated gate trace on the substrate. In this aspect, this may not require gate or source kelvin traces, just a bonding pad on the substrate which may go to the signal connector. These bonding pads may also be removed in some cases where the signal terminal is wire bondable or the bonds may be formed directly from the devices to a lead frame. This approach may allow for further improvements in power density, reduced complexity, reduced cost, and/or the like. Also note that the gate and source kelvin loops in this aspect may be tightly coupled. For example, close in proximity and direction such that flux cancellation may reduce the overall loop inductance.

In aspects of the power module 100, a mixed kelvin layout may be implemented for a linear arrangement, linear power flow with stitched gate bonding.

For either method of gate bonding, the power loop can be achieved with wire bonds, a direct clip attach, and the like. In some cases, the clip may be a standalone element or multiple elements. In other cases, it is joined to power contacts, signal contacts, and/or the like as part of a larger lead frame. There may be tradeoffs associated with the interconnection method regarding performance, manufacturability, and cost. Of particular importance here is that the mixed kelvin approach is compatible with any power interconnection scheme. In aspects, the disclosed device and process may implement a linear arrangement, parallel power flow.

In aspects, a mixed kelvin layout for a linear arrangement with parallel power flow. Here, stitched gate bonding frees up the room which would be used as a gate trace to bring power in across the width of the switch position. This layout may take full advantage of the available area for power conduction, and results in a lower and more balanced inductance across the switch position. The rightmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, as shown, or as a daisy chained stitch bond.

For this layout, the devices may be laid out linearly, the power flows in and out from wide power terminals following the width of the footprint. The signal terminals may be on the opposite side of the power terminals, as pictured, the same side, or on both sides.

The signal current flows through the gate terminal, through the trace on the substrate, through the stitched gate bonds, through the gate network on the devices, through the source pads of the devices to the wire bond jumpers, through to the trace on the substrate, and finally out of the source kelvin terminal. One device has a true kelvin with no overlap of the power loop, while the remaining devices have some overlap but minimal interaction with the drain-source current.

The power loop can be achieved with wire bonds, a direct clip attach, and the like. In some cases, the clips may be a standalone element. In other cases, it is joined to power contacts, signal contacts, etc. as part of a larger lead frame. There may be tradeoffs associated with the interconnection method regarding performance, manufacturability, and cost. Of particular importance here is that the mixed kelvin approach is compatible with any power interconnection scheme.

In aspects, a mixed kelvin layout for an array arrangement with power flowing from one side to the other. Here, the devices would typically be arranged as ‘legs’ where the gates may be in-line. The lower rightmost device has a true source kelvin bond from the source pad to a trace on the power substrate. Then, between each device, a jumper wire bond ties the source pads together in a low inductance path. These jumpers shorten the distance the signal current must flow in the loop while minimizing the shared path with the power loop. Note that in some cases, the power bonds themselves act as a jumper for the source kelvin. In those cases, the amount of shared distance should be minimized as much as possible to limit the effect of the power currents on the signals.

In aspects, the devices may be laid out in an example 2×2 array, with the power flowing in and out from the same side. The signals may be located on the source side in which they may share a similar voltage. The substrate may have a gate trace for the devices to individually bond to. Note that this signal trace would be part of the power substrate, or alternatively a portion of it could be on a lead frame, signal substrate, and the like. Also note that in some cases the signals could be on the source side, as pictured, the drain side, or both sides (left and right), depending on implementation.

For the signal loops, the current flows through the gate terminal, through the trace on the substrate, through the dedicated gate bonds, to the devices, then out the source pads of the devices to the wire bond jumpers, then to the trace on the substrate (or alternatively on a lead frame, signal substrate, etc.) and out of the source kelvin terminal. For one device, there is a true kelvin with no overlap of the power loop, while the remaining devices have some but minimal interaction with the drain-source current.

For further optimization, the gate pads on the device legs can be stitch bonded together such that they may all share the same linkage through a single daisy chained wire. In aspects, this may require a much simpler gate trace on the substrate (or lead frame, signal substrate, etc.). This approach could allow for further improvements in power density, reduced complexity, and reduced cost. Also note that the gate and source kelvin loops in this method may be tightly coupled (i.e. close in proximity and direction) such that flux cancellation can reduce the overall loop inductance.

For either method of gate bonding, the power loop can be achieved with wire bonds, a direct clip attach, and the like. In some cases, the clip is a standalone element. In other cases, it is joined to power contacts, signal contacts, etc. as part of a larger lead frame. There may be tradeoffs associated with the interconnection method regarding performance, manufacturability, and cost. Of particular importance here is that the mixed kelvin approach is compatible with any power interconnection scheme.

While four devices were used in the example layouts, it is apparent that the method can scale up or scale down the number of devices and still be compatible with and benefit from this method. The scalable approach extending the layout in the direction of the device paralleling still allows for the mixed kelvin approach to be utilized. In some cases, the signal connections may be formed on both sides (i.e. a true kelvin on each side) to minimize inductance.

In other cases where the footprint of the module is not able to be scaled, flexibility can be found in using the modularity feature of this approach. In a set footprint, each device location can be considered a set number of ‘sites’ which may or may not be populated. Modularity is found in the ability to populate a site with a device or leave it blank. This is a useful technique to design a footprint for a ‘fully loaded’ maximum power condition and have other product offerings with ‘sites’ not populated for lower power, more cost effective offerings.

This is demonstrated for an arrayed method of paralleling with a clip attach. Here, the same clip can be used, with device sites not populated and the wire bonding adjusted to match. Importantly, the true kelvin device or device(s) would not be depopulated to maintain product function.

Ultimately the utilization of both scalability and modularity for each of the described layout methods may deliver a large amount of design flexibility to incorporate the mixed kelvin technique into a multitude of different applications, product footprints, and power level requirements.

The described layouts may be used as standalone single switch positions. They may also find use arranged as ‘building block’ switch positions to form a variety of power module topologies (half-bridge, full-bridge, three-phase, common source, common drain, etc.).

In aspects, a series arrangement of two linear paralleled, parallel flow switch positions forms a half-bridge. This method can achieve high levels of power density with smaller substrate sizes. Note that the signal chains could be on one side of the package, as shown, the other side, or both. One attractive option, not shown, would be to use the opposite side of the package for other signal functions, such as temperature, current, or overcurrent sensing.

It should be apparent that the other layouts can be used as building blocks in a similar manner to arrange themselves into a layout that best suits the need of a given system. In some cases, the same building block is used in both positions. In other cases, it could be conceived that multiple of the layout approaches would be used, depending on the specific switch position.

Typically, power modules may be identified as one of the following categories.

Case module. In aspects, the case module implementation may include: Power substrate, devices, and terminals may be surrounded by a separate insulative housing or case and filled with an insulating element (gel, epoxy, and/or the like). In aspects, the Power substrate may or may not be attached to a base plate, cold plate, etc.

Overmolded module. In aspects, the overmolded module implementation may include: a Power substrate and devices attached to a lead frame and molded over with an epoxy molding compound or similar dielectric material.

Hermetic module. In aspects, the hermetic module implementation may include: a Power substrate and devices may be attached to a hermetic outer package, often a structure of metal, ceramic, and glass, then filled with a gel or epoxy, and sealed.

Hybrid module. In aspects, the hybrid module implementation may include: a combination of approaches that uses elements of multiple categories or is difficult to group in a single classification.

With respect to the disclosed method, the mixed kelvin approach is compatible with any packaging style. If devices are paralleled into a switch position, regardless of package structure, this method would be suitable. The following presents various case and overmolded power modules demonstrating implementation of this approach.

In an example embodiment of a single switch position package with arrayed power devices. Structurally, it comprises of a power substrate, power devices, a lead frame which is directly attached to both the power substrate and the topsides of the devices, and wire bonds for the signal connections. The substrate may have two traces, one for the drain connection and one for the gate connection. The gate trace runs underneath the source clip attached to the device tops such that the gates can be bonded to the same pad and connected electrically. Dedicated terminals for the gate and source kelvin may be located on the lower right side. Wire bonds connect the gate terminal down to a gate trace on the power substrate. Gates may be bonded out with a shared stitched bond per leg of devices. A wire bond from the source kelvin terminal to the lower right device forms the true kelvin connection, with the partial connection achieved through the source power terminal which is attached to the topsides of the devices (and runs over the gate trace on the substrate).

Depending on manufacturing method and layout, the signal bonding may be approached in a variety of manners. In some cases, the gate terminal is bonded directly to a trace on the power substrate. The device gates may be then wire bonded to this trace, forming an electrical connection. In some cases, the gate terminal is bonding both to the signal trace on the substrate as well as directly to the gates of the power devices. Examples of these different bonding strategies in the case that the bonding regions may be linear (or slightly angled).

Depending on manufacturing method and layout, the bonding regions of the signal terminals may be nested together in an L-bend. An L-bend is an attractive solution if the wire angles need to be shifted over to make room for other elements used in manufacturing, like hold down pins and clamps.

In some cases, the gate bonds may be stitched with a single daisy chained bond. Alternatively, the gates can be bonded individually. In some cases, the partial kelvin paths through the power source terminal directly attached to the device topsides is sufficient for effective operation. In other cases, further inductance reduction and shared path overlap can be achieved with additional wire bonds connecting source to source pads on the power devices.

In aspects, the disclosure is directed to a half bridge power module with a linear array of power devices. Structurally, it comprises of a base plate, power substrate, power devices, terminals attached to the power substrate, wire bonds for the signal connections, and wire bonds (or similar high current interconnection method) for the power connections. Being a half-bridge, there may be three power terminals and four or more signal terminals, and their associated traces on the power substrate. Gate bonds may be stitched from gate pad to gate pad on each switch position, down to a trace on the power substrate. They may also be bonded directly to the signal terminal in some cases. Source kelvin bonds may be formed similarly, stitched from source pad to source pad and to a trace on the power substrate or directly to the signal terminal. Here, the first source kelvin bond is a true kelvin, while the remaining may be partial kelvins.

In aspects, the disclosure is directed to a half bridge power module with a linear array of power devices. In this case, power flows from both sides of the package to balance inductances between the paralleled devices. Structurally, it comprises of a power substrate, power devices, a lead frame which is directly attached to both the power substrate and the topsides of the devices, and wire bonds for the signal connections. The substrate may have two traces, one for the drain connection and one for the gate connection. In this case, ‘rails’ on the lead frame span the length of the footprint to allow for individual gate bonds for each power device. A smaller terminal is used to deliver true kelvin bonds to some of the devices. Jumper bonds between the devices deliver the partial kelvin connection to the rest.

For this module type, the mixed kelvin approach allows for the source kelvin terminal to be much smaller than what it would be if each device needed a true kelvin. This allows for a few opportunities for flexibility in how the signal terminals may be configured and used.

Here, an additional terminal can be added to the source terminal to be used for current sensing. Alternatively, that pin location could be used as a secondary linkage to the long gate bonding rail, providing stability to improve manufacturability. Other possibilities, not pictured, are less pins (just the two on each side required for operation) or more pins (for additional sensing capability, such as temperature sense, could be conceived.

In aspects, a half bridge power module with a linear array of power devices. Structurally, it comprises of a base plate, power substrate, power devices, terminals attached to the power substrate, wire bonds for the signal connections, wire bonds (or similar high current interconnection method) for the power connections, and a plastic or similar dielectric housing. Not pictured are a lid and fasteners. The power terminals are shown as unfolded to show detail of the layout. Often, they will be folded over flat after the lid is attached.

Being a half-bridge, there may be three power terminals and four signal terminals, and their associated traces on the power substrate. Gate bonds may be stitched from gate pad to gate pad on each switch position and over to a signal terminal (as pictured) or to an interstitial trace on the substrate which would then be bonded up to the terminal. Source kelvin bonds may be formed similarly, stitched from source pad to source pad and to a trace on the power substrate or directly to the signal terminal or to an interstitial substrate trace. Here, the first source kelvin bond is a true kelvin, while the remaining may be partial kelvins.

In aspects, a half bridge power module with a linear array of power devices may be implemented. Structurally, it comprises of a base plate, power substrate, power devices, terminals attached to the power substrate, wire bonds for the signal connections, wire bonds (or similar high current interconnection method) for the power connections, and a plastic or similar dielectric housing. Not pictured are a lid and fasteners. The power terminals are shown as unfolded to show detail of the layout. Often, they will be folded over flat after the lid is attached.

For this layout, the AC trace runs underneath the V-terminal, which the V-terminal electrically isolated from the AC trace from the housing. Similar to the previous example, the gates and source pads may be stitched together and bonded over to a signal terminal (as shown) or to an interstitial pad on the power substrate. Signal terminals may be embedded into the plastic, as pictured, but may also be glued, bonded, etc. For this layout, some accessory bonds may be used for overcurrent protection, temperature sensing, and the like.

From the various layouts detailed in this disclosure, the modularity, the scalability, and the example embodiments, it should be apparent that this method is highly flexible to be applied to nearly any power electronics module that parallels devices. It allows for simplified layouts and methods to improved product function through better thermal performance to methods to reduce cost by the elimination of dedicated signal substrates.

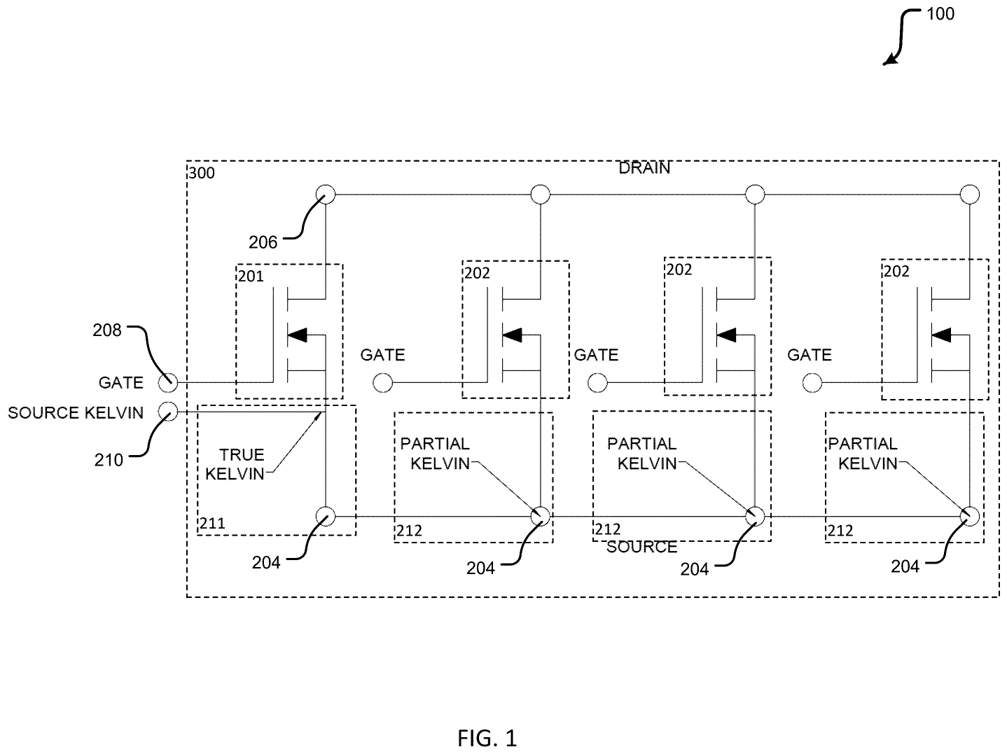

FIG. 1 illustrates a schematic of a power module according to aspects of the disclosure.

In particular, FIG. 1 illustrates a schematic of a power module 100 according to aspects of the disclosure. In aspects, the power module 100 may include at least one first power device 201 and at least one second power device 202. Further, the power module 100 may include at least one true Kelvin interconnection 211 and at least one pseudo-kelvin interconnection 212. Additionally, the power module 100 may include a power substrate 300.

In aspects, the at least one first power device 201 and the at least one second power device 202 may be arranged on the power substrate 300. In aspects, the at least one first power device 201 and the at least one second power device 202 may be attached to the power substrate 300. In aspects, the at least one first power device 201 and the at least one second power device 202 may be attached directly to the power substrate 300.

In aspects, there may be any number of the at least one first power device 201 arranged on the power substrate 300. In aspects, there may be any number of the at least one first power device 201 arranged on and along a first axis of the power substrate 300. In aspects, there may be any number of the at least one first power device 201 arranged on and along a second axis of the power substrate 300. In aspects, there may be any number of the at least one first power device 201 arranged on and along a first axis of the power substrate 300; and there may be any number of the at least one first power device 201 arranged on and along a second axis of the power substrate 300.

In aspects, there may be any number of the at least one second power device 202 arranged on the power substrate 300. In aspects, there may be any number of the at least one second power device 202 arranged on and along a first axis of the power substrate 300. In aspects, there may be any number of the at least one second power device 202 arranged on and along a second axis of the power substrate 300. In aspects, there may be any number of the at least one second power device 202 arranged on and along a first axis of the power substrate 300; and there may be any number of the at least one second power device 202 arranged on and along a second axis of the power substrate 300.

Further, the at least one first power device 201 and the at least one second power device 202 may each include a source connection 204. Additionally, the at least one first power device 201 and the at least one second power device 202 may each include a drain connection 206. In aspects, the drain connection 206 may be connected to the power substrate 300. In aspects, the drain connection 206 may be directly arranged on the power substrate 300.

Further, the at least one first power device 201 and the at least one second power device 202 may each include a gate connection 208. In this regard, only one implementation of the gate connection 208 is denoted by a reference numeral for ease of illustration.

Further, the power module 100 may include a source kelvin terminal 210. In aspects of the power module 100, the source connection 204 and the drain connection 206 may include respective power terminals. In aspects of the power module 100, the gate connection 208, and/or the source kelvin terminal 210 may include and/or may be implemented by respective signal terminals in and/or on the power module 100.

In aspects, the at least one first power device 201 may be configured to be implemented with the at least one true Kelvin interconnection 211; and the at least one second power device 202 may be configured to be implemented with the at least one pseudo-kelvin interconnection 212. As illustrated in FIG. 1, the power module 100 may implement a single implementation of the at least one first power device 201 and a single implementation of the at least one true Kelvin interconnection 211. In other aspects, the power module 100 may include multiple implementations of the at least one first power device 201 and may include multiple implementations of the at least one true Kelvin interconnection 211.

Further, the power module 100 may implement a plurality of the at least one second power device 202 and a plurality of the at least one pseudo-kelvin interconnection 212. In other aspects, the power module 100 may implement a single implementation of the at least one second power device 202 and a single implementation of the at least one pseudo-kelvin interconnection 212.

As further illustrated in FIG. 1, the at least one true Kelvin interconnection 211 may connect the at least one first power device 201 to the source kelvin terminal 210. In aspects, the at least one true Kelvin interconnection 211 may connect the at least one first power device 201 directly to the source kelvin terminal 210. In aspects, the at least one true Kelvin interconnection 211 may connect the source connection 204 of the at least one first power device 201 to the source kelvin terminal 210. In aspects, the at least one true Kelvin interconnection 211 may connect the source connection 204 of the at least one first power device 201 directly to the source kelvin terminal 210.

In aspects, the at least one true Kelvin interconnection 211 may connect the at least one first power device 201 to the source kelvin terminal 210 and may be configured to be electrically isolated from a power loop of the power module 100 and/or the at least one first power device 201. In aspects, the at least one true Kelvin interconnection 211 may be configured to be electrically isolated from a power loop of the power module 100 and/or the at least one first power device 201. In aspects, the at least one true Kelvin interconnection 211 may be configured to be electrically isolated from a power loop of the power module 100 and/or the at least one first power device 201 such that a current flow of the power loop does not also flow through the at least one true Kelvin interconnection 211.

Additionally, the at least one pseudo-kelvin interconnection 212 may connect the at least one second power device 202 indirectly to the source kelvin terminal 210. In aspects, the at least one pseudo-kelvin interconnection 212 may connect the source connection 204 of the at least one second power device 202 indirectly to the source kelvin terminal 210.

In aspects, the at least one pseudo-kelvin interconnection 212 may connect the at least one second power device 202 through the at least one true Kelvin interconnection 211. In aspects, the at least one pseudo-kelvin interconnection 212 may connect the source connection 204 of the at least one second power device 202 through the at least one true Kelvin interconnection 211. In aspects, the at least one pseudo-kelvin interconnection 212 may connect to the source connection 204 of the at least one first power device 201.

In aspects, the at least one pseudo-kelvin interconnection 212 may connect the source connection 204 of the at least one second power device 202 through a power loop of the power module 100 and/or the at least one second power device 202. In aspects, the at least one pseudo-kelvin interconnection 212 may be configured as part of a power loop of the power module 100 such that a current flow of the power loop also flows through at least a portion the at least one pseudo-kelvin interconnection 212.

The source kelvin terminal 210, the at least one pseudo-kelvin interconnection 212 and the at least one true Kelvin interconnection 211 may be utilized for achieving fast, clean, and efficient switching of the at least one first power device 201 and the at least one second power device 202 implemented as paralleled power electronic devices in the power module 100, which may not readily allow true source kelvin interconnection for each individual power device without needing additional elements such as signal substrates, complex signal routing, and/or the like.

Here, a true source kelvin may be delivered with the at least one true Kelvin interconnection 211 to one or more (but not all) of the power devices. In particular, a true source kelvin may be delivered with the at least one true Kelvin interconnection 211 to the power devices that include the at least one first power device 201.

Further, the remaining signal loops implemented by the at least one pseudo-kelvin interconnection 212 may share a partial path with a power loop of the at least one first power device 201 and/or the at least one second power device 202. In aspects of the power module 100, the shared path may travel a minimal distance with minimal influence from the power path due to a low common mode inductance.

Effectively, the power module 100 implementing the at least one true Kelvin interconnection 211 and the gate pad 232 may operate such that the at least one first power device 201 may start the turn-on and turn-off events faster and without interference, with the at least one second power device 202 following suit. This may improve efficiency, better stabilize oscillations, act to prevent gate voltages from drifting outside of their Safe Operating Area (SOA), and/or the like of the power module 100. The disclosed implementation of the at least one true Kelvin interconnection 211 and the at least one pseudo-kelvin interconnection 212 may help to mitigate and lessen the compromises when a true kelvin for each individual device is not possible or not practical.

In general, fast switching devices, such as Silicon Carbide (SiC) MOSFETs, may benefit from true source kelvin connections such as implemented by the at least one true Kelvin interconnection 211. In particular, the at least one true Kelvin interconnection 211 may be implemented such that there is no shared path through the power loop of the power module 100, for the most optimal switching performance. However, certain package structures may not be well suited for dedicated kelvin bonds for every device in parallel. This can be due to a terminal location, layout restrictions, device area, interconnection methods, cost targets, and/or the like and combinations thereof.

In these cases, implementation of the at least one pseudo-kelvin interconnection 212 as a partial or pseudo kelvin connection may be formed for implementations of the at least one second power device 202 where some of the signal loop is shared with the power loop. The more physical and electrical separation between the two paths, the less the effects of the common mode inductance may have on the ability to switch effectively. Effects can further be minimized in some aspects of the power module 100 by running signal currents in one direction and running the power in an orthogonal direction to further reduce interactions from a magnetic field.

Here, one or more devices implemented as the at least one first power device 201 may be implemented with the at least one true Kelvin interconnection 211, most often the edge device of a paralleled strand, such that the at least one first power device 201 may be bonded with a true kelvin bond. The neighboring devices implemented by the at least one second power device 202 and may be bonded such that the remaining paths the signals follow share some but limited path with the power interconnections through implementation of the at least one pseudo-kelvin interconnection 212, taking advantage of the minimal shared path distance achieved through the true kelvin bonded device.

In aspects, the power module 100 may include: a mixed kelvin configuration for providing a true kelvin connection to at least one device in a switch position. More specifically, the power module 100 may implement a true kelvin connection with the at least one true Kelvin interconnection 211 to the at least one first power device 201.

In aspects, the power module 100 may implement a low inductance pseudo kelvin connection to remaining devices in a switch position. More specifically, the power module 100 may implement a low inductance pseudo kelvin connection with the at least one pseudo-kelvin interconnection 212 to the at least one second power device 202 in a switch position.

In aspects, the at least one true Kelvin interconnection 211 may be configured as a true source kelvin interconnection to gate and source pads on the at least one first power device 201 through one or more wire bonds, ribbons, laminate overlays, direct attaches, and/or the like. In aspects, the at least one true Kelvin interconnection 211 may be configured as a true source kelvin interconnection to gate and source pads on the at least one first power device 201 through a combination of two or more wire bonds, ribbons, laminate overlays, direct attaches, and/or the like.

In aspects, the at least one true Kelvin interconnection 211 may be configured as a true source kelvin interconnection between the source connection 204 and the source kelvin terminal 210. In aspects, the at least one true Kelvin interconnection 211 may be configured between the source connection 204 and the source kelvin terminal 210 as one or more wire bonds, one or more wire bonds and signal traces, and/or the like.

In particular aspects, the source kelvin terminal 210 may be connected to a signal trace and the at least one true Kelvin interconnection 211 may be wire bonded to the signal trace that the source kelvin terminal 210 is connected.

In aspects, the at least one pseudo-kelvin interconnection 212 may be configured as a partial or pseudo kelvin interconnection to source pads on the at least one second power device 202 through wire bonds, ribbon, laminate overlay, direct attach, and/or the like. In aspects, the at least one pseudo-kelvin interconnection 212 may be configured as a partial or pseudo kelvin interconnection to source pads on the at least one second power device 202 through a combination of two or more wire bonds, ribbon, laminate overlay, direct attach, and/or the like.

In aspects, the at least one pseudo-kelvin interconnection 212 may be configured as a partial or pseudo kelvin interconnection to source pads on the at least one second power device 202; and the at least one pseudo-kelvin interconnection 212 may be connected to the at least one true Kelvin interconnection 211. In aspects, the at least one pseudo-kelvin interconnection 212 may be connected to the at least one true Kelvin interconnection 211 through one or more wire bonds between the at least one first power device 201 and the at least one second power device 202, one or more wire bonds connecting between different implementations of the at least one second power device 202, stitched wire bonds connecting between different implementations of the at least one second power device 202, and/or the like.

In aspects, the at least one pseudo-kelvin interconnection 212 may be connected to the at least one true Kelvin interconnection 211 through one or more clips between the at least one first power device 201 and the at least one second power device 202. In aspects, the at least one pseudo-kelvin interconnection 212 may be connected to the at least one true Kelvin interconnection 211 through one or more clips between different implementations of the at least one second power device 202.

In aspects, the at least one pseudo-kelvin interconnection 212 may be connected to the at least one true Kelvin interconnection 211 through one or more jumpers between the at least one first power device 201 and the at least one second power device 202. In aspects, the at least one pseudo-kelvin interconnection 212 may be connected to the at least one true Kelvin interconnection 211 through one or more jumpers between different implementations of the at least one second power device 202.

In aspects, the power module 100 may be configured with structures and layout implementations for linear arrangements of the at least one first power device 201 and/or the at least one second power device 202. In aspects, the power module 100 may be configured with structures and layout implementations for arrayed arrangements of the at least one first power device 201 and/or the at least one second power device 202.

In aspects, the power module 100 may be configured with structures and layout implementations for single switch, half-bridge, and three phase topologies; gate interconnection using individual wire bonds; gate interconnection using daisy chained wire bonds.

In aspects, the power module 100 may be configured with a mixed kelvin enablement through implementation of the at least one pseudo-kelvin interconnection 212 that may include a shared power path through a source clip attach, jumper wire bonds, daisy chained wire bonds, and/or the like. In aspects, the power module 100 may be configured with scalability through compatibility with many device sizes and pad layouts; scalability through adding or removing devices in the paralleled strand; modularity though fully and partially populated switch positions; flexibility to be applied to most power electronic module layouts which parallel devices; embodiments on single switch position packages; and/or embodiments on half-bridge packages.

In aspects, there may a single implementation of the at least one first power device 201 arranged on the power substrate 300. In aspects, there may a single implementation of the at least one first power device 201 arranged on the power substrate 300 and no implementations of the at least one second power device 202. In aspects, there may be a single implementation of the at least one second power device 202 arranged on the power substrate 300. In aspects, there may be a single implementation of the at least one second power device 202 arranged on the power substrate 300 and no implementations of the at least one first power device 201.

In aspects of the power module 100, the at least one first power device 201, the at least one second power device 202, the at least one true Kelvin interconnection 211, the at least one pseudo-kelvin interconnection 212, and/or the like illustrated in FIG. 1 and described in relation to FIG. 1 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIG. 1 and described in relation to FIG. 1.

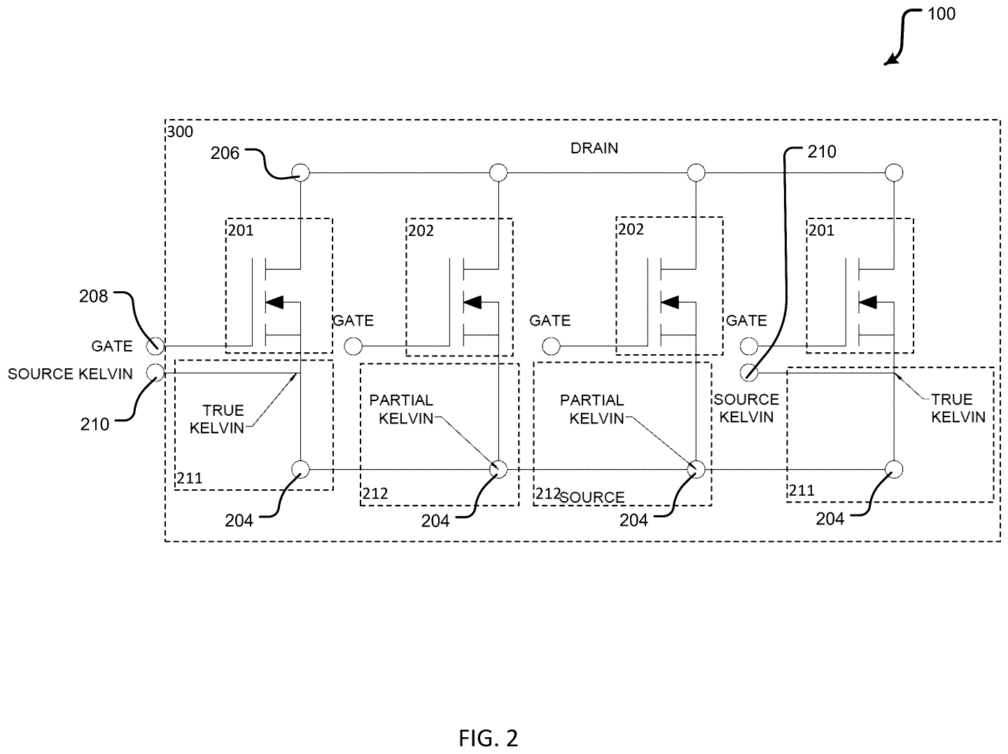

FIG. 2 illustrates a schematic of a power module according to aspects of the disclosure.

In particular, FIG. 2 illustrates a schematic of a power module 100 according to aspects of the disclosure. In this regard, FIG. 2 illustrates an aspect of the power module 100 that may have two implementations of the at least one true Kelvin interconnection 211 and two implementations of the at least one first power device 201.

Further, FIG. 2 illustrates an aspect of the power module 100 that may have two implementations of the source kelvin terminal 210. In other aspects, the power module 100 may implement a single implementation of the source kelvin terminal 210.

In aspects of the power module 100, the at least one first power device 201, the at least one second power device 202, the at least one true Kelvin interconnection 211, the at least one pseudo-kelvin interconnection 212, and/or the like illustrated in FIG. 2 and described in relation to FIG. 2 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIG. 2 and described in relation to FIG. 2.

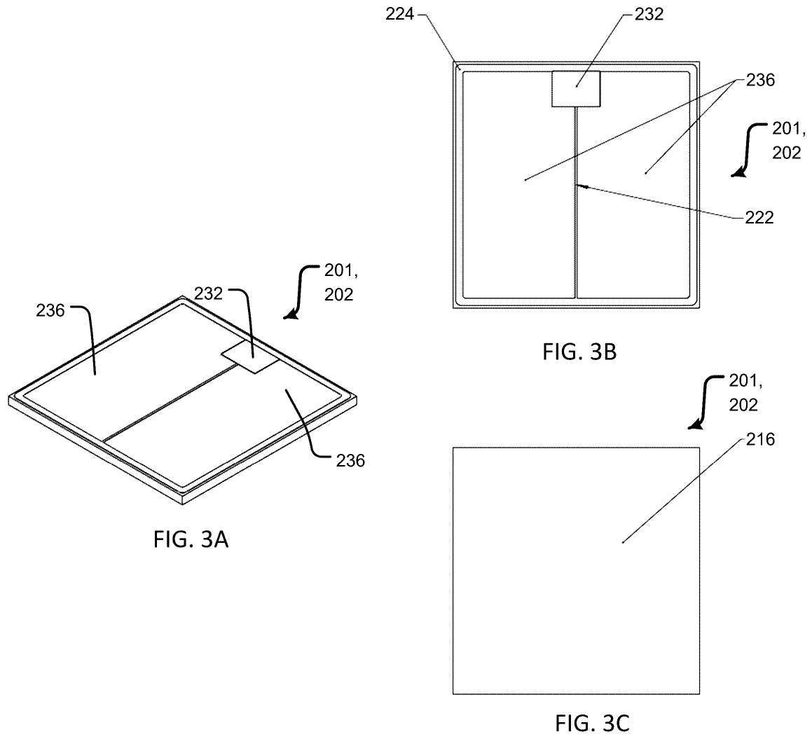

FIG. 3A is a perspective view of an exemplary power device according to aspects of the disclosure, FIG. 3B is a top view of the exemplary power device of FIG. 3A, and FIG. 3C is a bottom view of the exemplary power device of FIG. 3A.

In particular, FIGS. 3A-3B illustrate an exemplary power device that may be utilized to implement the at least one first power device 201 and/or the at least one second power device 202 of the power module 100. In aspects, the power module 100 may implement numerous layouts. For example, an exemplary implementation of the at least one first power device 201 and/or the at least one second power device 202 may be a MOSFET with three terminal pads: a gate pad 232, at least one source pad 236, and a drain pad 216. In aspects, the at least one source pad 236 may form the source connection 204. In aspects, the drain pad 216 may form the drain connection 206.

On the topside of the at least one first power device 201 and/or the at least one second power device 202, there may be the gate pad 232, gate runner(s) 222, and the at least one source pad 236. In aspects, the gate runner(s) 222 may be used to better distribute the gate across the device area and may run along the perimeter of the device as well as one or more multiple runners across and inner region. The topside may have an insulating layer 224, that may be implemented as a polyimide, that may protect surfaces and may provide electrical isolation. The backside of the device may be the drain pad 216. Note that this is a simplified description and illustration of the at least one first power device 201 and/or the at least one second power device 202 with respect to a package layout of the power module 100. There may be many other functional elements and layers in the at least one first power device 201 and/or the at least one second power device 202 that may not be relevant to the disclosure and accordingly not represented or called out.

In aspects, the insulating layer 224 may be a topside polyimide, or similar insulating material, and may be patterned to facilitate a given interconnection method, such as wire bonds, solder, sinter, and/or the like. As an example, if power wire bonding or ribbon bonding is used, the at least one source pad 236 may be best left open as much as possible to allow for optimal bonding area. In other cases, power contacts may be directly attached as a clip to the at least one source pad 236 and wire bonds connect to the gate pad 232. Here, the insulating layer 224, such as a polyimide, may be used to keep solder or similar attach material for the power clip from spreading onto the wire bonding pads. Note that the at least one source pad 236 may be still connected, just masked off on top through the insulating layer 224. In aspects, the insulating layer 224 may be implemented as a polyimide pattern for clip attach, which may be used for simplicity. For aspects of the power module 100, any device pad arrangement, device size, aspect ratio, and/or the like may be compatible.

In aspects of the power module 100, the at least one first power device 201 and the at least one second power device 202 illustrated in FIGS. 3A-3B and described in relation to FIGS. 3A-3B may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the at least one first power device 201 and/or the at least one second power device 202 illustrated in FIGS. 3A-3B and described in relation to FIGS. 3A-3B.

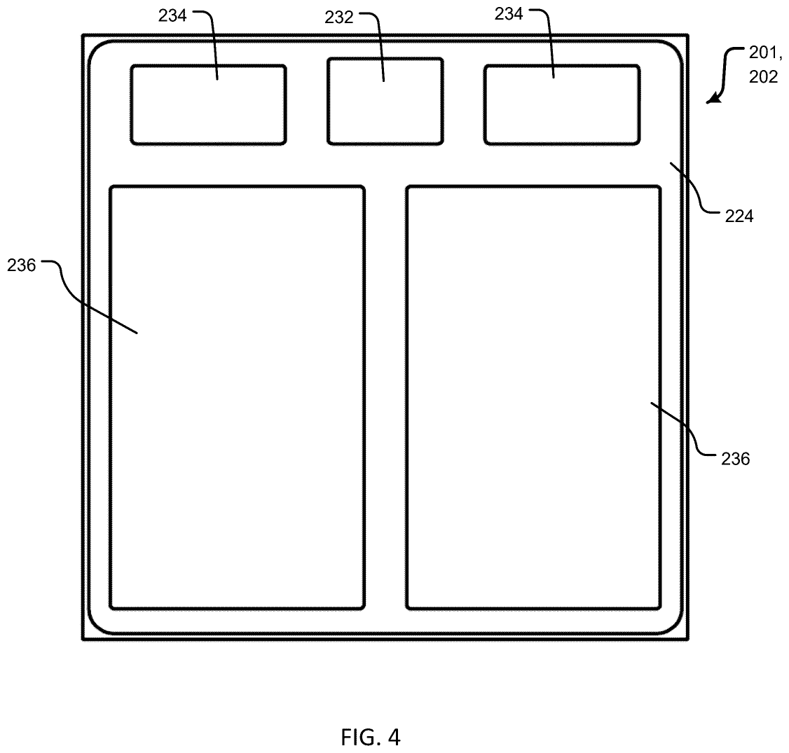

FIG. 4 is a top view of another exemplary power device according to aspects of the disclosure.

In particular, FIG. 4 illustrate another exemplary power device that may be utilized to implement the at least one first power device 201 and/or the at least one second power device 202 of the power module 100. In aspects, the power module 100 may implement numerous layouts. For example, an exemplary implementation of the at least one first power device 201 and/or the at least one second power device 202 may be a MOSFET with terminal pads that may include: the gate pad 232, the at least one source pad 236, the drain pad 216, and at least one source kelvin pad 234. In aspects, the at least one source pad 236 may form the source connection 204. In aspects, the drain pad 216 may form the drain connection 206.

In aspects of the power module 100, the at least one first power device 201 and the at least one second power device 202 illustrated in FIG. 4 and described in relation to FIG. 4 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the at least one first power device 201 and/or the at least one second power device 202 illustrated in FIG. 4 and described in relation to FIG. 4.

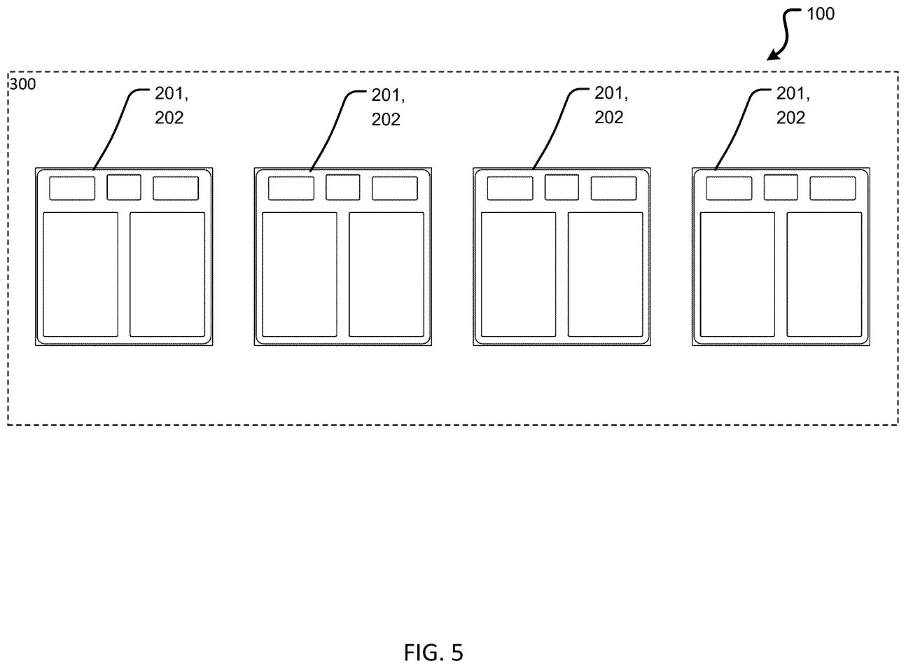

FIG. 5 is a top view of an exemplary power device arrangement of a power module according to aspects of the disclosure.

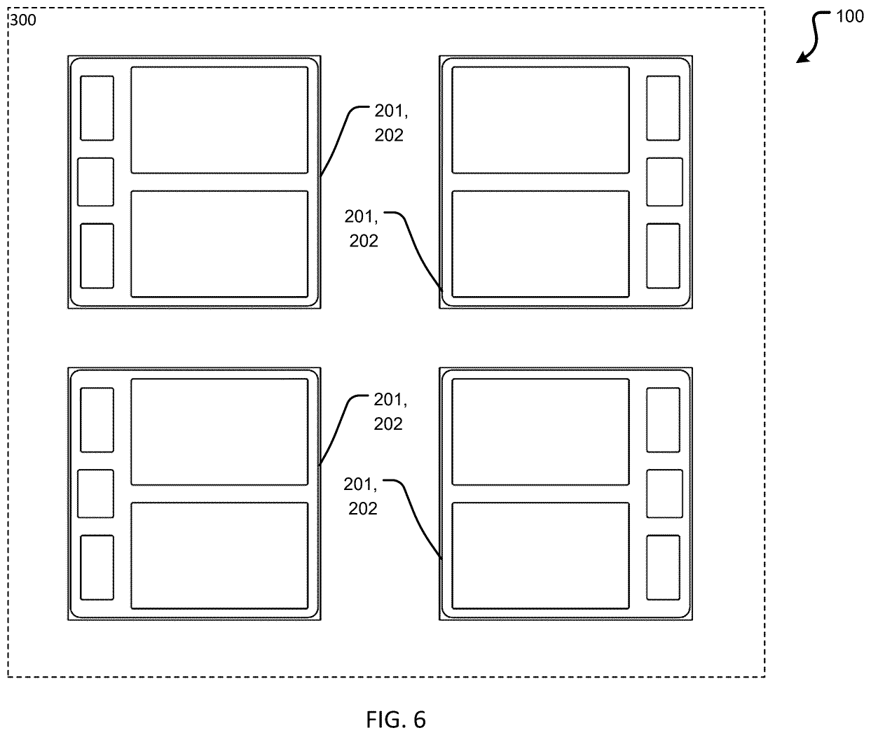

FIG. 6 is a top view of another exemplary power device arrangement of a power module according to aspects of the disclosure.

In aspects of the disclosure, the power module 100 may implemented the at least one first power device 201 and/or the at least one second power device 202 such that these devices may be paralleled to increase the amount of output current. In aspects of the power module 100, there may be a number configurations paralleling the at least one first power device 201 and/or the at least one second power device 202. In aspects, the configurations paralleling the at least one first power device 201 and/or the at least one second power device 202 may include:

Linear arrangement, linear power flow, where: power flows from one side of a strand to the other. This arrangement may be used when many devices (≥4) are paralleled; and/or may be used in existing industry standard footprints.

Linear arrangement, parallel power flow, where: devices in a strand in one direction; power flows evenly across the strand; maybe used when many devices (≥4) are paralleled; and/or may be used in low inductance, high performance packages.

Arrayed, where: devices may be arranged on a grid in two directions; power can flow in either or both directions; may be used with smaller device counts (≤6) that are paralleled; and/or may be used in small footprint, high performance packages.

As illustrated in FIG. 5, the power module 100 may implement the at least one first power device 201 and/or the at least one second power device 202 with a linear paralleling; and as illustrated in FIG. 6, the power module 100 may implement the at least one first power device 201 and/or the at least one second power device 202 with an arrayed paralleling. In aspects, a number of devices implemented by the power module 100 can be arbitrary with linear arrangements being more than two devices, and arrayed arrangements being at least four devices. In aspects of the power module 100, the arrays can be of arbitrary size, such as 2×2 (four devices), 2×3 (six devices), etc.

In aspects of the power module 100 set forth in the disclosure, layouts for the paralleling methods are disclosed. In aspects of FIG. 5 and FIG. 6, a ‘standard’ power module stack-up including substrates, electrical terminals for the power and signal connections, and the power and signal interconnections may be utilized. Other elements, such as attach layers, housings, base plates, etc. are not shown for simplicity, but are contemplated by this disclosure for implementation in a full system.

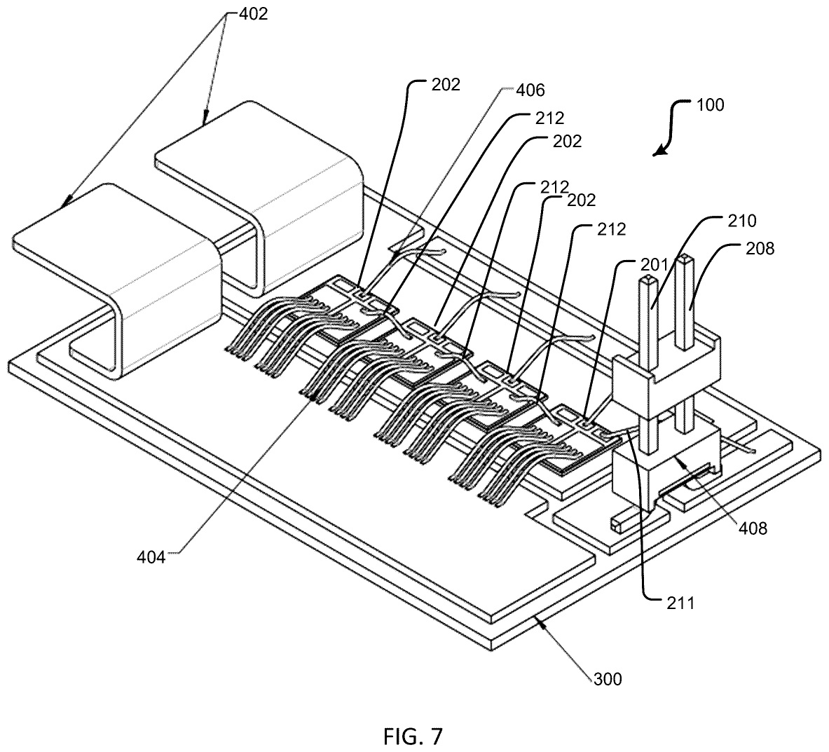

FIG. 7 illustrates a perspective view of aspects of a power module according to aspects of the disclosure.

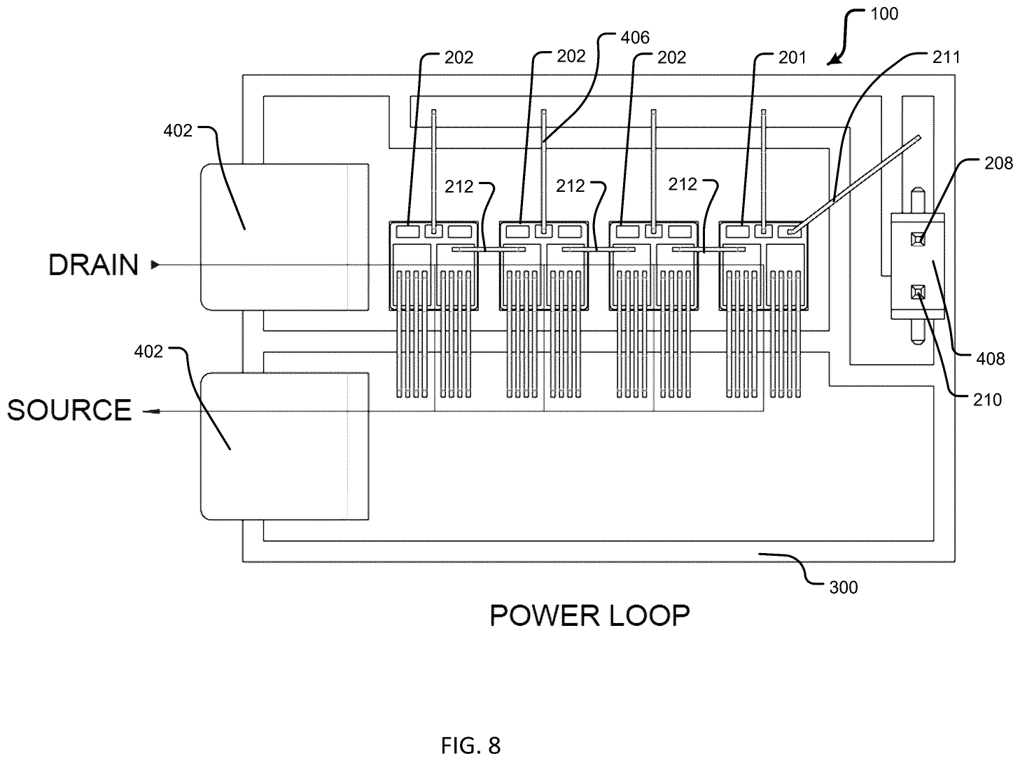

FIG. 8 illustrates a top view of the power module according to FIG. 7.

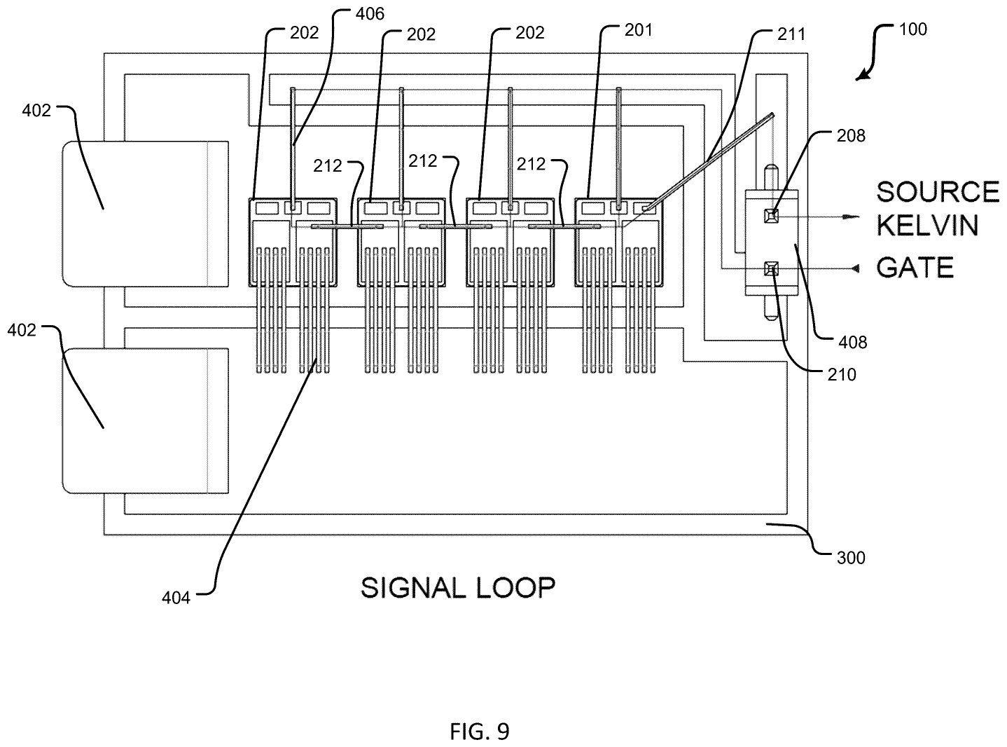

FIG. 9 illustrates another top view of the power module according to FIG. 7.

In particular, FIG. 7 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, and/or the like as previously described. Additionally, the power module 100 may include power terminals 402, power interconnections 404, signal interconnections 406, a signal terminal 408, and/or the like. The signal terminal 408 may include the gate connection 208 and the source kelvin terminal 210. In aspects, the signal terminal 408 may further include additional signal terminals for sensors, sensing, control, and/or the like (not shown).

Further, FIG. 7 illustrates an arrangement and configuration of implementations of the at least one pseudo-kelvin interconnection 212 with implementations of the at least one second power device 202 in the power module 100. Moreover, FIG. 7 illustrates an arrangement and configuration of the at least one true Kelvin interconnection 211 with an implementation of the at least one first power device 201. In aspects, implementations of the at least one pseudo-kelvin interconnection 212 may connect adjacent implementations of the at least one second power device 202; and an implementation of the at least one pseudo-kelvin interconnection 212 may connect an implementation of the at least one second power device 202 to and adjacent an implementation of the at least one first power device 201.

In this regard, FIG. 7 illustrates an implementation of the power module 100 having a mixed kelvin layout for a linear arrangement with linear power flow. Here, each implementation of the at least one first power device 201 and/or the at least one second power device 202 may have a dedicated gate wire bond implemented by the signal interconnections 406 over to a trace on the power substrate 300.

In aspects, a rightmost and/or leftmost device may have a true source kelvin bond from its source pad to a trace on the power substrate. In this regard, as illustrated in FIG. 7 this is implemented by the at least one first power device 201 implementing the at least one true Kelvin interconnection 211.

Additionally, partial kelvin connections may be formed through jumper wires from source pad of the true kelvin device to its neighbor, and then jumper wires from that device to its neighbor, and so on. As illustrated in FIG. 7, this is implemented by the implementations of the at least one pseudo-kelvin interconnection 212 for each of the at least one second power device 202. The jumpers implemented by the at least one pseudo-kelvin interconnection 212 may be separate wires, daisy chained stitch bond, and/or the like. These jumpers may shorten a distance a signal current must flow in a loop while minimizing the shared path with the power loop of the power module 100.

Additionally, the power module 100 may have a power loop as illustrated in FIG. 8 and a signal loop as illustrated in FIG. 9. In particular, the power module 100 may be configured such that the at least one first power device 201 and/or the at least one second power device 202 may be laid out linearly, with the power flowing in and out from the same side as illustrated in FIG. 8, while the signals flow in and out on one side as illustrated in FIG. 9. In aspects, the power module 100 may be configured such that the power terminals 402 may be on one side the power module 100, on opposite sides of the power module 100, or on both sides the power module 100. In aspects of the power module 100, the signal terminal 408 may be on the opposite side of the power module 100 from the signal terminal 408, as illustrated, the same side of the power module 100, or on both sides of the power module 100.

In aspects, the signal current may flow through the gate connection 208 of the signal terminal 408, through the trace on the power substrate 300, through dedicated gate bonds, through a gate network on the at least one first power device 201 and/or 202, through the source pads of the at least one first power device 201 and/or 202 to the at least one true Kelvin interconnection 211 and/or the at least one pseudo-kelvin interconnection 212, through to the trace on the power substrate 300, and finally out of the source kelvin terminal 210.

One device of the power module 100 may have a true kelvin with no overlap of the power loop, while the remaining devices of the power module 100 may have some overlap but minimal interaction with the drain-source current. In particular, the at least one first power device 201 may have a true kelvin implemented by the at least one true Kelvin interconnection 211 with no overlap of the power loop, while the remaining devices implemented by the at least one second power device 202 may implement the at least one pseudo-kelvin interconnection 212 with some overlap but minimal interaction with the drain-source current.

Accordingly, implementation of the power module 100 may allow for implementation of more efficient switching without needing to add a second trace on the power substrate 300, a lead frame, a signal substrate, and/or the like, which can take up room, add complexity, add cost, and/or the like for the power module 100.

In aspects of the power module 100, the at least one first power device 201, the at least one second power device 202, the at least one true Kelvin interconnection 211, the at least one pseudo-kelvin interconnection 212, and/or the like illustrated in FIG. 7, FIG. 8, and FIG. 9 and described in relation to FIG. 7, FIG. 8, and FIG. 9 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIG. 7, FIG. 8, and FIG. 9 and described in relation to FIG. 7, FIG. 8, and FIG. 9.

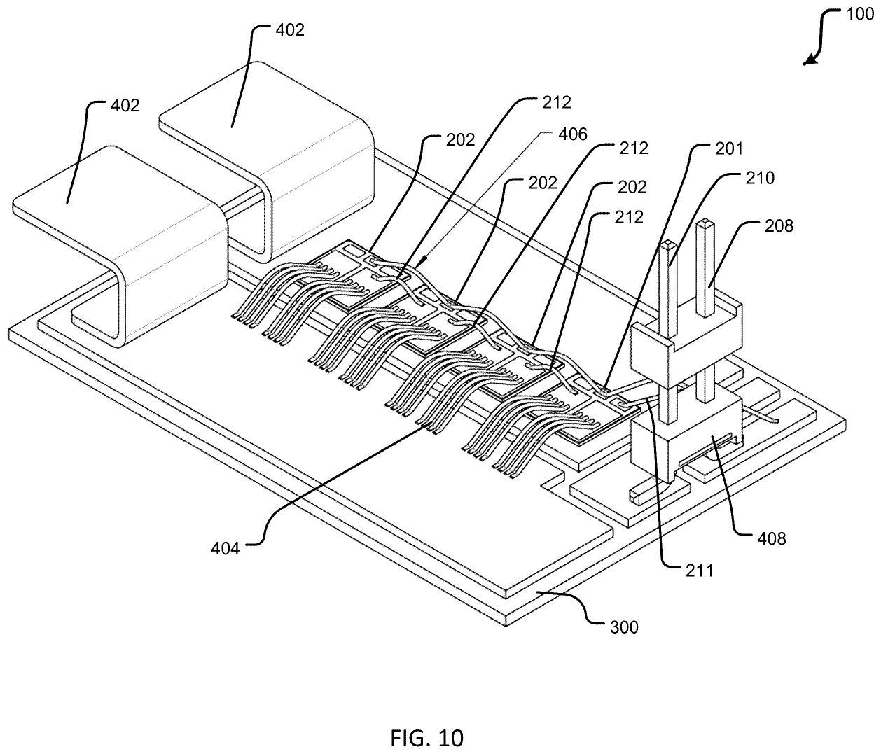

FIG. 10 illustrates a perspective view of a power module according to aspects of the disclosure.

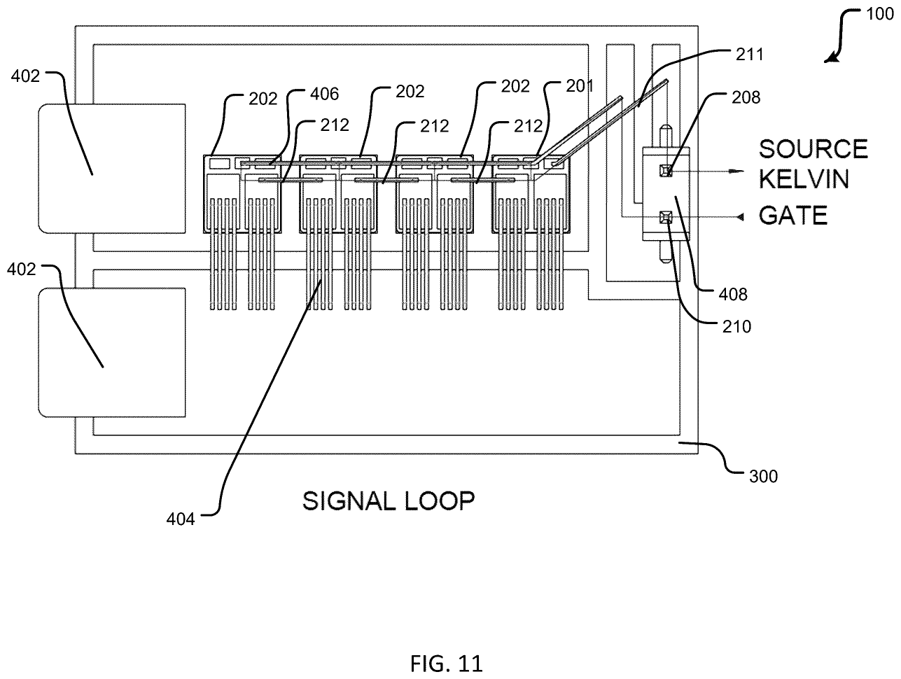

FIG. 11 illustrates a top view of the power module according to FIG. 10.

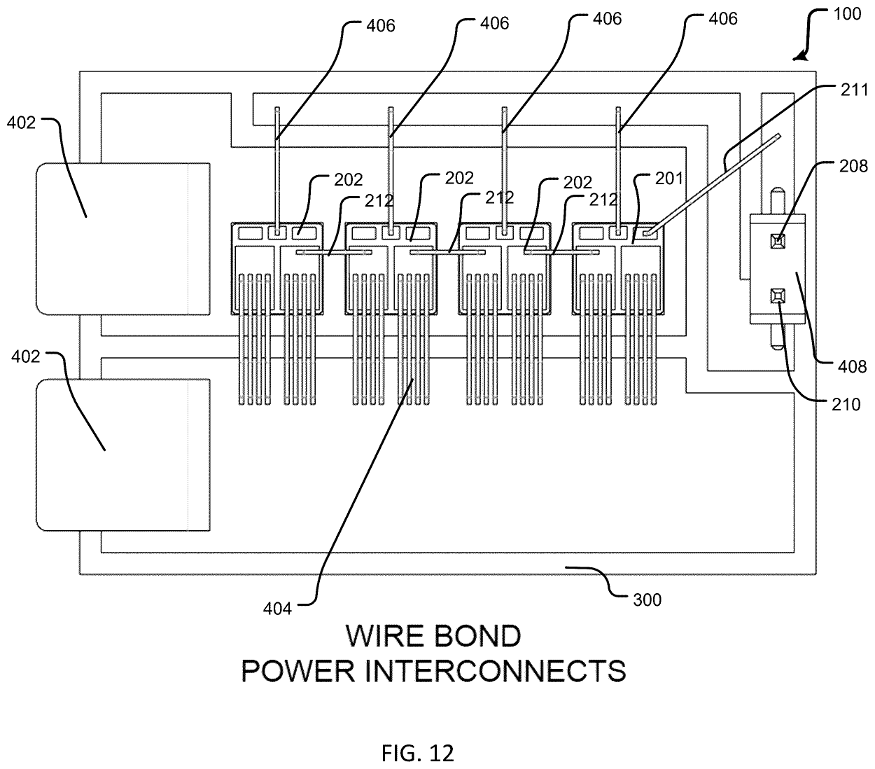

FIG. 12 illustrates another top view of the power module according to FIG. 10.

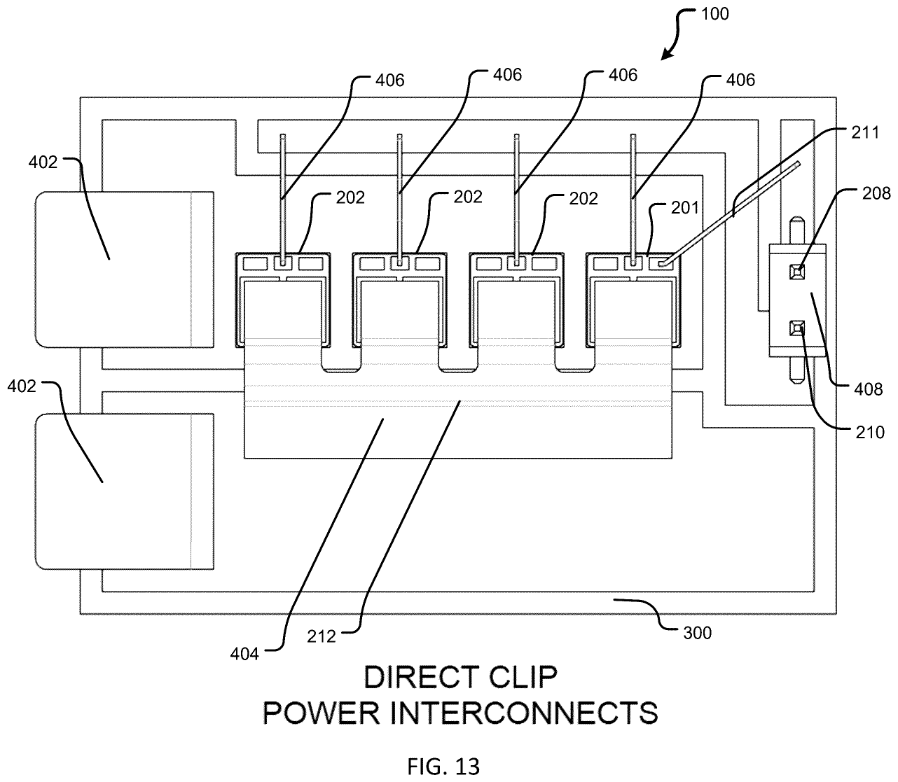

FIG. 13 illustrates another top view of the power module according to FIG. 10.

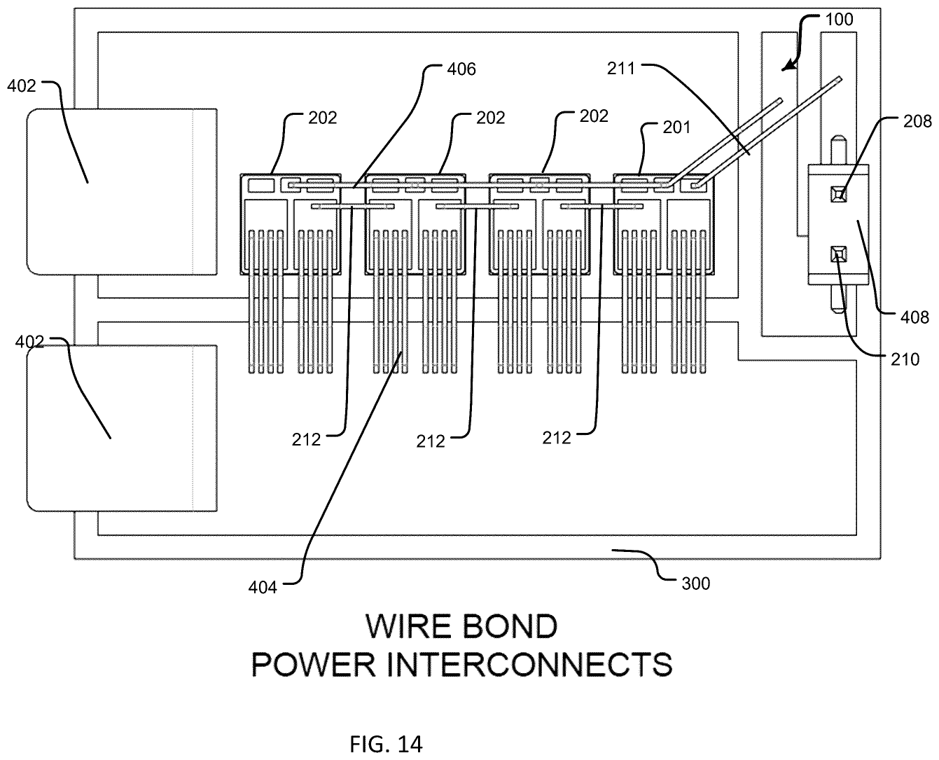

FIG. 14 illustrates another top view of the power module according to FIG. 10.

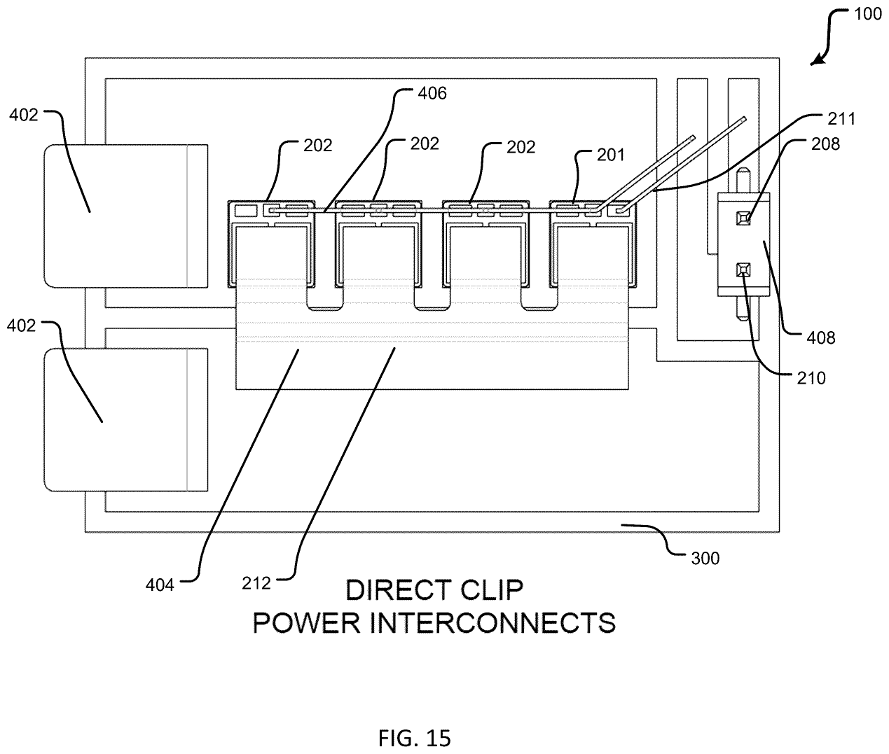

FIG. 15 illustrates another top view of the power module according to FIG. 10.

In particular, FIG. 10 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

With reference to FIG. 12-FIG. 15, the power loop can be achieved with wire bonds, a direct clip attach, and the like. In some cases, the clips may be a standalone element. In other cases, it is joined to power contacts, signal contacts, etc. as part of a larger lead frame. There may be tradeoffs associated with the interconnection method regarding performance, manufacturability, and cost. Of particular importance here is that the mixed kelvin approach is compatible with any power interconnection scheme.

In aspects of the power module 100, the at least one first power device 201, the at least one second power device 202, the at least one true Kelvin interconnection 211, the at least one pseudo-kelvin interconnection 212, and/or the like illustrated in FIG. 10 and described in relation to FIG. 10 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIG. 10 and described in relation to FIG. 10.

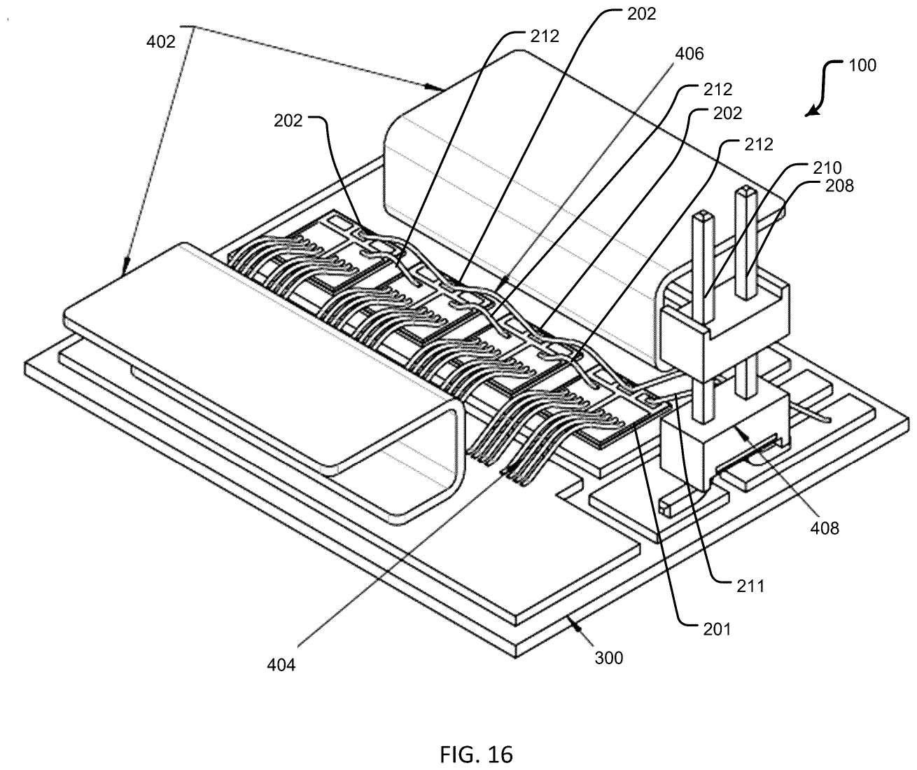

FIG. 16 illustrates a perspective view of a power module according to aspects of the disclosure.

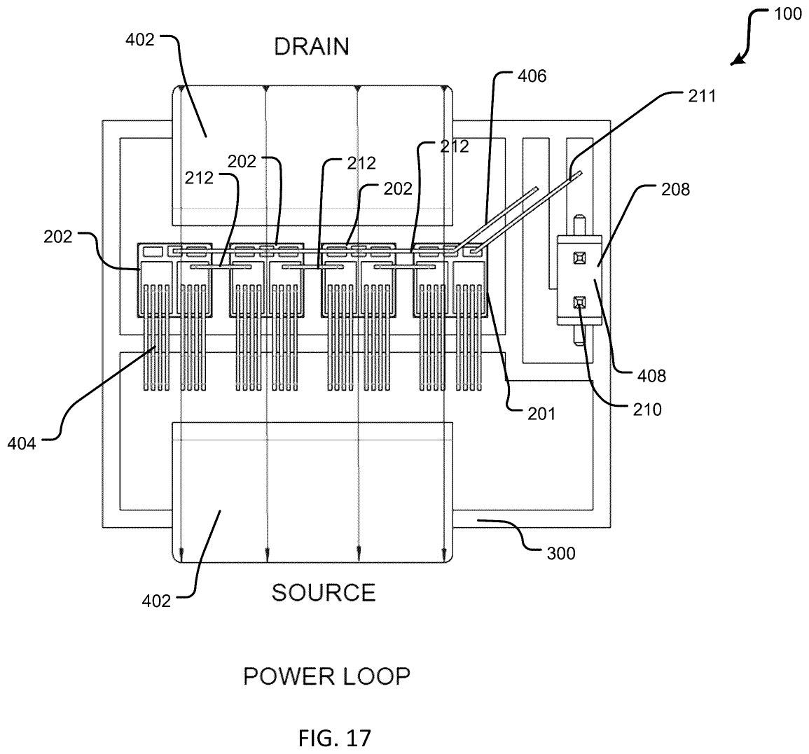

FIG. 17 illustrates a top view of the power module according to FIG. 16.

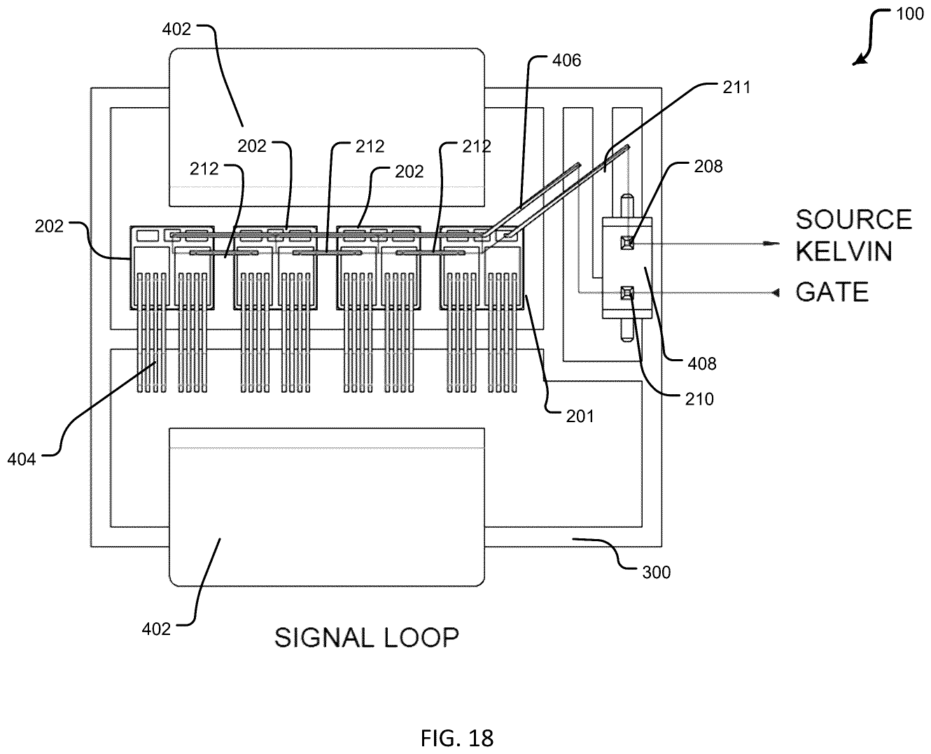

FIG. 18 illustrates another top view of the power module according to FIG. 16.

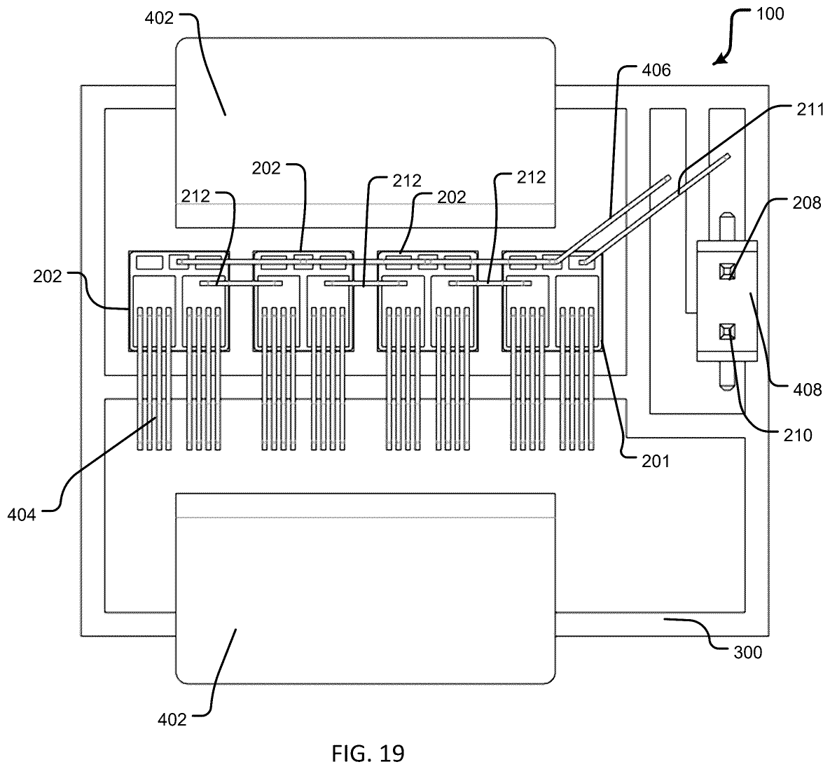

FIG. 19 illustrates another top view of the power module according to FIG. 16.

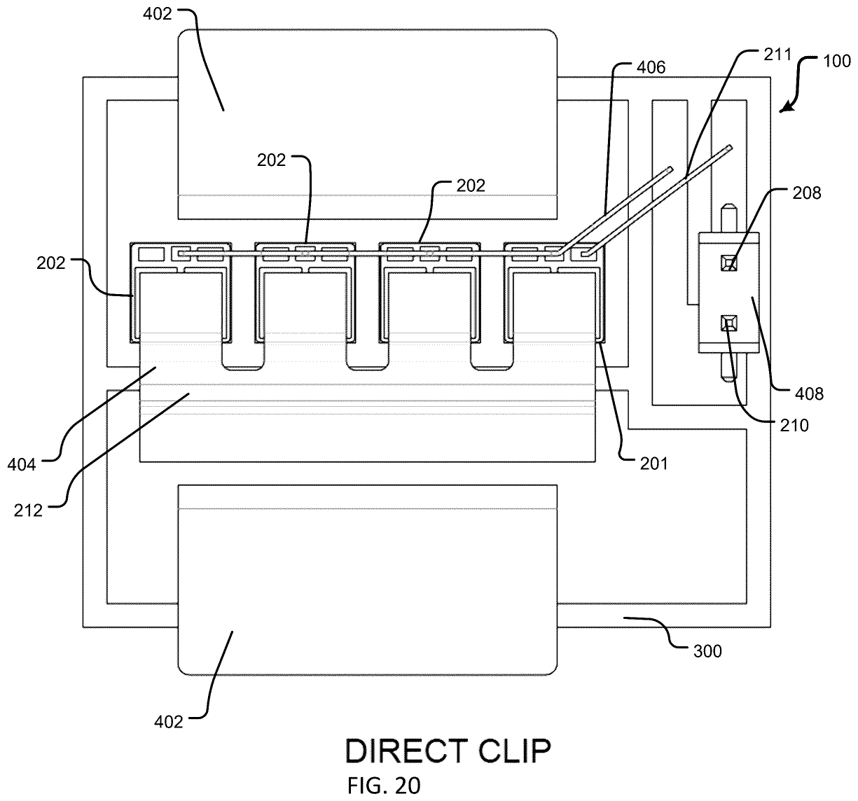

FIG. 20 illustrates another top view of the power module according to FIG. 16.

In particular, FIG. 16 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

With reference to FIG. 19 and FIG. 20, the power loop can be achieved with wire bonds, a direct clip attach, and the like. In some cases, the clips may be a standalone element. In other cases, it is joined to power contacts, signal contacts, etc. as part of a larger lead frame. There may be tradeoffs associated with the interconnection method regarding performance, manufacturability, and cost. Of particular importance here is that the mixed kelvin approach is compatible with any power interconnection scheme.

In aspects, the power module 100 may implement a linear arrangement, linear power flow. For example, a mixed kelvin layout for a linear arrangement with linear power flow. Here, each device may have a dedicated gate wire bond over to a trace on the power substrate. In aspects a rightmost and/or leftmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, daisy chained stitch bond, and/or the like. These jumpers may shorten the distance the signal current must flow in the loop while minimizing the shared path with the power loop.

In aspects of the power module 100, the power and signal loops may be laid out linearly, with the power flowing in and out from the same side, while the signals flow in and out on one side. The power terminals may be on one side, on opposite sides, or on both sides. The signal terminals may be on the opposite side of the power terminals, as pictured, the same side, or on both sides.

In aspects of the power module 100, the signal current may flow through the gate terminal, through the trace on the substrate, through the dedicated gate bonds, through the gate network on the devices, through the source pads of the devices to the wire bond jumpers, through to the trace on the substrate, and finally out of the source kelvin terminal. One device may have a true kelvin with no overlap of the power loop, while the remaining devices have some overlap but minimal interaction with the drain-source current. Notably through in this aspect of the power module 100, efficient switching can occur without needing to add a second trace on the substrate (or lead frame, signal substrate, etc.) which can take up room, add complexity, and add cost.

For further optimization of the power module 100, the gate pads on the devices can be stitch bonded together such that they all share the same linkage through a single daisy chained wire, removing the need for the dedicated gate trace on the substrate. In this aspect, this may not require gate or source kelvin traces, just a bonding pad on the substrate which may go to the signal connector. These bonding pads may also be removed in some cases where the signal terminal is wire bondable or the bonds may be formed directly from the devices to a lead frame. This approach may allow for further improvements in power density, reduced complexity, reduced cost, and/or the like. Also note that the gate and source kelvin loops in this aspect may be tightly coupled. For example, close in proximity and direction such that flux cancellation may reduce the overall loop inductance.

In aspects of the power module 100, a mixed kelvin layout may be implemented for a linear arrangement, linear power flow with stitched gate bonding. For either method of gate bonding, the power loop can be achieved with wire bonds, a direct clip attach, and the like. In some cases, the clip may be a standalone element or multiple elements. In other cases, it is joined to power contacts, signal contacts, and/or the like as part of a larger lead frame. There may be tradeoffs associated with the interconnection method regarding performance, manufacturability, and cost. Of particular importance here is that the mixed kelvin approach is compatible with any power interconnection scheme. In aspects, the disclosed device and process may implement a linear arrangement, parallel power flow

In aspects of the power module 100, a mixed kelvin layout for a linear arrangement with parallel power flow. Here, stitched gate bonding frees up the room which would be used as a gate trace to bring power in across the width of the switch position. This layout may take full advantage of the available area for power conduction, and results in a lower and more balanced inductance across the switch position. The rightmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, as shown, or as a daisy chained stitch bond.

In aspects, the power module 100 may implement a linear arrangement, linear power flow. For example, a mixed kelvin layout for a linear arrangement with linear power flow. Here, each device may have a dedicated gate wire bond over to a trace on the power substrate. In aspects a rightmost and/or leftmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, daisy chained stitch bond, and/or the like. These jumpers may shorten the distance the signal current must flow in the loop while minimizing the shared path with the power loop.

In aspects of the power module 100, the power and signal loops may be laid out linearly, with the power flowing in and out from the same side, while the signals flow in and out on one side. The power terminals may be on one side, on opposite sides, or on both sides. The signal terminals may be on the opposite side of the power terminals, as pictured, the same side, or on both sides.

In aspects of the power module 100, the signal current may flow through the gate terminal, through the trace on the substrate, through the dedicated gate bonds, through the gate network on the devices, through the source pads of the devices to the wire bond jumpers, through to the trace on the substrate, and finally out of the source kelvin terminal. One device may have a true kelvin with no overlap of the power loop, while the remaining devices have some overlap but minimal interaction with the drain-source current. Notably through in this aspect of the power module 100, efficient switching can occur without needing to add a second trace on the substrate (or lead frame, signal substrate, etc.) which can take up room, add complexity, and add cost.

For further optimization of the power module 100, the gate pads on the devices can be stitch bonded together such that they all share the same linkage through a single daisy chained wire, removing the need for the dedicated gate trace on the substrate. In this aspect, this may not require gate or source kelvin traces, just a bonding pad on the substrate which may go to the signal connector. These bonding pads may also be removed in some cases where the signal terminal is wire bondable or the bonds may be formed directly from the devices to a lead frame. This approach may allow for further improvements in power density, reduced complexity, reduced cost, and/or the like. Also note that the gate and source kelvin loops in this aspect may be tightly coupled. For example, close in proximity and direction such that flux cancellation may reduce the overall loop inductance.

In aspects of the power module 100, a mixed kelvin layout may be implemented for a linear arrangement, linear power flow with stitched gate bonding. For either method of gate bonding, the power loop can be achieved with wire bonds, a direct clip attach, and the like. In some cases, the clip may be a standalone element or multiple elements. In other cases, it is joined to power contacts, signal contacts, and/or the like as part of a larger lead frame. There may be tradeoffs associated with the interconnection method regarding performance, manufacturability, and cost. Of particular importance here is that the mixed kelvin approach is compatible with any power interconnection scheme. In aspects, the disclosed device and process may implement a linear arrangement, parallel power flow.

In aspects of the power module 100, a mixed kelvin layout for a linear arrangement with parallel power flow. Here, stitched gate bonding frees up the room which would be used as a gate trace to bring power in across the width of the switch position. This layout may take full advantage of the available area for power conduction, and results in a lower and more balanced inductance across the switch position. The rightmost device may have a true source kelvin bond from its source pad to a trace on the power substrate. Partial kelvin connections may be formed through jumper wires from source pad of the true kelvin device to its neighbor, and then jumper wires from that device to its neighbor, and so on. Jumpers may be separate wires, as shown, or as a daisy chained stitch bond.

With reference to FIG. 17 in FIG. 18, the devices may be laid out linearly, the power flows in and out from wide power terminals following the width of the footprint. The signal terminals may be on the opposite side of the power terminals, as pictured, the same side, or on both sides.

The signal current flows through the gate terminal, through the trace on the substrate, through the stitched gate bonds, through the gate network on the devices, through the source pads of the devices to the wire bond jumpers, through to the trace on the substrate, and finally out of the source kelvin terminal. One device may have a true kelvin with no overlap of the power loop, while the remaining devices have some overlap but minimal interaction with the drain-source current.

In aspects of the power module 100, the at least one first power device 201, the at least one second power device 202, the at least one true Kelvin interconnection 211, the at least one pseudo-kelvin interconnection 212, and/or the like illustrated in FIGS. 16-20 and described in relation to FIGS. 16-20 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 16-20 and described in relation to FIGS. 16-20.

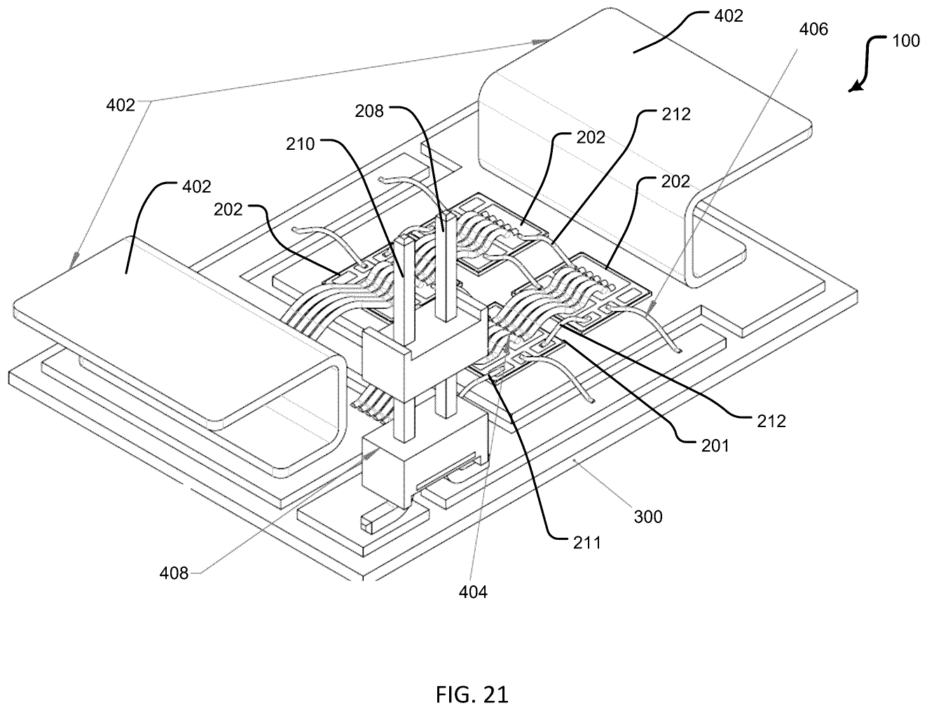

FIG. 21 illustrates a perspective view of a power module according to aspects of the disclosure.

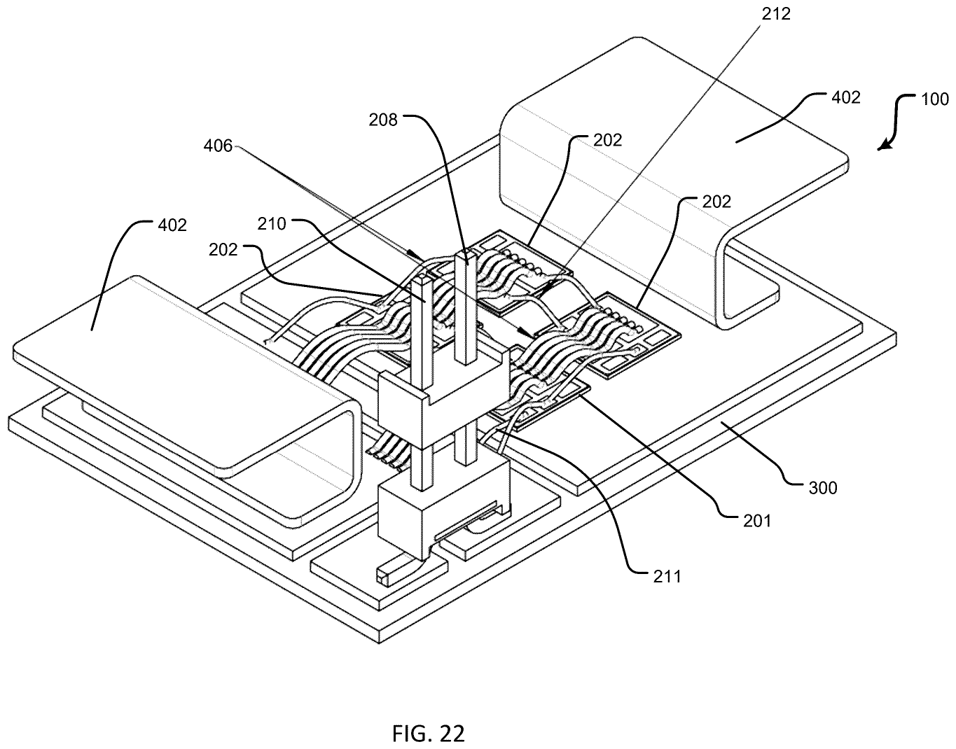

FIG. 22 illustrates a perspective view of the power module according to FIG. 21.

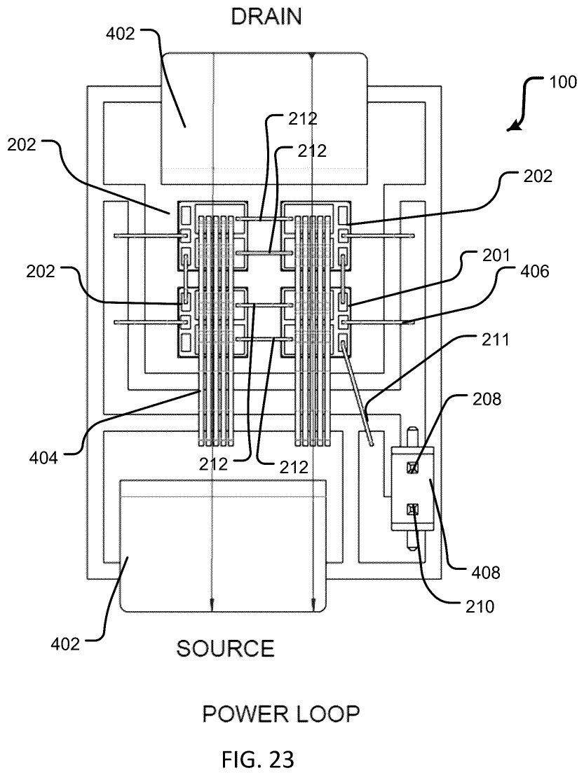

FIG. 23 illustrates another top view of the power module according to FIG. 21.

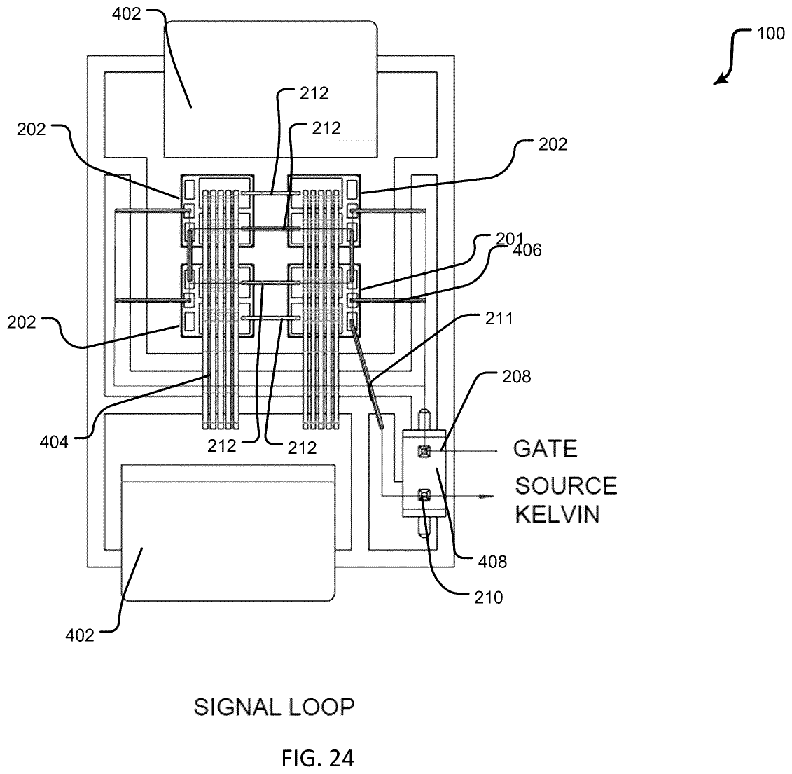

FIG. 24 illustrates another top view of the power module according to FIG. 21.

In particular, FIG. 21 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects of the power module 100, the at least one first power device 201, the at least one second power device 202, the at least one true Kelvin interconnection 211, the at least one pseudo-kelvin interconnection 212, and/or the like illustrated in FIGS. 21-24 and described in relation to FIGS. 21-24 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 21-24 and described in relation to FIGS. 21-24.

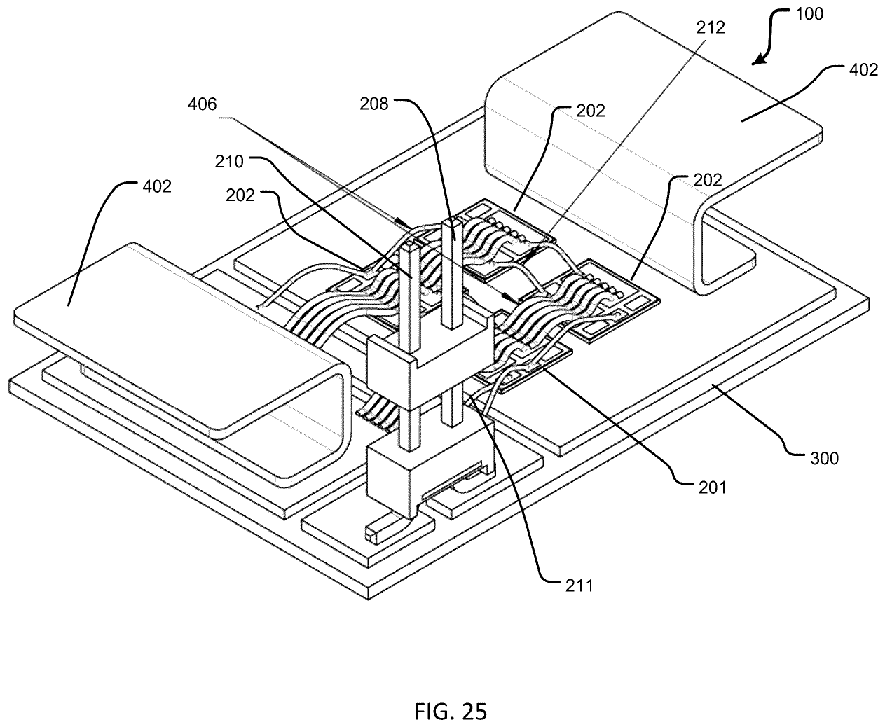

FIG. 25 illustrates a perspective view of a power module according to aspects of the disclosure.

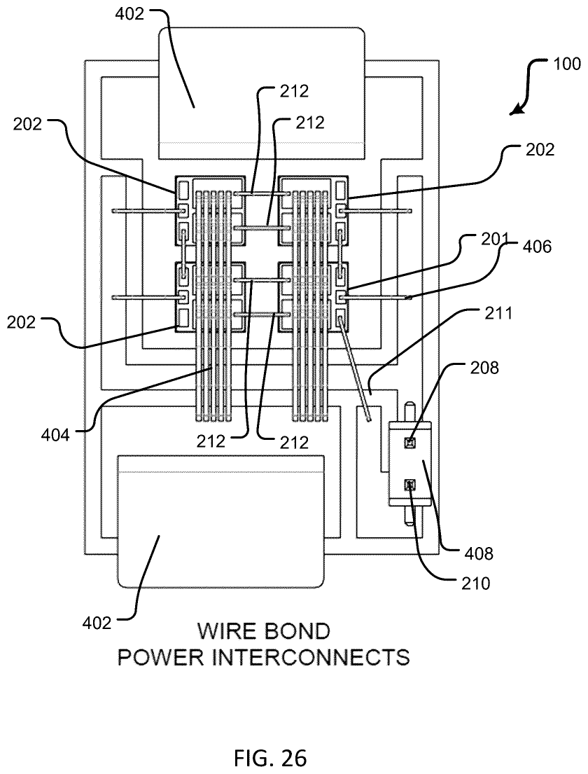

FIG. 26 illustrates a top view of the power module according to FIG. 25.

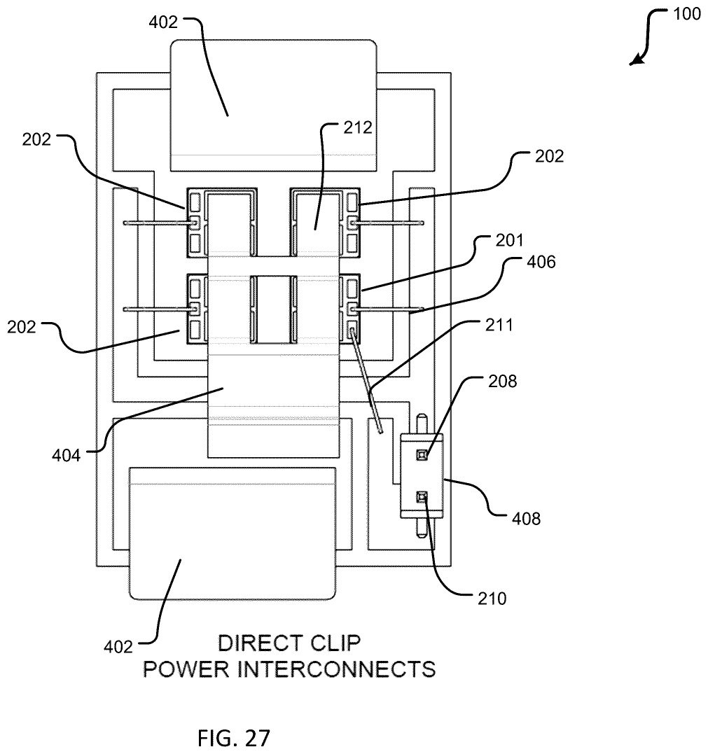

FIG. 27 illustrates another top view of the power module according to FIG. 25.

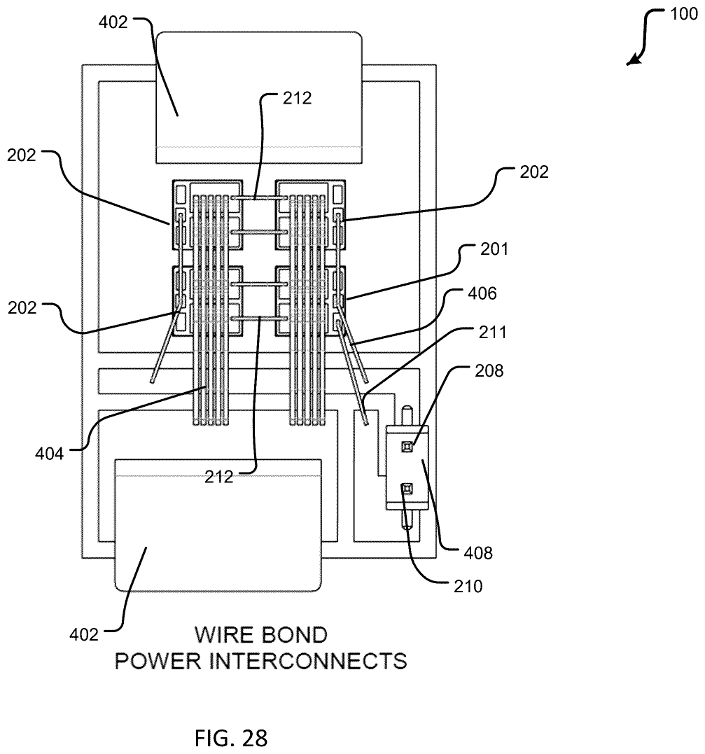

FIG. 28 illustrates another top view of the power module according to FIG. 25.

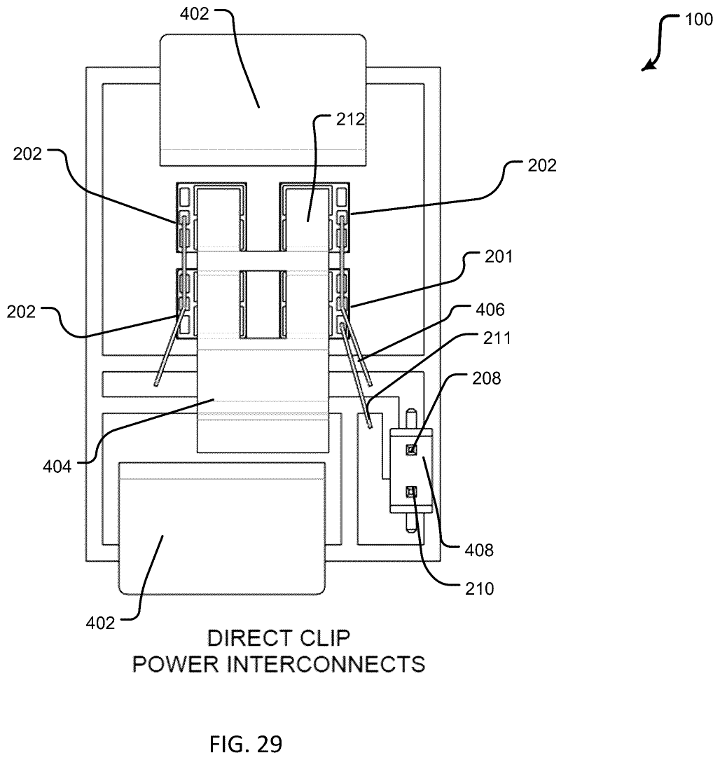

FIG. 29 illustrates another top view of the power module according to FIG. 25.

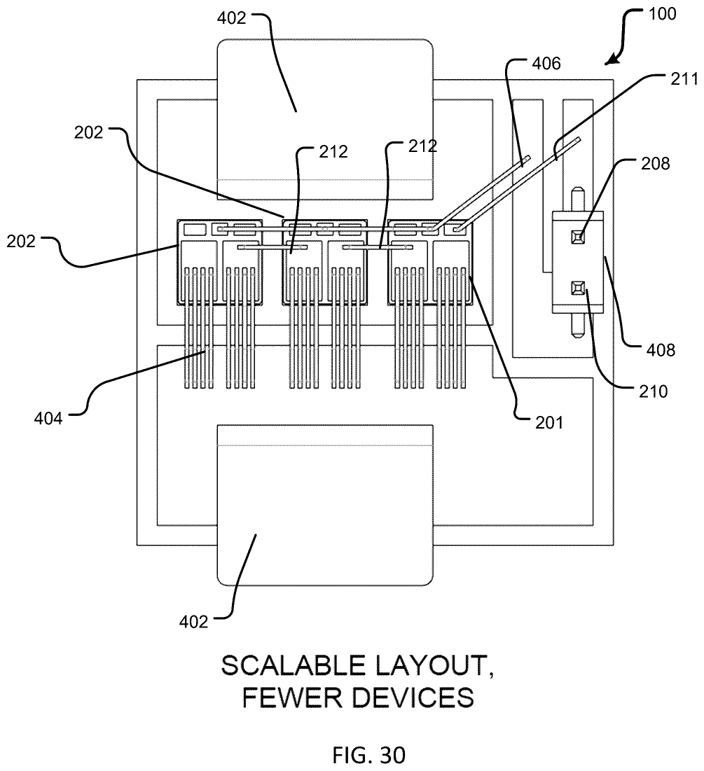

FIG. 30 illustrates another top view of the power module according to FIG. 25.

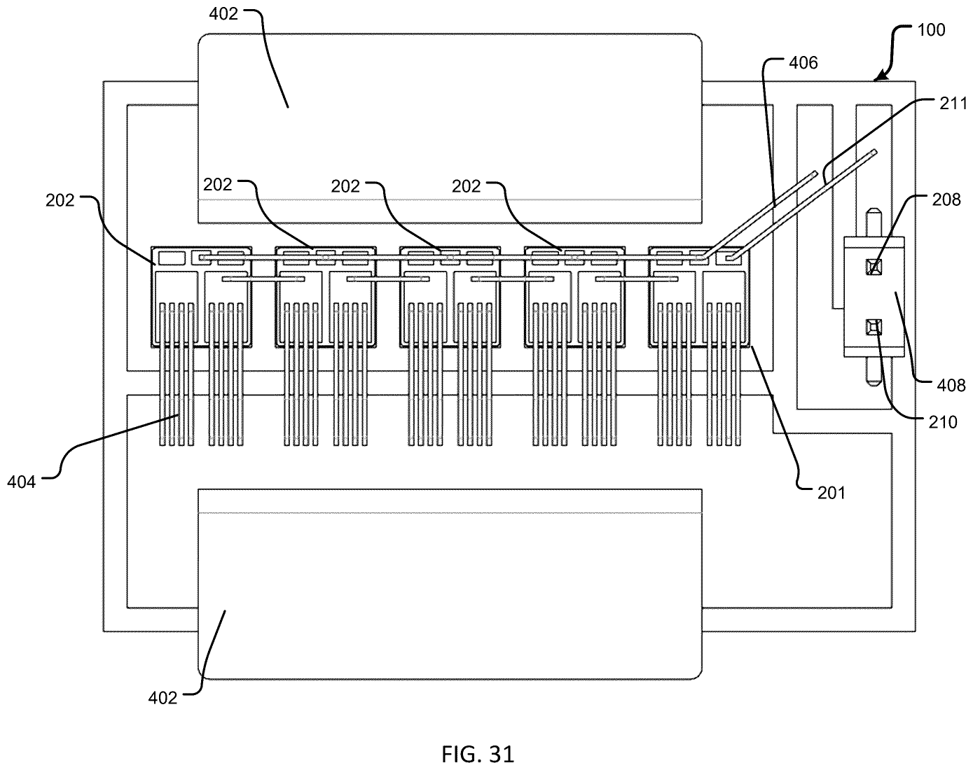

FIG. 31 illustrates another top view of the power module according to FIG. 25.

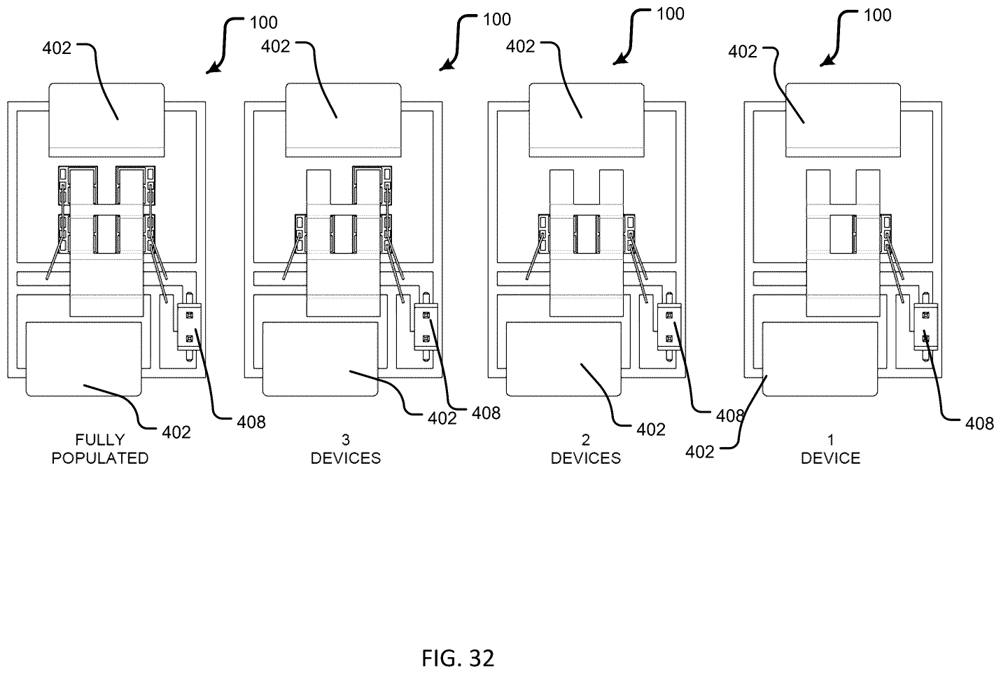

FIG. 32 illustrates top views of power modules according to FIG. 25.

In particular, FIG. 25 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects of the power module 100, the devices may be laid out in an example 2×2 array, with the power flowing in and out from the same side. The signals may be located on the source side in which they may share a similar voltage. The substrate may have a gate trace for the devices to individually bond to. Note that this signal trace would be part of the power substrate, or alternatively a portion of it could be on a lead frame, signal substrate, and the like. Also note that in some cases the signals could be on the source side, as pictured, the drain side, or both sides (left and right), depending on implementation.

For the signal loops of the power module 100, the current flows through the gate terminal, through the trace on the substrate, through the dedicated gate bonds, to the devices, then out the source pads of the devices to the wire bond jumpers, then to the trace on the substrate (or alternatively on a lead frame, signal substrate, etc.) and out of the source kelvin terminal. For one device, there is a true kelvin with no overlap of the power loop, while the remaining devices have some but minimal interaction with the drain-source current.

For further optimization of the power module 100, the gate pads on the device legs can be stitch bonded together such that they may all share the same linkage through a single daisy chained wire.

With reference to FIG. 26-FIG. 29, the power loop can be achieved with wire bonds, a direct clip attach, and the like. In some cases, the clips may be a standalone element. In other cases, it is joined to power contacts, signal contacts, etc. as part of a larger lead frame. There may be tradeoffs associated with the interconnection method regarding performance, manufacturability, and cost. Of particular importance here is that the mixed kelvin approach is compatible with any power interconnection scheme.

While four devices were used in the example layouts of the power module 100, it is apparent that the power module 100 can scale up or scale down the number of devices and still be compatible with and benefit from features of the disclosure as illustrated in FIG. 30 and FIG. 31. The scalable approach extending the layout in the direction of the device paralleling still allows for the mixed kelvin approach to be utilized. In some cases, the signal connections may be formed on both sides (i.e. a true kelvin on each side) to minimize inductance.

With reference to FIG. 32, in other cases where the footprint of the power module 100 is not able to be scaled, flexibility can be found in using the modularity feature of this approach. In a set footprint, each device location can be considered a set number of ‘sites’ which may or may not be populated. Modularity is found in the ability to populate a site with a device or leave it blank. This is a useful technique to design a footprint for a ‘fully loaded’ maximum power condition and have other product offerings with ‘sites’ not populated for lower power, more cost effective offerings.

This is demonstrated for an arrayed method of paralleling with a clip attach as illustrated in FIG. 32. Here, the same clip can be used, with device sites not populated and the wire bonding adjusted to match. Importantly, the true kelvin device or device(s) would not be depopulated to maintain product function.

In aspects of the power module 100, the at least one first power device 201, the at least one second power device 202, the at least one true Kelvin interconnection 211, the at least one pseudo-kelvin interconnection 212, and/or the like illustrated in FIGS. 25-32 and described in relation to FIGS. 25-32 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 25-32 and described in relation to FIGS. 25-32.

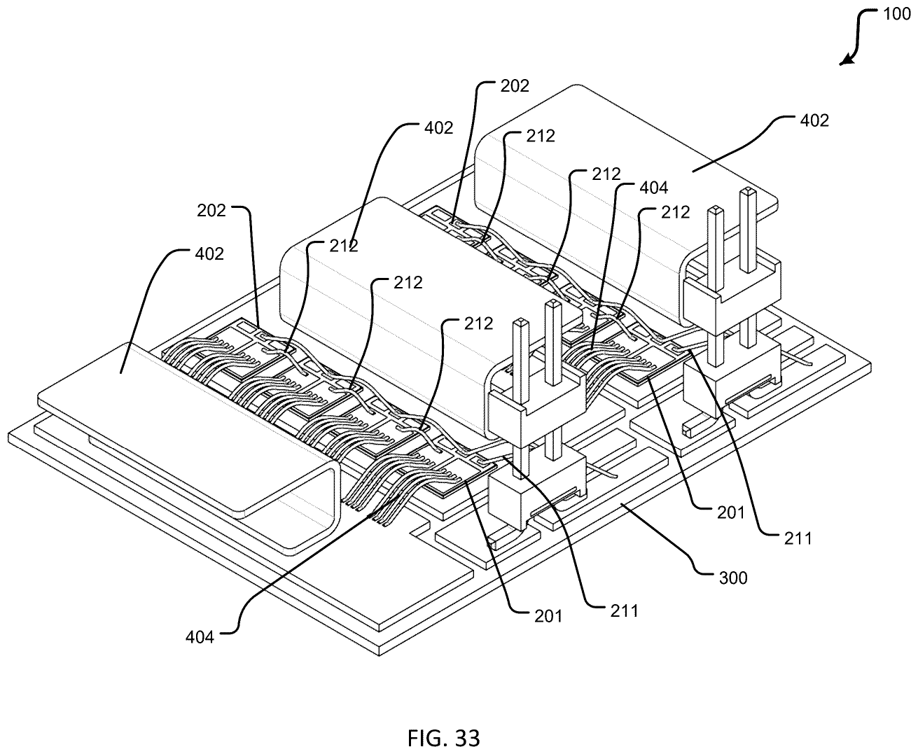

FIG. 33 illustrates a perspective view of a power module according to aspects of the disclosure.

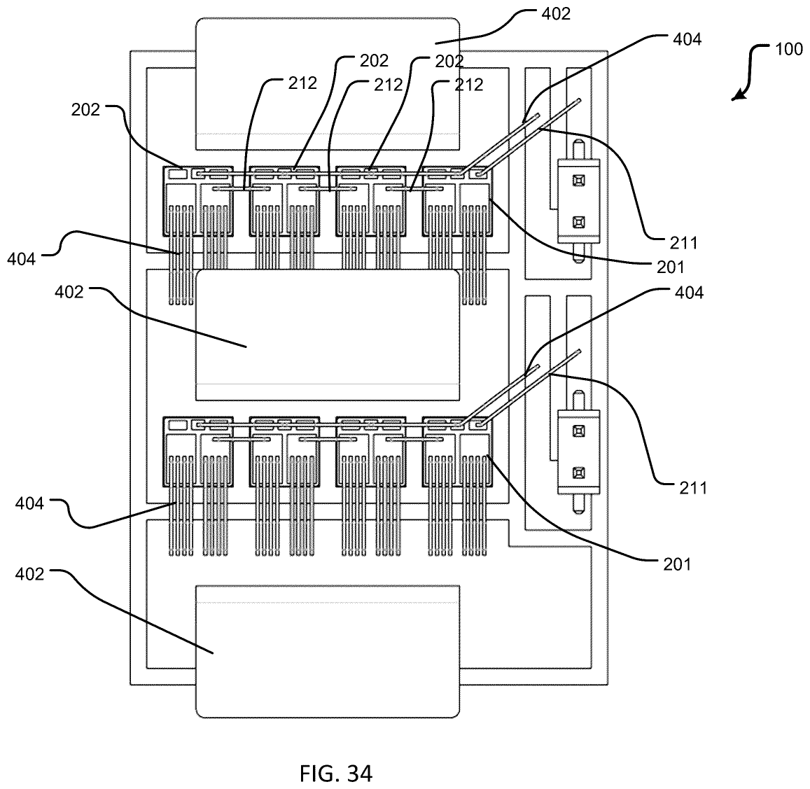

FIG. 34 illustrates a top view of the power module according to FIG. 33.

In particular, FIG. 33 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects of the power module 100, ultimately the utilization of both scalability and modularity for each of the described layout methods may deliver a large amount of design flexibility to incorporate the mixed kelvin technique into a multitude of different applications, product footprints, and power level requirements.

The described layouts of the power module 100 may be used as standalone single switch positions. They may also find use arranged as ‘building block’ switch positions to form a variety of power module topologies (half-bridge, full-bridge, three-phase, etc.).

In aspects of the power module 100 illustrated in FIG. 33, a series arrangement of two linear paralleled, parallel power flow switch positions to form a half-bridge. This method can achieve high levels of power density with smaller substrate sizes. Note that the signal chains could be on one side of the package, as shown, the other side, or both. One attractive option, not shown, would be to use the opposite side of the package for other signal functions, such as temperature, current, or overcurrent sensing.

In aspects of the power module 100, the at least one first power device 201, the at least one second power device 202, the at least one true Kelvin interconnection 211, the at least one pseudo-kelvin interconnection 212, and/or the like illustrated in FIGS. 33 and 34 and described in relation to FIGS. 33 and 34 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 33 and 34 and described in relation to FIGS. 33 and 34.

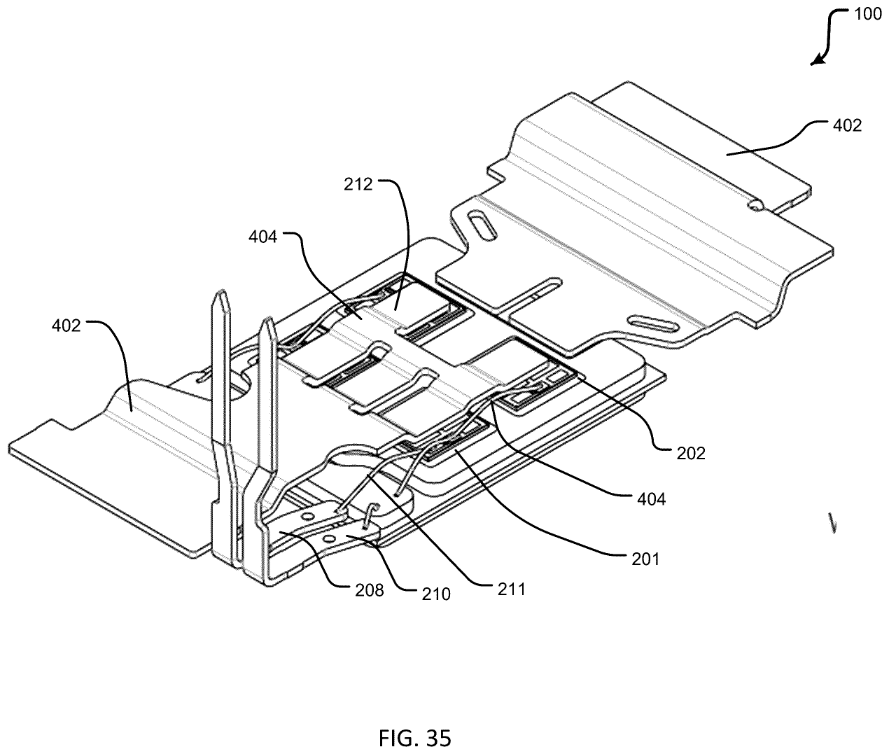

FIG. 35 illustrates a perspective view of a power module according to aspects of the disclosure.

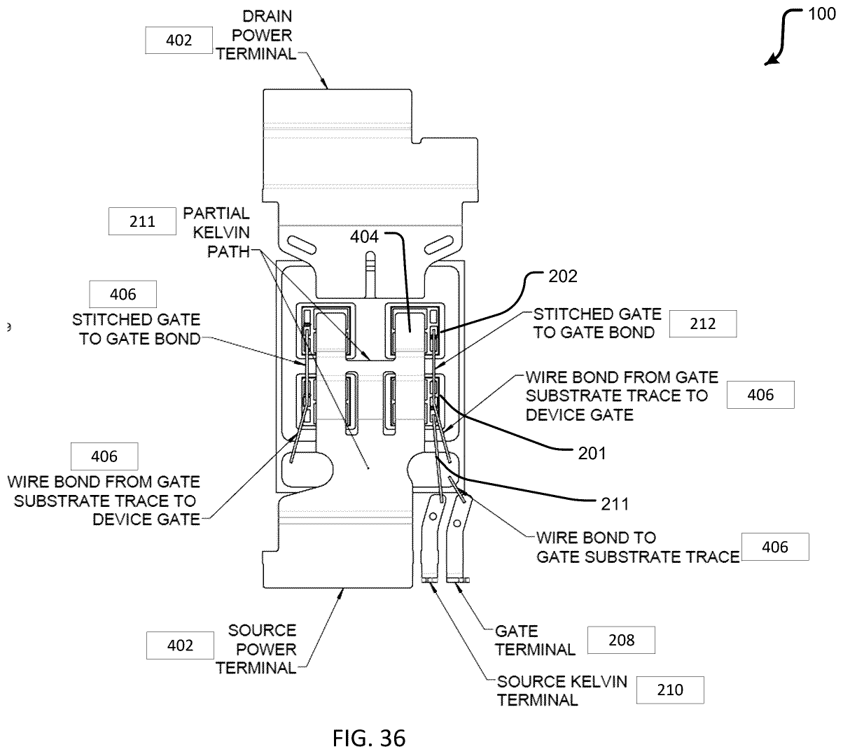

FIG. 36 illustrates a top view of the power module according to FIG. 35.

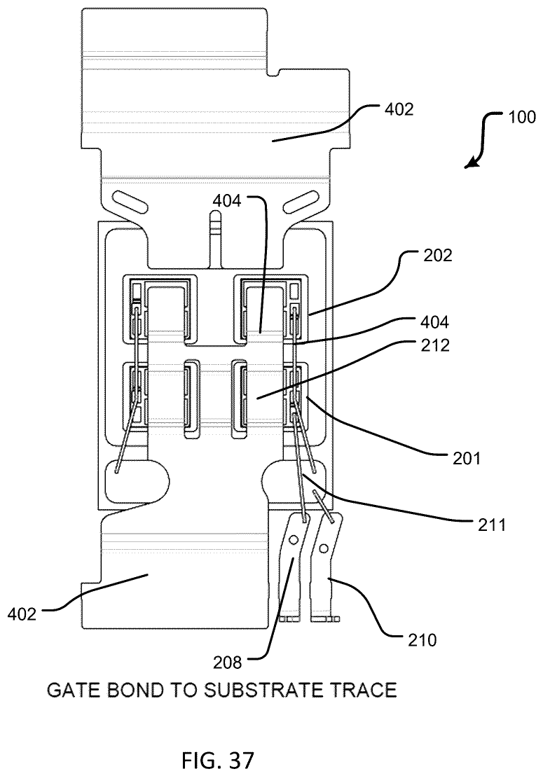

FIG. 37 illustrates another top view of the power module according to FIG. 35.

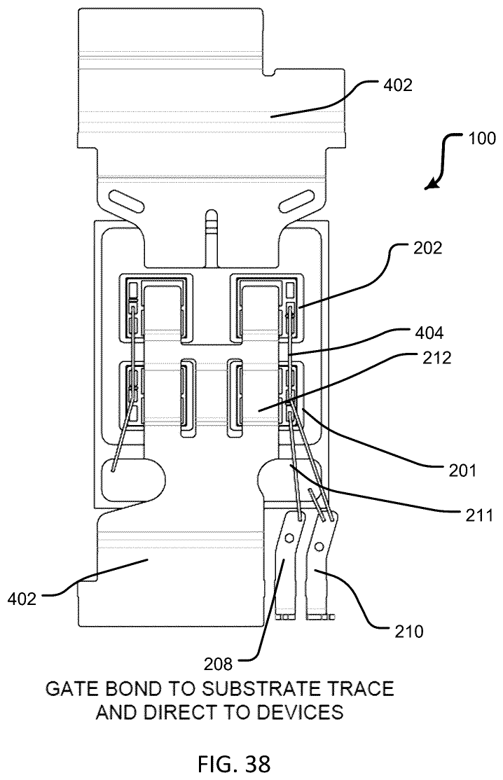

FIG. 38 illustrates another top view of the power module according to FIG. 35.

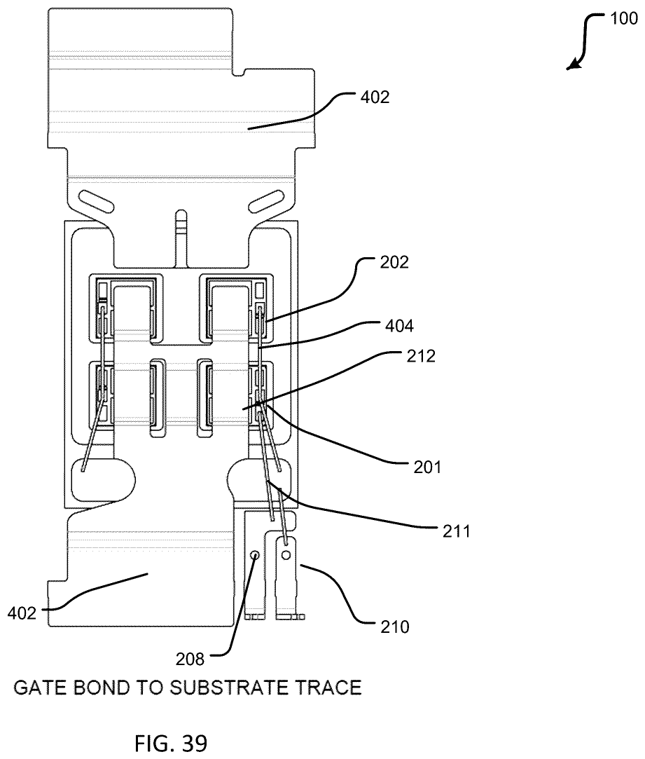

FIG. 39 illustrates another top view of the power module according to FIG. 35.

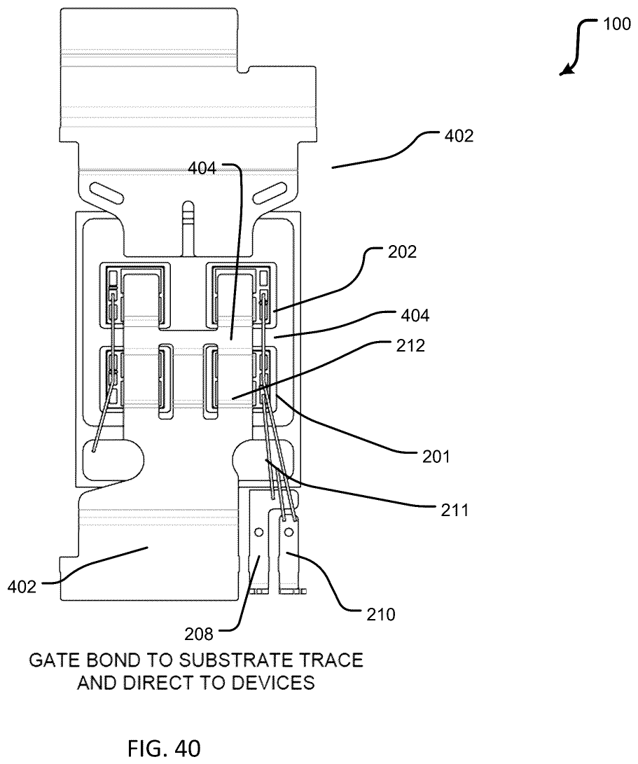

FIG. 40 illustrates another top view of the power module according to FIG. 35.

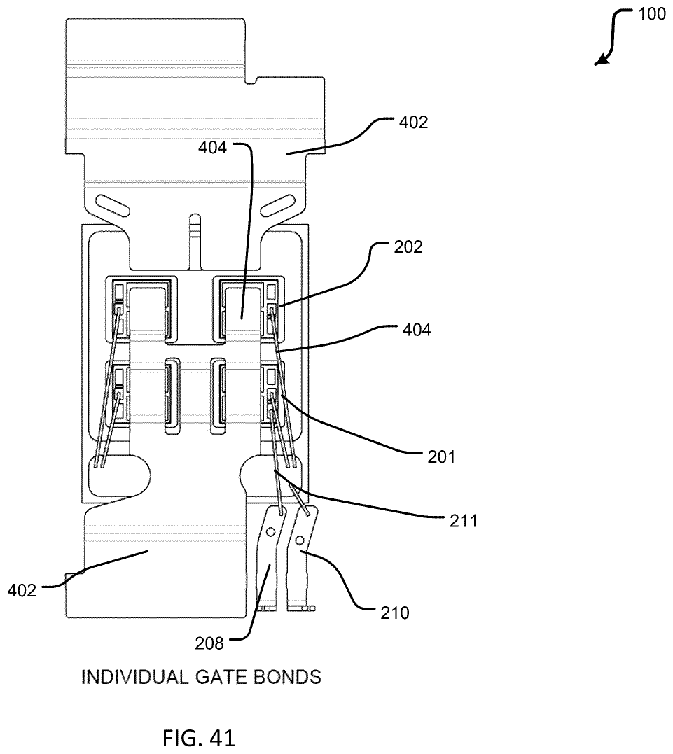

FIG. 41 illustrates another top view of the power module according to FIG. 35.

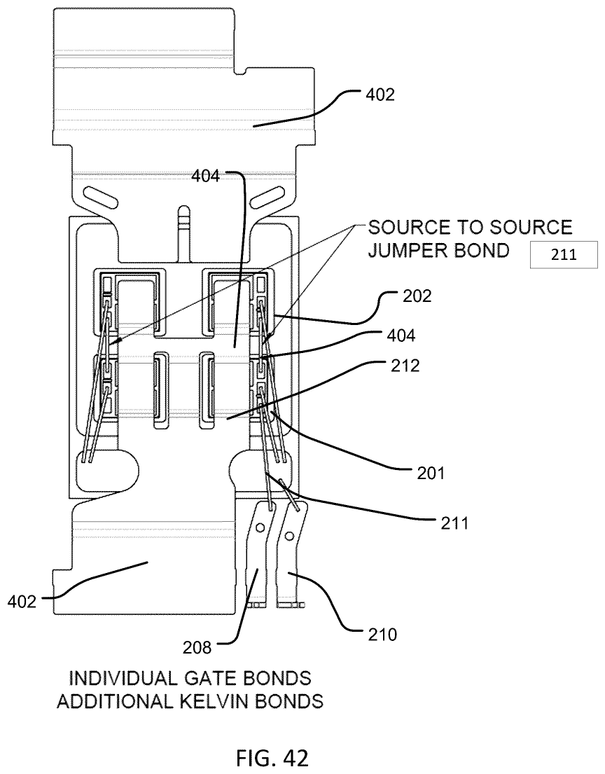

FIG. 42 illustrates another top view of the power module according to FIG. 35.

In particular, FIG. 35 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects, the power module 100 may be implemented in one of the following categories:

Case module. In aspects, the case module implementation may include: Power substrate, devices, and terminals may be surrounded by a separate insulative housing or case and filled with an insulating element (gel, epoxy, and/or the like). In aspects, the Power substrate may or may not be attached to a base plate, cold plate, etc.

Overmolded module. In aspects, the overmolded module implementation may include: a Power substrate and devices attached to a lead frame and molded over with an epoxy molding compound or similar dielectric material.

Hermetic module. In aspects, the hermetic module implementation may include: a Power substrate and devices may be attached to a hermetic outer package, often a structure of metal, ceramic, and glass, then filled with a gel or epoxy, and sealed.

Hybrid module. In aspects, the hybrid module implementation may include: a combination of approaches that uses elements of multiple categories or is difficult to group in a single classification.

With respect to the disclosed implementation of the power module 100, the mixed kelvin approach is compatible with any packaging style. If devices of the power module 100 are paralleled into a switch position, regardless of package structure, this method would be suitable. The following presents various case and overmolded power modules demonstrating implementation of this approach.

In aspects of the power module 100, a single switch position package may be implemented with arrayed power devices. Structurally, it comprises of a power substrate, power devices, a lead frame which is directly attached to both the power substrate and the topsides of the devices, and wire bonds for the signal connections. The substrate may have two traces, one for the drain connection and one for the gate connection. The gate trace runs underneath the source clip attached to the device tops such that the gates can be bonded to the same pad and connected electrically. Dedicated terminals for the gate and source kelvin may be located on the lower right side. Wire bonds connect the gate terminal down to a gate trace on the power substrate. Gates may be bonded out with a shared stitched bond per leg of devices. A wire bond from the source kelvin terminal to the lower right device forms the true kelvin connection, with the partial connection achieved through the source power terminal which is attached to the topsides of the devices (and runs over the gate trace on the substrate).

Depending on manufacturing method and layout, the signal bonding of the power module 100 may be approached in a variety of manners. In some cases, the gate terminal may be bonded directly to a trace on the power substrate. The device gates may be then wire bonded to this trace, forming an electrical connection. In some cases, the gate terminal is bonding both to the signal trace on the substrate as well as directly to the gates of the power devices. Examples of these different bonding strategies in the case that the bonding regions may be linear (or slightly angled).

With reference to FIG. 39 and FIG. 40, in some cases, the gate bonds may be stitched with a single daisy chained bond. Alternatively, the gates can be bonded individually. In some cases, the partial kelvin paths through the power source terminal directly attached to the device topsides is sufficient for effective operation. In other cases, further inductance reduction and shared path overlap can be achieved with additional wire bonds connecting source to source pads on the power devices.

With reference to FIG. 41 and FIG. 42, the gate bonds of the power module 100 may be stitched with a single daisy chained bond. Alternatively, the gates can be bonded individually. In some cases, the partial kelvin paths through the power source terminal directly attached to the device topsides is sufficient for effective operation. In other cases, further inductance reduction and shared path overlap can be achieved with additional wire bonds connecting source to source pads on the power devices.

In aspects of the power module 100, the at least one first power device 201, the at least one second power device 202, the at least one true Kelvin interconnection 211, the at least one pseudo-kelvin interconnection 212, and/or the like illustrated in FIGS. 35-42 and described in relation to FIGS. 35-42 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 35-42 and described in relation to FIGS. 35-42.

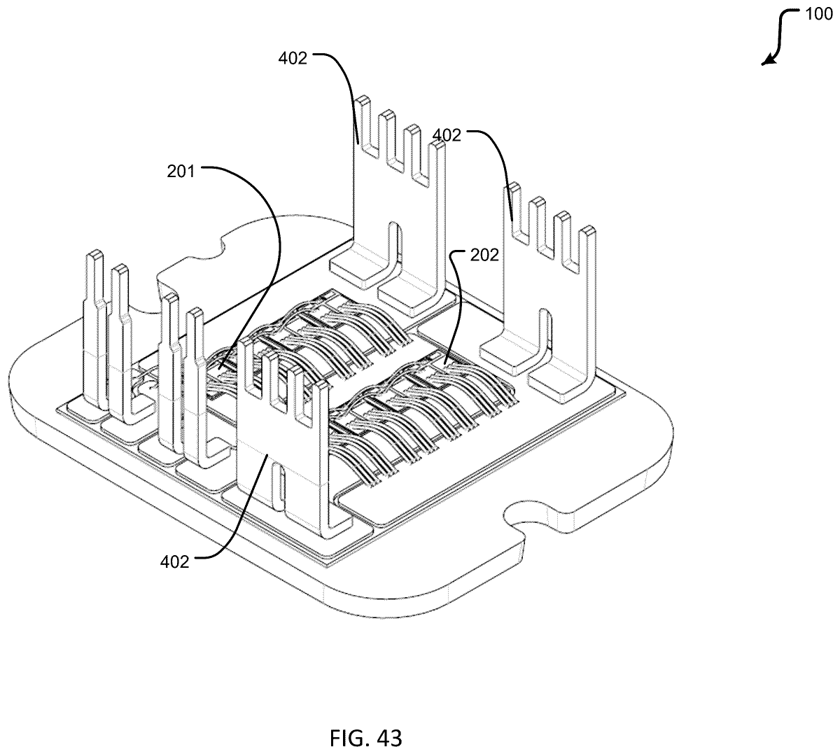

FIG. 43 illustrates a perspective view of a power module according to aspects of the disclosure.

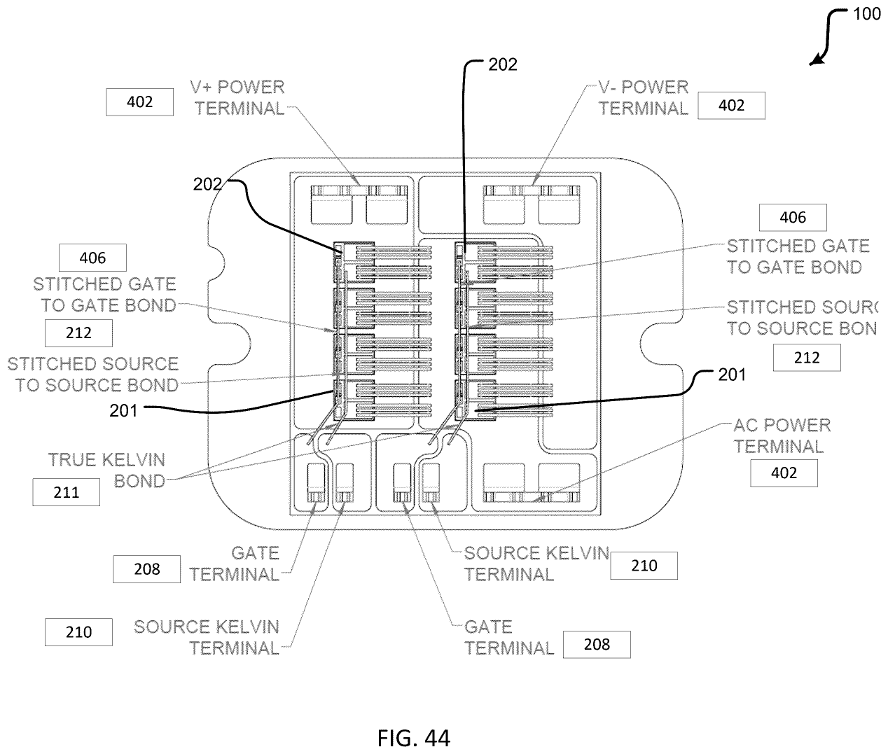

FIG. 44 illustrates a top view of the power module according to FIG. 43.

In particular, FIG. 43 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects of the power module 100 and depending on a manufacturing method and layout, the bonding regions of the signal terminals may be nested together in an L-bend. An L-bend is an attractive solution if the wire angles need to be shifted over to make room for other elements used in manufacturing, like hold down pins and clamps.

In aspects of the power module 100, the gate bonds may be stitched with a single daisy chained bond. Alternatively, the gates can be bonded individually. In some cases, the partial kelvin paths through the power source terminal directly attached to the device topsides is sufficient for effective operation. In other cases, further inductance reduction and shared path overlap can be achieved with additional wire bonds connecting source to source pads on the power devices.

In aspects, the power module 100 may be implemented as a half bridge power module with a linear array of power devices. Structurally, the power module 100 may include a base plate, power substrate, power devices, terminals attached to the power substrate, wire bonds for the signal connections, and wire bonds (or similar high current interconnection method) for the power connections. Being a half-bridge implementation of the power module 100, there may be three power terminals and four signal terminals, and their associated traces on the power substrate. Gate bonds may be stitched from gate pad to gate pad on each switch position, down to a trace on the power substrate. They may also be bonded directly to the signal terminal in some cases. Source kelvin bonds may be formed similarly, stitched from source pad to source pad and to a trace on the power substrate or directly to the signal terminal. Here, the first source kelvin bond is a true kelvin, while the remaining may be partial kelvins.

In aspects of the power module 100, the at least one first power device 201, the at least one second power device 202, the at least one true Kelvin interconnection 211, the at least one pseudo-kelvin interconnection 212, and/or the like illustrated in FIGS. 43 and 44 and described in relation to FIGS. 43 and 44 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 43 and 44 and described in relation to FIGS. 43 and 44.

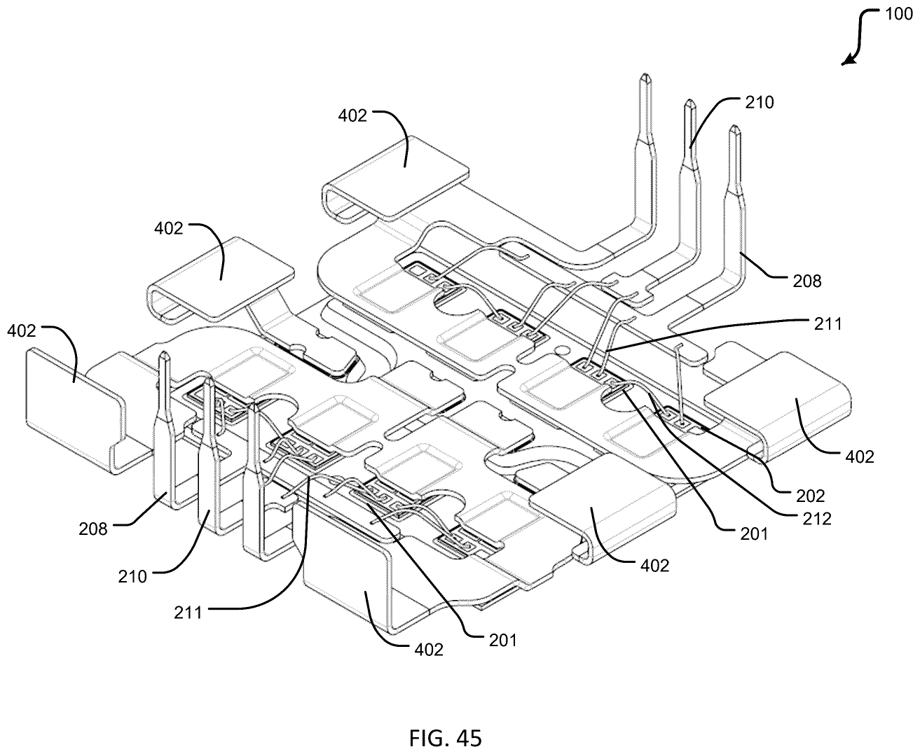

FIG. 45 illustrates a perspective view of a power module according to aspects of the disclosure.

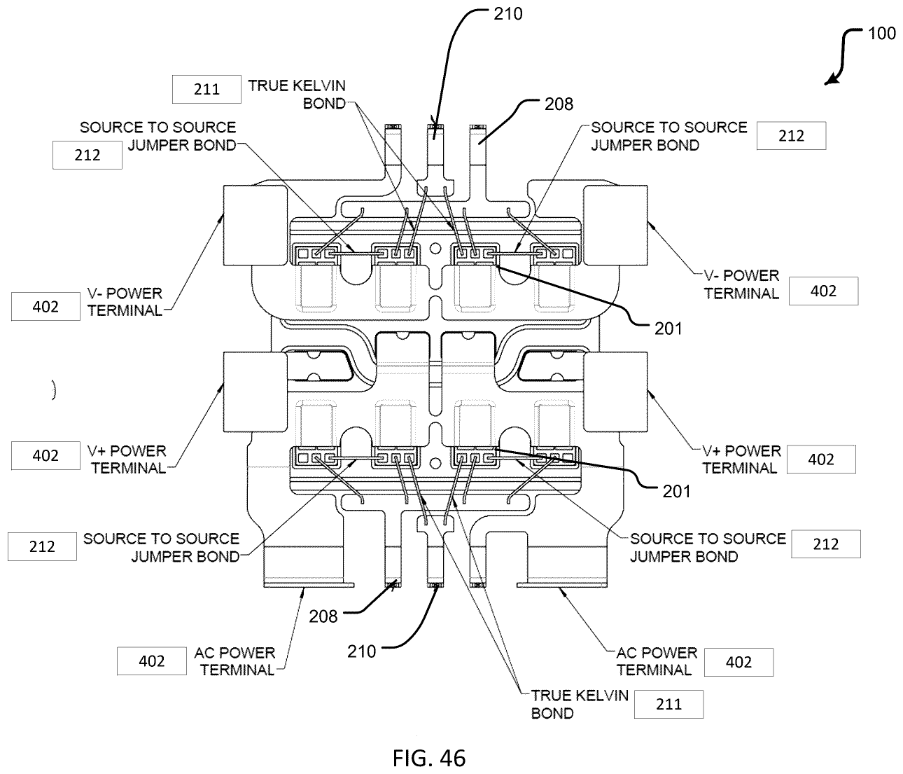

FIG. 46 illustrates a top view of the power module according to FIG. 45.

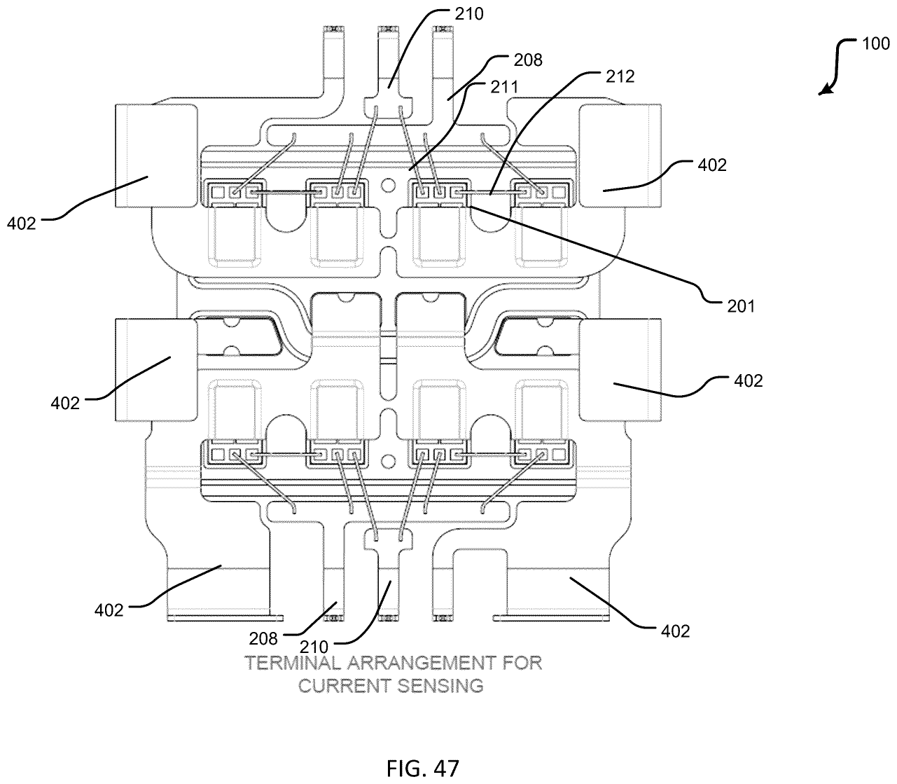

FIG. 47 illustrates another top view of the power module according to FIG. 45.

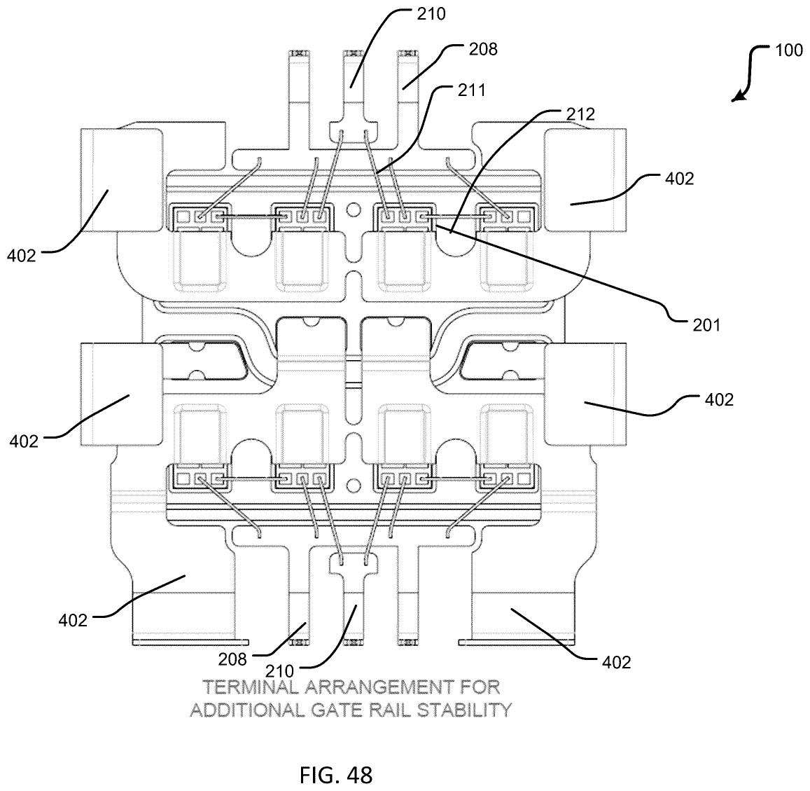

FIG. 48 illustrates another top view of the power module according to FIG. 45.

In particular, FIG. 45 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects, the power module 100 may be implemented a half bridge power module with a linear array of power devices. In this implementation of the power module 100, power may flow from both sides of the package to balance inductances between the paralleled devices. Structurally, the power module 100 may include a power substrate, power devices, a lead frame which is directly attached to both the power substrate and the topsides of the devices, and wire bonds for the signal connections. The substrate may have two traces, one for the drain connection and one for the gate connection. In this case, ‘rails’ on the lead frame span the length of the footprint to allow for individual gate bonds for each power device. A smaller terminal is used to deliver true kelvin bonds to some of the devices. Jumper bonds between the devices deliver the partial kelvin connection to the rest.

In aspects of the power module 100, the mixed kelvin approach may allow for the source kelvin terminal to be much smaller than what it would be if each device needed a true kelvin. This allows for a few opportunities for flexibility in how the signal terminals may be configured and used.

In this aspect of the power module 100, an additional terminal can be added to the source terminal to be used for current sensing. Alternatively, that pin location could be used as a secondary linkage to the long gate bonding rail, providing stability to improve manufacturability. Other possibilities, not pictured, are less pins (just the two on each side required for operation) or more pins (for additional sensing capability, such as temperature sense, could be conceived.

With reference to the power module 100 illustrated in FIG. 47 and FIG. 48, the power module 100 may be implemented with an additional terminal that can be added to the source terminal to be used for current sensing. Alternatively, that pin location could be used as a secondary linkage to the long gate bonding rail, providing stability to improve manufacturability. Other possibilities, not illustrated, are less pins (just the two on each side required for operation) implemented by the power module 100 or more pins, for additional sensing capability, such as temperature sense, could be implemented by the power module 100.

In aspects of the power module 100, the at least one first power device 201, the at least one second power device 202, the at least one true Kelvin interconnection 211, the at least one pseudo-kelvin interconnection 212, and/or the like illustrated in FIGS. 45-48 and described in relation to FIGS. 45-48 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 45-48 and described in relation to FIGS. 45-48.

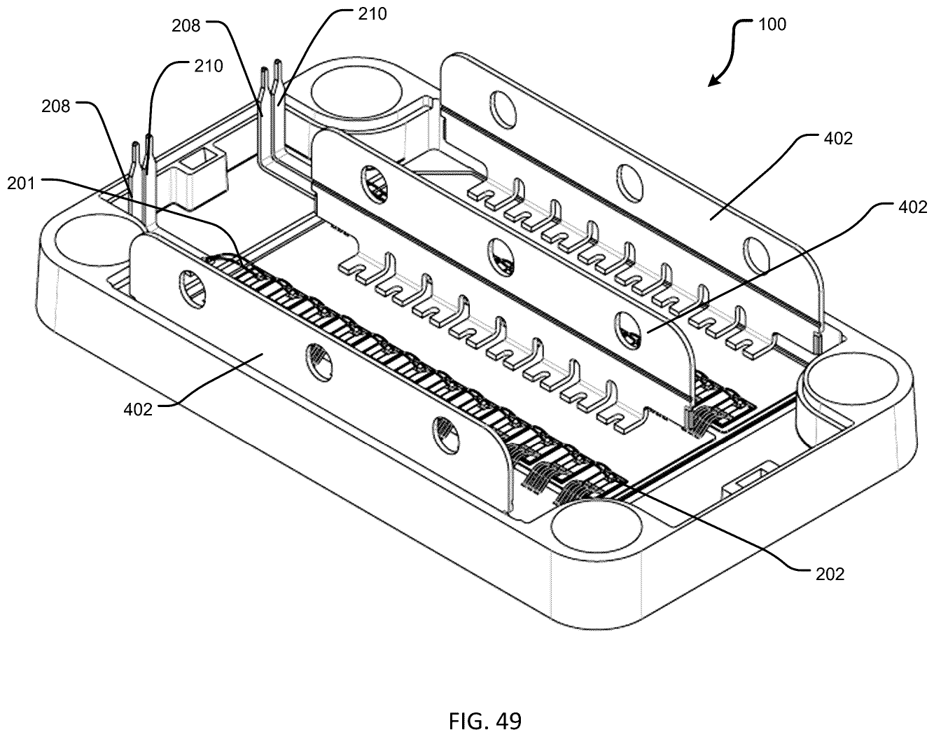

FIG. 49 illustrates a perspective view of a power module according to aspects of the disclosure.

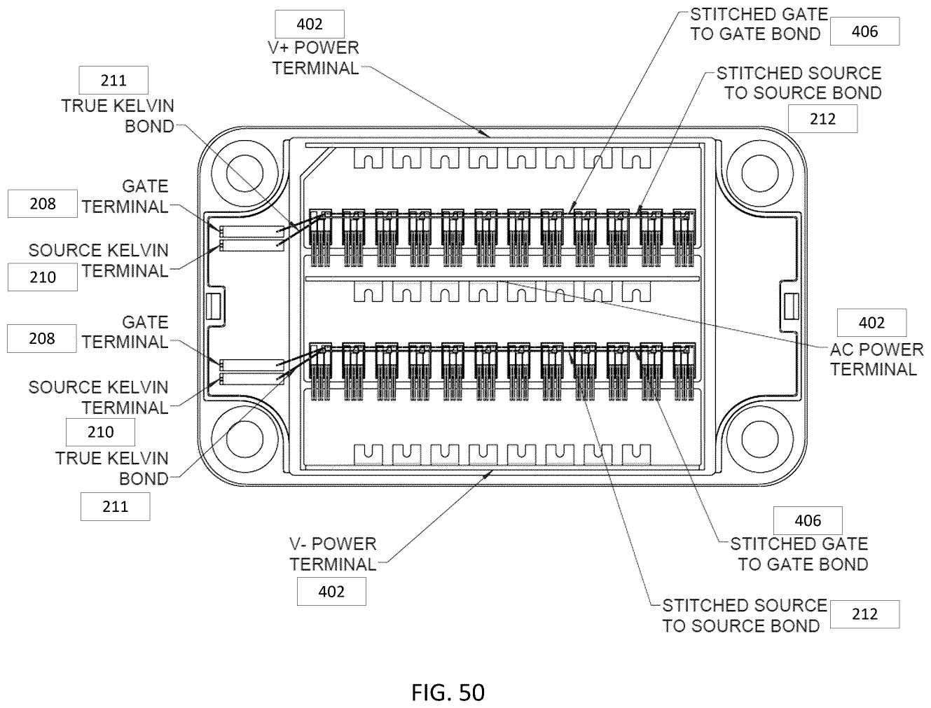

FIG. 50 illustrates a top view of the power module according to FIG. 49.

In particular, FIG. 49 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects, the power module 100 may be implemented as a half bridge power module with a linear array of power devices. Structurally, the power module 100 may include a base plate, power substrate, power devices, terminals attached to the power substrate, wire bonds for the signal connections, wire bonds (or similar high current interconnection method) for the power connections, and a plastic or similar dielectric housing. Not illustrated are a lid and fasteners. The power terminals are shown as unfolded to show detail of the layout. Often, they will be folded over flat after the lid is attached.

Being a half-bridge implementation of the power module 100, there may be three power terminals and four signal terminals, and their associated traces on the power substrate. Gate bonds may be stitched from gate pad to gate pad on each switch position and over to a signal terminal (as pictured) or to an interstitial trace on the substrate which would then be bonded up to the terminal. Source kelvin bonds may be formed similarly, stitched from source pad to source pad and to a trace on the power substrate or directly to the signal terminal or to an interstitial substrate trace. Here, the first source kelvin bond is a true kelvin, while the remaining may be partial kelvins.

In aspects of the power module 100, an AC trace runs underneath a V-terminal, which V-terminal may be electrically isolated from the AC trace from the housing. Similar to the previous implementations of the power module 100, the gates and source pads may be stitched together and bonded over to a signal terminal (as shown) or to an interstitial pad on the power substrate. Signal terminals may be embedded into the plastic, as illustrated, but may also be glued, bonded, etc. For this layout of the power module 100, some accessory bonds may be used for overcurrent protection, temperature sensing, and the like.

In aspects of the power module 100, the at least one first power device 201, the at least one second power device 202, the at least one true Kelvin interconnection 211, the at least one pseudo-kelvin interconnection 212, and/or the like illustrated in FIGS. 49 and 50 and described in relation to FIGS. 49 and 50 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 49 and 50 and described in relation to FIGS. 49 and 50.

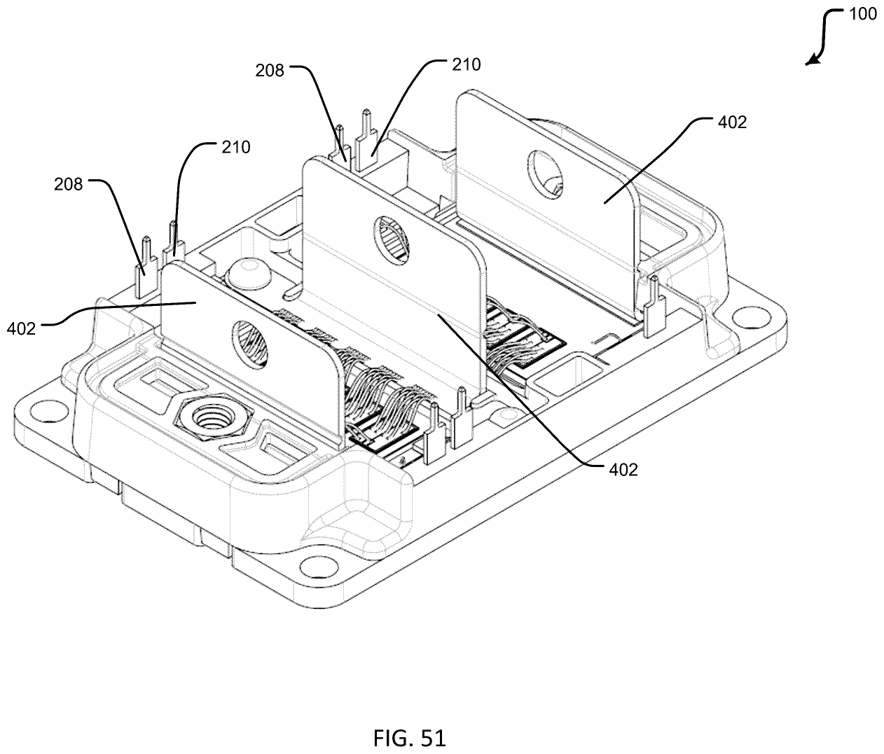

FIG. 51 illustrates a perspective view of a power module according to aspects of the disclosure.

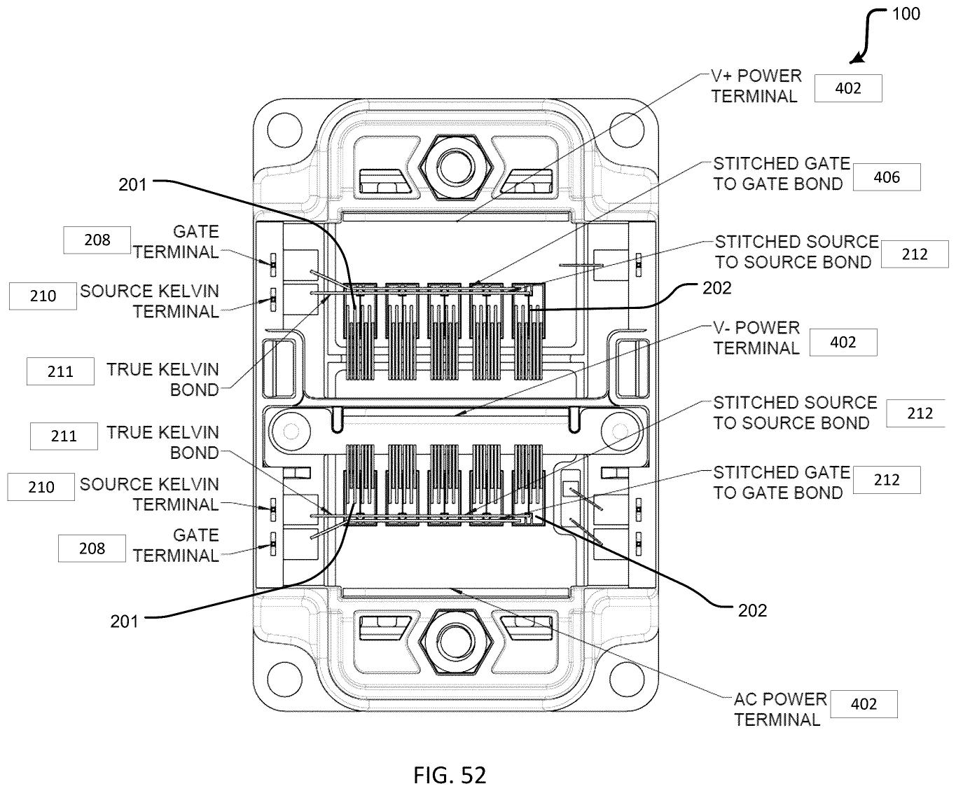

FIG. 52 illustrates a top view of the power module according to FIG. 51.

In particular, FIG. 51 illustrates an implementation of the power module 100 that may include the power substrate 300, the gate connection 208, the source kelvin terminal 210, the at least one first power device 201, the at least one second power device 202, the at least one true Kelvin interconnection 211, the at least one pseudo-kelvin interconnection 212, the power terminals 402, the power interconnections 404, the signal interconnections 406, the signal terminal 408, and/or the like as previously disclosed.

In aspects of the power module 100, the at least one first power device 201, the at least one second power device 202, the at least one true Kelvin interconnection 211, the at least one pseudo-kelvin interconnection 212, and/or the like illustrated in FIGS. 49 and 50 and described in relation to FIGS. 49 and 50 may optionally implement any other aspects of the power module 100, the at least one first power device 201, the at least one second power device 202, the at least one true Kelvin interconnection 211, the at least one pseudo-kelvin interconnection 212, and/or the like described and illustrated herein. Additionally, aspects of the power module 100, the at least one first power device 201, the at least one second power device 202, the at least one true Kelvin interconnection 211, the at least one pseudo-kelvin interconnection 212, and/or the like illustrated and described herein may optionally implement any other aspects of the power module 100, the at least one first power device 201, the at least one second power device 202, the at least one true Kelvin interconnection 211, the at least one pseudo-kelvin interconnection 212, and/or the like illustrated in FIGS. 49 and 50 and described in relation to FIGS. 49 and 50.

The following are a number of nonlimiting EXAMPLES of aspects of the disclosure.

One EXAMPLE: a power module includes a power substrate. The power module in addition includes at least one first power device arranged on the power substrate. The module moreover includes at least one second power device arranged on the power substrate. The module also includes at least one true Kelvin interconnection. The module further includes at least one pseudo-Kelvin interconnection.

The above-noted EXAMPLE may further include any one or a combination of more than one of the following EXAMPLES: The power module of the above-noted EXAMPLE where the at least one first power device is connected to the at least one true Kelvin interconnection; and where the at least one second power device is connected to the at least one pseudo-Kelvin interconnection. The power module of the above-noted EXAMPLE includes a source Kelvin terminal. The power module of the above-noted EXAMPLE where the at least one true Kelvin interconnection connects the at least one first power device to the source Kelvin terminal. The power module of the above-noted EXAMPLE where the at least one true Kelvin interconnection connects a source pad of the at least one first power device to the source Kelvin terminal. The power module of the above-noted EXAMPLE where the at least one true Kelvin interconnection connects a source Kelvin pad of the at least one first power device to the source Kelvin terminal. The power module of the above-noted EXAMPLE where the source Kelvin terminal is connected to a signal trace; and where the at least one true Kelvin interconnection is wire bonded to the signal trace. The power module of the above-noted EXAMPLE where the at least one true Kelvin interconnection is configured to be electrically isolated from a power loop of the power module. The power module of the above-noted EXAMPLE where the at least one true Kelvin interconnection is configured to be electrically isolated from a power loop of the power module such that a current flow of the power loop does not flow through the at least one true Kelvin interconnection. The power module of the above-noted EXAMPLE where the at least one pseudo-Kelvin interconnection connects the at least one second power device through the at least one true Kelvin interconnection. The power module of the above-noted EXAMPLE where the at least one pseudo-Kelvin interconnection connects to a source pad of the at least one first power device. The power module of the above-noted EXAMPLE where the at least one pseudo-Kelvin interconnection connects a source pad of the at least one second power device at least partially through a power loop of the power module. The power module of the above-noted EXAMPLE where the at least one pseudo-Kelvin interconnection is configured as part of a power loop of the power module such that a current flow of the power loop also flows through at least a portion the at least one pseudo-Kelvin interconnection. The power module of the above-noted EXAMPLE where the at least one first power device and the at least one second power device are implemented as paralleled power electronic devices in the power module. The power module of the above-noted EXAMPLE where the at least one pseudo-Kelvin interconnection shares a partial path with a power loop of the at least one first power device and/or the at least one second power device. The power module of the above-noted EXAMPLE where the at least one true Kelvin interconnection is configured such that there is no shared path through a power loop of the power module. The power module of the above-noted EXAMPLE where the at least one pseudo-Kelvin interconnection is configured such that there is a shared path through a power loop of the power module. The power module of the above-noted EXAMPLE where the at least one pseudo-Kelvin interconnection is configured to operate with a signal current flow in one direction and a power flow in a direction orthogonal to the signal current flow. The power module of the above-noted EXAMPLE where the at least one first power device is configured with the at least one true Kelvin interconnection and the at least one first power device is arranged on an edge of the power substrate. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The power module of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The power module of the above-noted EXAMPLE where the at least one pseudo-Kelvin interconnection is connected to the at least one true Kelvin interconnection. The power module of the above-noted EXAMPLE where the at least one pseudo-Kelvin interconnection is connected to the at least one true Kelvin interconnection through one or more wire bonds between the at least one first power device and the at least one second power device. The power module of the above-noted EXAMPLE where the at least one pseudo-Kelvin interconnection comprises one or more wire bonds connecting between different implementations of the at least one second power device. The power module of the above-noted EXAMPLE where the at least one pseudo-Kelvin interconnection comprises one or more stitched wire bonds connecting between different implementations of the at least one second power device. The power module of the above-noted EXAMPLE where the at least one pseudo-Kelvin interconnection is connected to the at least one true Kelvin interconnection through one or more clips between the at least one first power device and the at least one second power device. The power module of the above-noted EXAMPLE where the at least one pseudo-Kelvin interconnection is connected to the at least one true Kelvin interconnection through one or more clips between different implementations of the at least one second power device. The power module of the above-noted EXAMPLE where the at least one pseudo-Kelvin interconnection is connected to the at least one true Kelvin interconnection through one or more jumpers between the at least one first power device and the at least one second power device. The power module of the above-noted EXAMPLE where the at least one pseudo-Kelvin interconnection is connected to the at least one true Kelvin interconnection through one or more jumpers between different implementations of the at least one second power device. The power module of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The power module of the above-noted EXAMPLE includes two implementations of the at least one true Kelvin interconnection and two implementations of the at least one first power device. The power module of the above-noted EXAMPLE where the at least one first power device and/or the at least one second power device comprise a MOSFET with a gate pad, at least one source pad, and a drain pad. The power module of the above-noted EXAMPLE where the at least one true Kelvin interconnection is connected to the at least one source pad of the at least one first power device; and where the at least one pseudo-Kelvin interconnection is connected to the at least one source pad of the at least one second power device. The power module of the above-noted EXAMPLE where the at least one first power device and/or the at least one second power device comprise a MOSFET with a gate pad, at least one source pad, a drain pad, and at least one source Kelvin pad. The power module of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The power module of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The power module of the above-noted EXAMPLE includes a single implementation of the at least one first power device and a single implementation of the at least one true Kelvin interconnection. The power module of the above-noted EXAMPLE includes multiple implementations of the at least one first power device and multiple implementations of the at least one true Kelvin interconnection. The power module of the above-noted EXAMPLE includes a plurality of the at least one second power device and a plurality of the at least one pseudo-Kelvin interconnection. The power module of the above-noted EXAMPLE where a number of the at least one first power device are arranged on and along a first axis of the power substrate. The power module of the above-noted EXAMPLE where a number of the at least one first power device are arranged on and along a second axis of the power substrate. The power module of the above-noted EXAMPLE where a number of the at least one first power device are arranged on and along a first axis of the power substrate; and where a number of the at least one first power device are arranged on and along a second axis of the power substrate. The power module of the above-noted EXAMPLE where a number of the at least one second power device are arranged on and along a first axis of the power substrate. The power module of the above-noted EXAMPLE where a number of the at least one second power device are arranged on and along a second axis of the power substrate. The power module of the above-noted EXAMPLE where a number of the at least one second power device are arranged on and along a first axis of the power substrate; and where a number of the at least one second power device are arranged on and along a second axis of the power substrate.

One EXAMPLE: a power module includes at least one first power device.

The power module in addition includes at least one second power device. The module moreover includes at least one true Kelvin interconnection. The module also includes at least one pseudo-Kelvin interconnection. The module further includes where the at least one pseudo-Kelvin interconnection is connected to the at least one true Kelvin interconnection.

The above-noted EXAMPLE may further include any one or a combination of more than one of the following EXAMPLES: The power module of the above-noted EXAMPLE where the at least one first power device is connected to the at least one true Kelvin interconnection; and where the at least one second power device is connected to the at least one pseudo-Kelvin interconnection. The power module of the above-noted EXAMPLE includes a source Kelvin terminal. The power module of the above-noted EXAMPLE where the at least one true Kelvin interconnection connects the at least one first power device to the source Kelvin terminal. The power module of the above-noted EXAMPLE where the at least one true Kelvin interconnection connects a source pad of the at least one first power device to the source Kelvin terminal. The power module of the above-noted EXAMPLE where the at least one true Kelvin interconnection connects a source Kelvin pad of the at least one first power device to the source Kelvin terminal. The power module of the above-noted EXAMPLE where the source Kelvin terminal is connected to a signal trace; and where the at least one true Kelvin interconnection is wire bonded to the signal trace. The power module of the above-noted EXAMPLE where the at least one true Kelvin interconnection is configured to be electrically isolated from a power loop of the power module. The power module of the above-noted EXAMPLE where the at least one true Kelvin interconnection is configured to be electrically isolated from a power loop of the power module such that a current flow of the power loop does not flow through the at least one true Kelvin interconnection. The power module of the above-noted EXAMPLE where the at least one pseudo-Kelvin interconnection connects the at least one second power device through the at least one true Kelvin interconnection. The power module of the above-noted EXAMPLE where the at least one pseudo-Kelvin interconnection connects to a source pad of the at least one first power device. The power module of the above-noted EXAMPLE where the at least one pseudo-Kelvin interconnection connects a source pad of the at least one second power device at least partially through a power loop of the power module. The power module of the above-noted EXAMPLE where the at least one pseudo-Kelvin interconnection is configured as part of a power loop of the power module such that a current flow of the power loop also flows through at least a portion the at least one pseudo-Kelvin interconnection. The power module of the above-noted EXAMPLE where the at least one first power device and the at least one second power device are implemented as paralleled power electronic devices in the power module. The power module of the above-noted EXAMPLE where the at least one pseudo-Kelvin interconnection shares a partial path with a power loop of the at least one first power device and/or the at least one second power device. The power module of the above-noted EXAMPLE where the at least one true Kelvin interconnection is configured such that there is no shared path through a power loop of the power module. The power module of the above-noted EXAMPLE where the at least one pseudo-Kelvin interconnection is configured such that there is a shared path through a power loop of the power module. The power module of the above-noted EXAMPLE where the at least one pseudo-Kelvin interconnection is configured to operate with a signal current flow in one direction and a power flow in a direction orthogonal to the signal current flow. The power module of the above-noted EXAMPLE where the at least one first power device is configured with the at least one true Kelvin interconnection and the at least one first power device is arranged on an edge of a power substrate. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The power module of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The power module of the above-noted EXAMPLE where the at least one pseudo-Kelvin interconnection is connected to the at least one true Kelvin interconnection through one or more wire bonds between the at least one first power device and the at least one second power device. The power module of the above-noted EXAMPLE where the at least one pseudo-Kelvin interconnection comprises one or more wire bonds connecting between different implementations of the at least one second power device. The power module of the above-noted EXAMPLE where the at least one pseudo-Kelvin interconnection comprises one or more stitched wire bonds connecting between different implementations of the at least one second power device. The power module of the above-noted EXAMPLE where the at least one pseudo-Kelvin interconnection is connected to the at least one true Kelvin interconnection through one or more clips between the at least one first power device and the at least one second power device. The power module of the above-noted EXAMPLE where the at least one pseudo-Kelvin interconnection is connected to the at least one true Kelvin interconnection through one or more clips between different implementations of the at least one second power device. The power module of the above-noted EXAMPLE where the at least one pseudo-Kelvin interconnection is connected to the at least one true Kelvin interconnection through one or more jumpers between the at least one first power device and the at least one second power device. The power module of the above-noted EXAMPLE where the at least one pseudo-Kelvin interconnection is connected to the at least one true Kelvin interconnection through one or more jumpers between different implementations of the at least one second power device. The power module of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The power module of the above-noted EXAMPLE includes two implementations of the at least one true Kelvin interconnection and two implementations of the at least one first power device. The power module of the above-noted EXAMPLE where the at least one first power device and/or the at least one second power device comprise a MOSFET with a gate pad, at least one source pad, and a drain pad. The power module of the above-noted EXAMPLE where the at least one true Kelvin interconnection is connected to the at least one source pad of the at least one first power device; and where the at least one pseudo-Kelvin interconnection is connected to the at least one source pad of the at least one second power device. The power module of the above-noted EXAMPLE where the at least one first power device and/or the at least one second power device comprise a MOSFET with a gate pad, at least one source pad, a drain pad, and at least one source Kelvin pad. The power module of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The power module of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The power module of the above-noted EXAMPLE includes a single implementation of the at least one first power device and a single implementation of the at least one true Kelvin interconnection. The power module of the above-noted EXAMPLE includes multiple implementations of the at least one first power device and multiple implementations of the at least one true Kelvin interconnection. The power module of the above-noted EXAMPLE includes a plurality of the at least one second power device and a plurality of the at least one pseudo-Kelvin interconnection. The power module of the above-noted EXAMPLE where a number of the at least one first power device are arranged on and along a first axis of a power substrate. The power module of the above-noted EXAMPLE where a number of the at least one first power device are arranged on and along a second axis of a power substrate. The power module of the above-noted EXAMPLE where a number of the at least one first power device are arranged on and along a first axis of a power substrate; and where a number of the at least one first power device are arranged on and along a second axis of the power substrate. The power module of the above-noted EXAMPLE where a number of the at least one second power device are arranged on and along a first axis of a power substrate. The power module of the above-noted EXAMPLE where a number of the at least one second power device are arranged on and along a second axis of a power substrate. The power module of the above-noted EXAMPLE where a number of the at least one second power device are arranged on and along a first axis of a power substrate; and where a number of the at least one second power device are arranged on and along a second axis of the power substrate.

One EXAMPLE: a power module includes at least one first power device. The power module in addition includes at least one second power device. The module moreover includes at least one true Kelvin interconnection. The module also includes at least one pseudo-Kelvin interconnection. The module further includes where the at least one first power device is connected to the at least one true Kelvin interconnection. The module in addition includes where the at least one second power device is connected to the at least one pseudo-Kelvin interconnection.

The above-noted EXAMPLE may further include any one or a combination of more than one of the following EXAMPLES: The power module of the above-noted EXAMPLE where the at least one pseudo-Kelvin interconnection is connected to the at least one true Kelvin interconnection. The power module of the above-noted EXAMPLE includes a source Kelvin terminal. The power module of the above-noted EXAMPLE where the at least one true Kelvin interconnection connects the at least one first power device to the source Kelvin terminal. The power module of the above-noted EXAMPLE where the at least one true Kelvin interconnection connects a source pad of the at least one first power device to the source Kelvin terminal. The power module of the above-noted EXAMPLE where the at least one true Kelvin interconnection connects a source Kelvin pad of the at least one first power device to the source Kelvin terminal. The power module of the above-noted EXAMPLE where the source Kelvin terminal is connected to a signal trace; and where the at least one true Kelvin interconnection is wire bonded to the signal trace. The power module of the above-noted EXAMPLE where the at least one true Kelvin interconnection is configured to be electrically isolated from a power loop of the power module. The power module of the above-noted EXAMPLE where the at least one true Kelvin interconnection is configured to be electrically isolated from a power loop of the power module such that a current flow of the power loop does not flow through the at least one true Kelvin interconnection. The power module of the above-noted EXAMPLE where the at least one pseudo-Kelvin interconnection connects the at least one second power device through the at least one true Kelvin interconnection. The power module of the above-noted EXAMPLE where the at least one pseudo-Kelvin interconnection connects to a source pad of the at least one first power device. The power module of the above-noted EXAMPLE where the at least one pseudo-Kelvin interconnection connects a source pad of the at least one second power device at least partially through a power loop of the power module. The power module of the above-noted EXAMPLE where the at least one pseudo-Kelvin interconnection is configured as part of a power loop of the power module such that a current flow of the power loop also flows through at least a portion the at least one pseudo-Kelvin interconnection. The power module of the above-noted EXAMPLE where the at least one first power device and the at least one second power device are implemented as paralleled power electronic devices in the power module. The power module of the above-noted EXAMPLE where the at least one pseudo-Kelvin interconnection shares a partial path with a power loop of the at least one first power device and/or the at least one second power device. The power module of the above-noted EXAMPLE where the at least one true Kelvin interconnection is configured such that there is no shared path through a power loop of the power module. The power module of the above-noted EXAMPLE where the at least one pseudo-Kelvin interconnection is configured such that there is a shared path through a power loop of the power module. The power module of the above-noted EXAMPLE where the at least one pseudo-Kelvin interconnection is configured to operate with a signal current flow in one direction and a power flow in a direction orthogonal to the signal current flow. The power module of the above-noted EXAMPLE where the at least one first power device is configured with the at least one true Kelvin interconnection and the at least one first power device is arranged on an edge of a power substrate. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The power module of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The power module of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The power module of the above-noted EXAMPLE where the at least one pseudo-Kelvin interconnection is connected to the at least one true Kelvin interconnection through one or more wire bonds between the at least one first power device and the at least one second power device. The power module of the above-noted EXAMPLE where the at least one pseudo-Kelvin interconnection comprises one or more wire bonds connecting between different implementations of the at least one second power device. The power module of the above-noted EXAMPLE where the at least one pseudo-Kelvin interconnection comprises one or more stitched wire bonds connecting between different implementations of the at least one second power device. The power module of the above-noted EXAMPLE where the at least one pseudo-Kelvin interconnection is connected to the at least one true Kelvin interconnection through one or more clips between the at least one first power device and the at least one second power device. The power module of the above-noted EXAMPLE where the at least one pseudo-Kelvin interconnection is connected to the at least one true Kelvin interconnection through one or more clips between different implementations of the at least one second power device. The power module of the above-noted EXAMPLE where the at least one pseudo-Kelvin interconnection is connected to the at least one true Kelvin interconnection through one or more jumpers between the at least one first power device and the at least one second power device. The power module of the above-noted EXAMPLE where the at least one pseudo-Kelvin interconnection is connected to the at least one true Kelvin interconnection through one or more jumpers between different implementations of the at least one second power device. The power module of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The power module of the above-noted EXAMPLE includes two implementations of the at least one true Kelvin interconnection and two implementations of the at least one first power device. The power module of the above-noted EXAMPLE where the at least one first power device and/or the at least one second power device comprise a MOSFET with a gate pad, at least one source pad, and a drain pad. The power module of the above-noted EXAMPLE where the at least one true Kelvin interconnection is connected to the at least one source pad of the at least one first power device; and where the at least one pseudo-Kelvin interconnection is connected to the at least one source pad of the at least one second power device. The power module of the above-noted EXAMPLE where the at least one first power device and/or the at least one second power device comprise a MOSFET with a gate pad, at least one source pad, a drain pad, and at least one source Kelvin pad. The power module of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The power module of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The power module of the above-noted EXAMPLE includes a single implementation of the at least one first power device and a single implementation of the at least one true Kelvin interconnection. The power module of the above-noted EXAMPLE includes multiple implementations of the at least one first power device and multiple implementations of the at least one true Kelvin interconnection. The power module of the above-noted EXAMPLE includes a plurality of the at least one second power device and a plurality of the at least one pseudo-Kelvin interconnection. The power module of the above-noted EXAMPLE where a number of the at least one first power device are arranged on and along a first axis of a power substrate. The power module of the above-noted EXAMPLE where a number of the at least one first power device are arranged on and along a second axis of a power substrate. The power module of the above-noted EXAMPLE where a number of the at least one first power device are arranged on and along a first axis of a power substrate; and where a number of the at least one first power device are arranged on and along a second axis of the power substrate. The power module of the above-noted EXAMPLE where a number of the at least one second power device are arranged on and along a first axis of a power substrate. The power module of the above-noted EXAMPLE where a number of the at least one second power device are arranged on and along a second axis of a power substrate. The power module of the above-noted EXAMPLE where a number of the at least one second power device are arranged on and along a first axis of a power substrate; and where a number of the at least one second power device are arranged on and along a second axis of the power substrate.

One EXAMPLE: a process includes providing a power substrate. The process in addition includes arranging at least one first power device on the power substrate. The process moreover includes arranging at least one second power device on the power substrate. The process also includes providing at least one true Kelvin interconnection. The process further includes providing at least one pseudo-Kelvin interconnection.

The above-noted EXAMPLE may further include any one or a combination of more than one of the following EXAMPLES: The process of the above-noted EXAMPLE includes: connecting the at least one first power device to the at least one true Kelvin interconnection; and connecting the at least one second power device to the at least one pseudo-Kelvin interconnection. The process of the above-noted EXAMPLE includes providing a source Kelvin terminal. The process of the above-noted EXAMPLE where the at least one true Kelvin interconnection connects the at least one first power device to the source Kelvin terminal. The process of the above-noted EXAMPLE where the at least one true Kelvin interconnection connects a source pad of the at least one first power device to the source Kelvin terminal. The process of the above-noted EXAMPLE where the at least one true Kelvin interconnection connects a source Kelvin pad of the at least one first power device to the source Kelvin terminal. The process of the above-noted EXAMPLE where the source Kelvin terminal is connected to a signal trace; and where the at least one true Kelvin interconnection is wire bonded to the signal trace. The process of the above-noted EXAMPLE where the at least one true Kelvin interconnection is configured to be electrically isolated from a power loop of the power module. The process of the above-noted EXAMPLE where the at least one true Kelvin interconnection is configured to be electrically isolated from a power loop of the power module such that a current flow of the power loop does not flow through the at least one true Kelvin interconnection. The process of the above-noted EXAMPLE where the at least one pseudo-Kelvin interconnection connects the at least one second power device through the at least one true Kelvin interconnection. The process of the above-noted EXAMPLE where the at least one pseudo-Kelvin interconnection connects to a source pad of the at least one first power device. The process of the above-noted EXAMPLE where the at least one pseudo-Kelvin interconnection connects a source pad of the at least one second power device at least partially through a power loop of the power module. The process of the above-noted EXAMPLE where the at least one pseudo-Kelvin interconnection is configured as part of a power loop of the power module such that a current flow of the power loop also flows through at least a portion the at least one pseudo-Kelvin interconnection. The process of the above-noted EXAMPLE where the at least one first power device and the at least one second power device are implemented as paralleled power electronic devices in the power module. The process of the above-noted EXAMPLE where the at least one pseudo-Kelvin interconnection shares a partial path with a power loop of the at least one first power device and/or the at least one second power device. The process of the above-noted EXAMPLE where the at least one true Kelvin interconnection is configured such that there is no shared path through a power loop of the power module. The process of the above-noted EXAMPLE where the at least one pseudo-Kelvin interconnection is configured such that there is a shared path through a power loop of the power module. The process of the above-noted EXAMPLE where the at least one pseudo-Kelvin interconnection is configured to operate with a signal current flow in one direction and a power flow in a direction orthogonal to the signal current flow. The process of the above-noted EXAMPLE where the at least one first power device is configured with the at least one true Kelvin interconnection and the at least one first power device is arranged on an edge of the power substrate. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The process of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The process of the above-noted EXAMPLE where the at least one pseudo-Kelvin interconnection is connected to the at least one true Kelvin interconnection. The process of the above-noted EXAMPLE where the at least one pseudo-Kelvin interconnection is connected to the at least one true Kelvin interconnection through one or more wire bonds between the at least one first power device and the at least one second power device. The process of the above-noted EXAMPLE where the at least one pseudo-Kelvin interconnection comprises one or more wire bonds connecting between different implementations of the at least one second power device. The process of the above-noted EXAMPLE where the at least one pseudo-Kelvin interconnection comprises one or more stitched wire bonds connecting between different implementations of the at least one second power device. The process of the above-noted EXAMPLE where the at least one pseudo-Kelvin interconnection is connected to the at least one true Kelvin interconnection through one or more clips between the at least one first power device and the at least one second power device. The process of the above-noted EXAMPLE where the at least one pseudo-Kelvin interconnection is connected to the at least one true Kelvin interconnection through one or more clips between different implementations of the at least one second power device. The process of the above-noted EXAMPLE where the at least one pseudo-Kelvin interconnection is connected to the at least one true Kelvin interconnection through one or more jumpers between the at least one first power device and the at least one second power device. The process of the above-noted EXAMPLE where the at least one pseudo-Kelvin interconnection is connected to the at least one true Kelvin interconnection through one or more jumpers between different implementations of the at least one second power device. The process of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The process of the above-noted EXAMPLE includes two implementations of the at least one true Kelvin interconnection and two implementations of the at least one first power device. The process of the above-noted EXAMPLE where the at least one first power device and/or the at least one second power device comprise a MOSFET with a gate pad, at least one source pad, and a drain pad. The process of the above-noted EXAMPLE where the at least one true Kelvin interconnection is connected to the at least one source pad of the at least one first power device; and where the at least one pseudo-Kelvin interconnection is connected to the at least one source pad of the at least one second power device. The process of the above-noted EXAMPLE where the at least one first power device and/or the at least one second power device comprise a MOSFET with a gate pad, at least one source pad, a drain pad, and at least one source Kelvin pad. The process of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The process of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The process of the above-noted EXAMPLE includes a single implementation of the at least one first power device and a single implementation of the at least one true Kelvin interconnection. The process of the above-noted EXAMPLE includes multiple implementations of the at least one first power device and multiple implementations of the at least one true Kelvin interconnection. The process of the above-noted EXAMPLE includes a plurality of the at least one second power device and a plurality of the at least one pseudo-Kelvin interconnection. The process of the above-noted EXAMPLE where a number of the at least one first power device are arranged on and along a first axis of the power substrate. The process of the above-noted EXAMPLE where a number of the at least one first power device are arranged on and along a second axis of the power substrate. The process of the above-noted EXAMPLE where a number of the at least one first power device are arranged on and along a first axis of the power substrate; and where a number of the at least one first power device are arranged on and along a second axis of the power substrate. The process of the above-noted EXAMPLE where a number of the at least one second power device are arranged on and along a first axis of the power substrate. The process of the above-noted EXAMPLE where a number of the at least one second power device are arranged on and along a second axis of the power substrate. The process of the above-noted EXAMPLE where a number of the at least one second power device are arranged on and along a first axis of the power substrate; and where a number of the at least one second power device are arranged on and along a second axis of the power substrate.

One EXAMPLE: a process includes providing at least one first power device. The process in addition includes providing at least one second power device. The process moreover includes providing at least one true Kelvin interconnection. The process also includes providing at least one pseudo-Kelvin interconnection. The process further includes connecting the at least one pseudo-Kelvin interconnection to the at least one true Kelvin interconnection.

The above-noted EXAMPLE may further include any one or a combination of more than one of the following EXAMPLES: The process of the above-noted EXAMPLE includes: connecting the at least one first power device to the at least one true Kelvin interconnection; and connecting the at least one second power device to the at least one pseudo-Kelvin interconnection. The process of the above-noted EXAMPLE includes a source Kelvin terminal. The process of the above-noted EXAMPLE where the at least one true Kelvin interconnection connects the at least one first power device to the source Kelvin terminal. The process of the above-noted EXAMPLE where the at least one true Kelvin interconnection connects a source pad of the at least one first power device to the source Kelvin terminal. The process of the above-noted EXAMPLE where the at least one true Kelvin interconnection connects a source Kelvin pad of the at least one first power device to the source Kelvin terminal. The process of the above-noted EXAMPLE where the source Kelvin terminal is connected to a signal trace; and where the at least one true Kelvin interconnection is wire bonded to the signal trace. The process of the above-noted EXAMPLE where the at least one true Kelvin interconnection is configured to be electrically isolated from a power loop of the power module. The process of the above-noted EXAMPLE where the at least one true Kelvin interconnection is configured to be electrically isolated from a power loop of the power module such that a current flow of the power loop does not flow through the at least one true Kelvin interconnection. The process of the above-noted EXAMPLE where the at least one pseudo-Kelvin interconnection connects the at least one second power device through the at least one true Kelvin interconnection. The process of the above-noted EXAMPLE where the at least one pseudo-Kelvin interconnection connects to a source pad of the at least one first power device. The process of the above-noted EXAMPLE where the at least one pseudo-Kelvin interconnection connects a source pad of the at least one second power device at least partially through a power loop of the power module. The process of the above-noted EXAMPLE where the at least one pseudo-Kelvin interconnection is configured as part of a power loop of the power module such that a current flow of the power loop also flows through at least a portion the at least one pseudo-Kelvin interconnection. The process of the above-noted EXAMPLE where the at least one first power device and the at least one second power device are implemented as paralleled power electronic devices in the power module. The process of the above-noted EXAMPLE where the at least one pseudo-Kelvin interconnection shares a partial path with a power loop of the at least one first power device and/or the at least one second power device. The process of the above-noted EXAMPLE where the at least one true Kelvin interconnection is configured such that there is no shared path through a power loop of the power module. The process of the above-noted EXAMPLE where the at least one pseudo-Kelvin interconnection is configured such that there is a shared path through a power loop of the power module. The process of the above-noted EXAMPLE where the at least one pseudo-Kelvin interconnection is configured to operate with a signal current flow in one direction and a power flow in a direction orthogonal to the signal current flow. The process of the above-noted EXAMPLE where the at least one first power device is configured with the at least one true Kelvin interconnection and the at least one first power device is arranged on an edge of a power substrate. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The process of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The process of the above-noted EXAMPLE where the at least one pseudo-Kelvin interconnection is connected to the at least one true Kelvin interconnection through one or more wire bonds between the at least one first power device and the at least one second power device. The process of the above-noted EXAMPLE where the at least one pseudo-Kelvin interconnection comprises one or more wire bonds connecting between different implementations of the at least one second power device. The process of the above-noted EXAMPLE where the at least one pseudo-Kelvin interconnection comprises one or more stitched wire bonds connecting between different implementations of the at least one second power device. The process of the above-noted EXAMPLE where the at least one pseudo-Kelvin interconnection is connected to the at least one true Kelvin interconnection through one or more clips between the at least one first power device and the at least one second power device. The process of the above-noted EXAMPLE where the at least one pseudo-Kelvin interconnection is connected to the at least one true Kelvin interconnection through one or more clips between different implementations of the at least one second power device. The process of the above-noted EXAMPLE where the at least one pseudo-Kelvin interconnection is connected to the at least one true Kelvin interconnection through one or more jumpers between the at least one first power device and the at least one second power device. The process of the above-noted EXAMPLE where the at least one pseudo-Kelvin interconnection is connected to the at least one true Kelvin interconnection through one or more jumpers between different implementations of the at least one second power device. The process of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The process of the above-noted EXAMPLE includes two implementations of the at least one true Kelvin interconnection and two implementations of the at least one first power device. The process of the above-noted EXAMPLE where the at least one first power device and/or the at least one second power device comprise a MOSFET with a gate pad, at least one source pad, and a drain pad. The process of the above-noted EXAMPLE where the at least one true Kelvin interconnection is connected to the at least one source pad of the at least one first power device; and where the at least one pseudo-Kelvin interconnection is connected to the at least one source pad of the at least one second power device. The process of the above-noted EXAMPLE where the at least one first power device and/or the at least one second power device comprise a MOSFET with a gate pad, at least one source pad, a drain pad, and at least one source Kelvin pad. The process of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The process of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The process of the above-noted EXAMPLE includes a single implementation of the at least one first power device and a single implementation of the at least one true Kelvin interconnection. The process of the above-noted EXAMPLE includes multiple implementations of the at least one first power device and multiple implementations of the at least one true Kelvin interconnection. The process of the above-noted EXAMPLE includes a plurality of the at least one second power device and a plurality of the at least one pseudo-Kelvin interconnection. The process of the above-noted EXAMPLE where a number of the at least one first power device are arranged on and along a first axis of a power substrate. The process of the above-noted EXAMPLE where a number of the at least one first power device are arranged on and along a second axis of a power substrate. The process of the above-noted EXAMPLE where a number of the at least one first power device are arranged on and along a first axis of a power substrate; and where a number of the at least one first power device are arranged on and along a second axis of the power substrate. The process of the above-noted EXAMPLE where a number of the at least one second power device are arranged on and along a first axis of a power substrate. The process of the above-noted EXAMPLE where a number of the at least one second power device are arranged on and along a second axis of a power substrate. The process of the above-noted EXAMPLE where a number of the at least one second power device are arranged on and along a first axis of a power substrate; and where a number of the at least one second power device are arranged on and along a second axis of the power substrate.

One EXAMPLE: a process includes providing at least one first power device. The process in addition includes providing at least one second power device. The process moreover includes providing at least one true Kelvin interconnection. The process also includes providing at least one pseudo-Kelvin interconnection. The process further includes connecting the at least one first power device to the at least one true Kelvin interconnection. The process in addition includes connecting the at least one second power device to the at least one pseudo-Kelvin interconnection.

The above-noted EXAMPLE may further include any one or a combination of more than one of the following EXAMPLES: The process of the above-noted EXAMPLE where the at least one pseudo-Kelvin interconnection is connected to the at least one true Kelvin interconnection. The process of the above-noted EXAMPLE includes a source Kelvin terminal. The process of the above-noted EXAMPLE where the at least one true Kelvin interconnection connects the at least one first power device to the source Kelvin terminal. The process of the above-noted EXAMPLE where the at least one true Kelvin interconnection connects a source pad of the at least one first power device to the source Kelvin terminal. The process of the above-noted EXAMPLE where the at least one true Kelvin interconnection connects a source Kelvin pad of the at least one first power device to the source Kelvin terminal. The process of the above-noted EXAMPLE where the source Kelvin terminal is connected to a signal trace; and where the at least one true Kelvin interconnection is wire bonded to the signal trace. The process of the above-noted EXAMPLE where the at least one true Kelvin interconnection is configured to be electrically isolated from a power loop of the power module. The process of the above-noted EXAMPLE where the at least one true Kelvin interconnection is configured to be electrically isolated from a power loop of the power module such that a current flow of the power loop does not flow through the at least one true Kelvin interconnection. The process of the above-noted EXAMPLE where the at least one pseudo-Kelvin interconnection connects the at least one second power device through the at least one true Kelvin interconnection. The process of the above-noted EXAMPLE where the at least one pseudo-Kelvin interconnection connects to a source pad of the at least one first power device. The process of the above-noted EXAMPLE where the at least one pseudo-Kelvin interconnection connects a source pad of the at least one second power device at least partially through a power loop of the power module. The process of the above-noted EXAMPLE where the at least one pseudo-Kelvin interconnection is configured as part of a power loop of the power module such that a current flow of the power loop also flows through at least a portion the at least one pseudo-Kelvin interconnection. The process of the above-noted EXAMPLE where the at least one first power device and the at least one second power device are implemented as paralleled power electronic devices in the power module. The process of the above-noted EXAMPLE where the at least one pseudo-Kelvin interconnection shares a partial path with a power loop of the at least one first power device and/or the at least one second power device. The process of the above-noted EXAMPLE where the at least one true Kelvin interconnection is configured such that there is no shared path through a power loop of the power module. The process of the above-noted EXAMPLE where the at least one pseudo-Kelvin interconnection is configured such that there is a shared path through a power loop of the power module. The process of the above-noted EXAMPLE where the at least one pseudo-Kelvin interconnection is configured to operate with a signal current flow in one direction and a power flow in a direction orthogonal to the signal current flow. The process of the above-noted EXAMPLE where the at least one first power device is configured with the at least one true Kelvin interconnection and the at least one first power device is arranged on an edge of a power substrate. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, ribbons, laminate overlays, and/or direct attaches. The process of the above-noted EXAMPLE where the at least one true Kelvin interconnection is configured as a true source Kelvin interconnection to at least one source pad on the at least one first power device; and where the at least one true Kelvin interconnection comprises one or more wire bonds, and/or one or more wire bonds and signal traces. The process of the above-noted EXAMPLE where the at least one pseudo-Kelvin interconnection is configured as a partial or pseudo Kelvin interconnection to source pads on the at least one second power device through one or more wire bonds, ribbons, laminate overlays, and/or direct attaches. The process of the above-noted EXAMPLE where the at least one pseudo-Kelvin interconnection is connected to the at least one true Kelvin interconnection through one or more wire bonds between the at least one first power device and the at least one second power device. The process of the above-noted EXAMPLE where the at least one pseudo-Kelvin interconnection comprises one or more wire bonds connecting between different implementations of the at least one second power device. The process of the above-noted EXAMPLE where the at least one pseudo-Kelvin interconnection comprises one or more stitched wire bonds connecting between different implementations of the at least one second power device. The process of the above-noted EXAMPLE where the at least one pseudo-Kelvin interconnection is connected to the at least one true Kelvin interconnection through one or more clips between the at least one first power device and the at least one second power device. The process of the above-noted EXAMPLE where the at least one pseudo-Kelvin interconnection is connected to the at least one true Kelvin interconnection through one or more clips between different implementations of the at least one second power device. The process of the above-noted EXAMPLE where the at least one pseudo-Kelvin interconnection is connected to the at least one true Kelvin interconnection through one or more jumpers between the at least one first power device and the at least one second power device. The process of the above-noted EXAMPLE where the at least one pseudo-Kelvin interconnection is connected to the at least one true Kelvin interconnection through one or more jumpers between different implementations of the at least one second power device. The process of the above-noted EXAMPLE includes a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path. The process of the above-noted EXAMPLE includes two implementations of the at least one true Kelvin interconnection and two implementations of the at least one first power device. The process of the above-noted EXAMPLE where the at least one first power device and/or the at least one second power device comprise a MOSFET with a gate pad, at least one source pad, and a drain pad. The process of the above-noted EXAMPLE where the at least one true Kelvin interconnection is connected to the at least one source pad of the at least one first power device; and where the at least one pseudo-Kelvin interconnection is connected to the at least one source pad of the at least one second power device. The process of the above-noted EXAMPLE where the at least one first power device and/or the at least one second power device comprise a MOSFET with a gate pad, at least one source pad, a drain pad, and at least one source Kelvin pad. The process of the above-noted EXAMPLE where the at least one true Kelvin interconnection is connected to the at least one source Kelvin pad of the at least one first power device; and where the at least one pseudo-Kelvin interconnection is connected to the at least one source pad of the at least one second power device. The process of the above-noted EXAMPLE where the at least one true Kelvin interconnection is connected to the at least one source Kelvin pad of the at least one first power device; and where the at least one pseudo-Kelvin interconnection is connected to the at least one source Kelvin pad of the at least one second power device. The process of the above-noted EXAMPLE includes a single implementation of the at least one first power device and a single implementation of the at least one true Kelvin interconnection. The process of the above-noted EXAMPLE includes multiple implementations of the at least one first power device and multiple implementations of the at least one true Kelvin interconnection. The process of the above-noted EXAMPLE includes a plurality of the at least one second power device and a plurality of the at least one pseudo-Kelvin interconnection. The process of the above-noted EXAMPLE where a number of the at least one first power device are arranged on and along a first axis of a power substrate. The process of the above-noted EXAMPLE where a number of the at least one first power device are arranged on and along a second axis of a power substrate. The process of the above-noted EXAMPLE where a number of the at least one first power device are arranged on and along a first axis of a power substrate; and where a number of the at least one first power device are arranged on and along a second axis of the power substrate. The process of the above-noted EXAMPLE where a number of the at least one second power device are arranged on and along a first axis of a power substrate. The process of the above-noted EXAMPLE where a number of the at least one second power device are arranged on and along a second axis of a power substrate. The process of the above-noted EXAMPLE where a number of the at least one second power device are arranged on and along a first axis of a power substrate; and where a number of the at least one second power device are arranged on and along a second axis of the power substrate.

Accordingly, the disclosure has set forth a power module and process of implementing a power module that may be utilized for achieving fast, clean, and efficient switching of paralleled power electronic devices in packages and/or layouts, which do not readily allow true source kelvin interconnection for each individual device without needing additional elements such as signal substrates, complex signal routing, and/or the like.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power module comprising:
a power substrate;
at least one first power device arranged on the power substrate;
at least one second power device arranged on the power substrate;
at least one true Kelvin interconnection; and
at least one pseudo-Kelvin interconnection.

2. The power module according to claim 1,
wherein the at least one first power device is connected to the at least one true Kelvin interconnection; and
wherein the at least one second power device is connected to the at least one pseudo-Kelvin interconnection.

3. The power module according to claim 1, further comprising a source Kelvin terminal.

4. The power module according to claim 3, wherein the at least one true Kelvin interconnection connects the at least one first power device to the source Kelvin terminal.

5. (canceled)

6. The power module according to claim 3, wherein the at least one true Kelvin interconnection connects a source Kelvin pad of the at least one first power device to the source Kelvin terminal.

7. The power module according to claim 3,
wherein the source Kelvin terminal is connected to a signal trace; and
wherein the at least one true Kelvin interconnection is wire bonded to the signal trace.

8. The power module according to claim 1, wherein the at least one true Kelvin interconnection is configured to be electrically isolated from a power loop of the power module.

9. The power module according to claim 1, wherein the at least one true Kelvin interconnection is configured to be electrically isolated from a power loop of the power module such that a current flow of the power loop does not flow through the at least one true Kelvin interconnection.

10. The power module according to claim 1, wherein the at least one pseudo-Kelvin interconnection connects the at least one second power device through the at least one true Kelvin interconnection.

11. (canceled)

12. (canceled)

13. The power module according to claim 1, wherein the at least one pseudo-Kelvin interconnection is configured as part of a power loop of the power module such that a current flow of the power loop also flows through at least a portion the at least one pseudo-Kelvin interconnection.

14. The power module according to claim 1, wherein the at least one first power device and the at least one second power device are implemented as paralleled power electronic devices in the power module.

15. The power module according to claim 1, wherein the at least one pseudo-Kelvin interconnection shares a partial path with a power loop of the at least one first power device and/or the at least one second power device.

16. The power module according to claim 1, wherein the at least one true Kelvin interconnection is configured such that there is no shared path through a power loop of the power module.

17. The power module according to claim 1, wherein the at least one pseudo-Kelvin interconnection is configured such that there is a shared path through a power loop of the power module.

18. The power module according to claim 1, wherein the at least one pseudo-Kelvin interconnection is configured to operate with a signal current flow in one direction and a power flow in a direction orthogonal to the signal current flow.

19. The power module according to claim 1, wherein the at least one first power device is configured with the at least one true Kelvin interconnection and the at least one first power device is arranged on an edge of the power substrate.

20. The power module according to claim 1, wherein the at least one true Kelvin interconnection is configured as a true source Kelvin interconnection to at least one source pad on the at least one first power device; and wherein the at least one true Kelvin interconnection comprises one or more wire bonds, ribbons, laminate overlays, and/or direct attaches.

21. The power module according to claim 1,
wherein the at least one true Kelvin interconnection is configured as a true source Kelvin interconnection to at least one source pad on the at least one first power device; and
wherein the at least one true Kelvin interconnection comprises one or more wire bonds, and/or one or more wire bonds and signal traces.

22. The power module according to claim 1, wherein the at least one pseudo-Kelvin interconnection is configured as a partial or pseudo Kelvin interconnection to source pads on the at least one second power device through one or more wire bonds, ribbons, laminate overlays, and/or direct attaches.

23. The power module according to claim 1, wherein the at least one pseudo-Kelvin interconnection is connected to the at least one true Kelvin interconnection.

24. The power module according to claim 1, wherein the at least one pseudo-Kelvin interconnection is connected to the at least one true Kelvin interconnection through one or more wire bonds between the at least one first power device and the at least one second power device.

25. The power module according to claim 1, wherein the at least one pseudo-Kelvin interconnection comprises one or more wire bonds connecting between different implementations of the at least one second power device.

26. The power module according to claim 1, wherein the at least one pseudo-Kelvin interconnection comprises one or more stitched wire bonds connecting between different implementations of the at least one second power device.

27. The power module according to claim 1, wherein the at least one pseudo-Kelvin interconnection is connected to the at least one true Kelvin interconnection through one or more clips between the at least one first power device and the at least one second power device.

28. The power module according to claim 1, wherein the at least one pseudo-Kelvin interconnection is connected to the at least one true Kelvin interconnection through one or more clips between different implementations of the at least one second power device.

29. The power module according to claim 1, wherein the at least one pseudo-Kelvin interconnection is connected to the at least one true Kelvin interconnection through one or more jumpers between the at least one first power device and the at least one second power device.

30. The power module according to claim 1, wherein the at least one pseudo-Kelvin interconnection is connected to the at least one true Kelvin interconnection through one or more jumpers between different implementations of the at least one second power device.

31. The power module according to claim 1, further comprising a mixed Kelvin configuration that comprises: the at least one pseudo-Kelvin interconnection that includes a shared power path through one or more source clip attaches, jumper wire bonds, and/or daisy chained wire bonds; and the at least one true Kelvin interconnection that comprises one or more wire bonds, ribbons, laminate overlays, and/or direct attaches configured separate from a power path.

32. (canceled)

33. The power module according to claim 1, wherein the at least one first power device and/or the at least one second power device comprise a MOSFET with a gate pad, at least one source pad, and a drain pad.

34.-46. (canceled)

47. A power module comprising:
at least one first power device;
at least one second power device;
at least one true Kelvin interconnection; and
at least one pseudo-Kelvin interconnection,
wherein the at least one pseudo-Kelvin interconnection is connected to the at least one true Kelvin interconnection.

48.-91. (canceled)

92. A power module comprising:
at least one first power device;
at least one second power device;
at least one true Kelvin interconnection; and
at least one pseudo-Kelvin interconnection,
wherein the at least one first power device is connected to the at least one true Kelvin interconnection; and
wherein the at least one second power device is connected to the at least one pseudo-Kelvin interconnection.

93.-272. (canceled)
